(19) United States
(12) Patent Application Publication
(10) Pub. No.: US 2018/0113566 A1
(43) Pub. Date: Apr. 26, 2018

(54) Display Device, Display Module, Electronic Device, and Touch Panel Input System

(71) Applicant: Semiconductor Energy Laboratory Co., Ltd., Kanagawa-ken (JP)

(72) Inventor: Isamu Shigemori, Atsugi (JP)

(73) Assignee: Semiconductor Energy Laboratory Co., Ltd., Kanagawa-ken (JP)

(21) Appl. No.: 15/790,366

(22) Filed: Oct. 23, 2017

(30) Foreign Application Priority Data
Oct. 25, 2016 (JP) 2016-208987

(51) Int. Cl. G06F 3/041; G06F 3/044; G02F 1/1333; G02F 1/1368; H01L 27/12

(52) U.S. Cl. CPC G06F 3/0418; G06F 3/044; G06F 3/0412; G06F 3/0482; G02F 1/1368; H01L 27/1225; G02F 1/13338

(57) ABSTRACT

A touch panel input system in which the operability of a touch panel is improved is provided. In an input system using a touch panel, a person whose fingertips are trembled or a person whose eyesight is poor touches something mistakenly, which is regarded as misoperation, in input operation in some cases. The touch panel input system uses a touch sensor module including a touch panel and a control portion. The touch panel includes a first touch sensing region and a second touch sensing region. The control portion includes a step of calculating areas where a touch is sensed in the first touch sensing region and the second touch sensing region. The control portion includes a step of determining one of the first and second touch sensing regions that has a larger integrated area is a touched position.

### TECHNICAL FIELD

One embodiment of the present invention relates to a display device, a display module, an electronic device, and a touch panel input system.

Note that one embodiment of the present invention is not limited to the above technical field. The technical field of one embodiment of the invention disclosed in this specification and the like relates to an object, a method, or a manufacturing method. The present invention relates to a process, a machine, manufacture, or a composition of matter. In particular, one embodiment of the present invention relates to a semiconductor device, a display device, a light-emitting device, a power storage device, a memory, a touch sensing device, a driving method thereof, or a manufacturing method thereof.

In this specification and the like, a semiconductor device refers to an element, a circuit, a device, or the like that can function by utilizing semiconductor characteristics. An example of the semiconductor device is a semiconductor element such as a transistor or a diode. Another example of the semiconductor device is a circuit including a semiconductor element. Another example of the semiconductor device is a device provided with a circuit including a semiconductor element.

### BACKGROUND ART

Electronic devices such as a smartphone, a tablet, an electronic book reader, a notebook personal computer, and a digital watch/clock are widely used. The electronic devices are small and highly portable, and include touch panels that can be handled easily by operators.

The electronic devices need to perform display suitable for the brightness of a use environment (i.e., an outdoor environment or an indoor environment). Furthermore, a smartphone, a tablet, and the like need to be able to be used for a long time in the case where they are used for an electronic book, games, or a communication tool such as a social networking service.

A display device that achieves low power consumption by performing display by utilizing reflected light in an environment with sufficiently bright external light, such as natural light or light from an indoor lighting device, and performing display by utilizing a light-emitting element in an environment with insufficient brightness is proposed.

For example, Patent Document 1 discloses a character input method using a touch panel included in a portable electronic device.

For example, Patent Document 2 discloses a hybrid display device in which a pixel circuit for controlling a liquid crystal element and a pixel circuit for controlling a light-emitting element are provided in one pixel.

### REFERENCE

### Patent Document

[Patent Document 1] Japanese Published Patent Application No. 2009-288873
[Patent Document 2] PCT International Publication No. WO2007/041150

### DISCLOSURE OF INVENTION

An electronic device including a touch panel is easy to use. However, for example, a person whose arm, hand, or fingertips is/are trembled or a person whose eyesight is poor may touch something mistakenly, which is regarded as misoperation, in input operation. In touch operation on a small display object (hereinafter, an icon) or the like, there is a problem that a plurality of icons are selected.

A smartphone, a tablet, an electronic book reader, a notebook personal computer, a digital watch/clock, and the like have been used more and more in places where bright external light is obtained. A reflective liquid crystal display device employs a display method that utilizes external light. Because the reflective liquid crystal display device does not require a backlight, it consumes low power; however, it can display images favorably only in a place where bright external light is obtained. A light-emitting display device, which includes a self-luminous electroluminescence (EL) element, can display images favorably in a dark place; in contrast, in a bright place, there is a problem of a reduction in visibility because the luminance is fixed.

Electronic devices such as a smartphone and a tablet that are used in places where bright external light is obtained perform display at high luminance to increase visibility. Thus, the mobile devices tend to consume a large amount of electric power. Therefore, the capacity of batteries needs to be increased in order that the electronic devices can withstand long-time use. However, when the capacity of the batteries is increased, there is a problem that the electronic devices become heavy.

In view of the above problems, an object of one embodiment of the present invention is to provide a touch sensor module with a novel structure. Another object of one embodiment of the present invention is to provide a display module that has improved operability. Another object of one embodiment of the present invention is to provide an electronic device with low power consumption.

Note that the descriptions of these objects do not disturb the existence of other objects. In one embodiment of the present invention, there is no need to achieve all the objects. Other objects are apparent from and can be derived from the description of the specification, the drawings, the claims, and the like.

Note that the objects of one embodiment of the present invention are not limited to the above objects. The objects described above do not disturb the existence of other objects. The other objects are the ones that are not described above and are described below. The other objects are apparent from and can be derived from the description of the specification, the drawings, and the like by those skilled in the art. One embodiment of the present invention is to solve at least one of the aforementioned objects and the other objects.

One embodiment of the present invention is a touch panel input system using a touch sensor module. The touch sensor module includes a touch panel and a control portion. The touch panel includes a first touch sensing region and a second touch sensing region. The control portion has a function of performing a step of calculating areas where a touch is sensed in the first touch sensing region and the second touch sensing region. The control portion also has a function of performing a step of determining that one of the first and second touch sensing regions that has a larger calculated area is a touched position.

In the above structure, the control portion preferably has a function of performing a step of integrating the areas where a touch is sensed by time, and a step of determining that one of the first and second touch sensing regions that has a larger integrated area is a touched position.

In any of the above structures, the touch panel input system further uses a display module. The display module includes the touch sensor module and a display device. The display device includes a first display region. The first display region includes a second display region and a third display region. The control portion has a function of dividing the first display region into the second display region and the third display region to control the second display region and the third display region. The first touch sensing region is positioned to overlap with and be in the second display region. The second touch sensing region is positioned to overlap with and be in the third display region. The control portion has a function of performing a step of extracting a plurality of display objects displayed in the second display region overlapping with the first touch sensing region by sensing a touch on the first touch sensing region, a step of displaying the plurality of display objects extracted from the second display region in the first display region, a step of extracting a plurality of display objects displayed in the third display region overlapping with the second touch sensing region by sensing a touch on the second touch sensing region, and a step of displaying the plurality of display objects extracted from the third display region in the first display region.

In any of the above structures, it is preferable that the touch sensor module further include a third touch sensing region. It is preferable that the first display region further include a fourth display region. The third touch sensing region is preferably positioned to overlap with and be in the fourth display region. The control portion preferably has a function of displaying a display object of an arrow in the fourth display region. The control portion preferably has a function of performing a step of moving a selection position from the second display region to the third display region in accordance with a direction shown by the display object of the arrow by sensing a touch on the third touch sensing region, and a step of changing a gray level of the third display region to show that the third display region is selected.

In any of the above structures, it is preferable that the display device include a plurality of pixels, the pixel include a first pixel circuit and a second pixel circuit, the first pixel circuit include a first display element, the second pixel circuit include a second display element, the first display element include a reflective electrode, the first display element perform display by making the reflective electrode reflect external light, the reflective electrode include an opening region or a notch region, and light emitted by the second display element be transmitted through the opening region or the notch region to perform display.

In any of the above structures, the first display element in the display device is preferably a reflective liquid crystal element.

In any of the above structures, the second display element in the display device is preferably a light-emitting element.

In any of the above structures, the display device preferably has a function of displaying an image using first light reflected from the first display element and/or second light emitted from the second display element.

In any of the above structures, it is preferable that the display device having any of the above structures further include a transistor, and the transistor include metal oxide in a semiconductor layer. In any of the above structures, the transistor including metal oxide in the semiconductor layer in the display device preferably includes a back gate.

One embodiment of the present invention is an electronic device. The electronic device preferably includes the touch panel input system having any of the above structures, a CPU, and a battery.

One embodiment of the present invention can provide a touch sensor module with a novel structure. Another embodiment of the present invention can provide a display module that has improved operability. Another embodiment of the present invention can provide an electronic device with low power consumption.

Note that the effects of one embodiment of the present invention are not limited to the above effects. The effects described above do not disturb the existence of other effects. The other effects are the ones that are not described above and are described below. The other effects are apparent from and can be derived from the description of the specification, the drawings, and the like by those skilled in the art. One embodiment of the present invention is to have at least one of the aforementioned effects and the other effects. Therefore, one embodiment of the present invention does not have the effects described above in some cases.

### BRIEF DESCRIPTION OF DRAWINGS

FIG. 1A illustrates the structure of an electronic device, FIG. 1B illustrates a touch panel, and FIG. 1C is an enlarged view of FIG. 1B.

FIG. 2 is a block diagram illustrating an electronic device.

FIGS. 3A and 3B each illustrate a touch sensor module, and FIGS. 3C and 3D each illustrate a display device.

FIGS. 4A and 4B illustrate a display module.

FIG. 5 is a flow chart showing operation of a display module.

FIGS. 6A and 6B illustrate a display module.

FIG. 7 is a flow chart showing operation of a display module.

FIGS. 8A to 8C illustrate a display module.

FIG. 9 is a flow chart showing operation of a display module.

FIG. 10 illustrates an electronic device.

FIGS. 11A and 11B are each a block diagram illustrating a display panel.

FIGS. 12A to 12C each illustrate a pixel.

FIGS. 13A to 13C each illustrate a pixel.

FIGS. 14A to 14C each illustrate a pixel.

FIG. 15 illustrates a structure of a display panel.

FIG. 16 illustrates a structure of a display panel.

FIG. 17 illustrates a structure of a display panel.

FIGS. 18A to 18C each illustrate a structure of a transistor.

FIG. 19 illustrates a structure of a display panel.

FIG. 20A illustrates a circuit of a display panel, and FIGS. 20B1 and 20B2 are top views of a pixel.

FIG. 21 illustrates a circuit of a display panel.

FIG. 22A illustrates a circuit of a display panel, and FIG. 22B is a top view of a pixel.

FIG. 23A illustrates a structure of a display device, and FIG. 23B illustrates an example of a display module.

FIG. 24 illustrates a structure of a display panel.

FIG. 25 illustrates a structure of a display panel.

FIG. 26 illustrates a structure of a display panel.

FIG. 27 illustrates a structure of a display panel.

FIG. 28 illustrates a structure of a display panel.

FIGS. 29A to 29D illustrate a structure of a display panel.

FIG. 30 shows measured results of XRD spectra of samples.

FIGS. 31A and 31B are TEM images of a sample and FIGS. 31C to 31L are electron diffraction patterns thereof.

FIGS. 32A to 32C show EDX mapping images of a sample.

FIGS. 33A to 33F illustrate structure examples of electronic devices.

### BEST MODE FOR CARRYING OUT THE INVENTION

Hereinafter, embodiments are described with reference to drawings. However, the embodiments can be implemented in many different modes, and it is readily appreciated by those skilled in the art that modes and details thereof can be changed in various ways without departing from the spirit and scope of the present invention. Therefore, the present invention should not be interpreted as being limited to the description of the embodiments below.

In the drawings, the size, the layer thickness, or the region is exaggerated for clarity in some cases. Therefore, the size, the layer thickness, or the region is not necessarily limited to the illustrated scale. Note that the drawings are schematic views showing ideal examples, and embodiments of the present invention are not limited to shapes or values shown in the drawings.

Note that in this specification, ordinal numbers such as “first”, “second”, and “third” are used in order to avoid confusion among components, and the terms do not limit the components numerically.

In this specification, terms for describing arrangement, such as “over”, “above”, “under”, and “below”, are used for convenience in describing a positional relation between components with reference to drawings. Furthermore, the positional relationship between components is changed as appropriate in accordance with a direction in which each component is described. Thus, there is no limitation on terms used in this specification, and description can be made appropriately depending on the situation.

In this specification and the like, a transistor is an element having at least three terminals of a gate, a drain, and a source. The transistor has a channel formation region between a drain (a drain terminal, a drain region, or a drain electrode) and a source (a source terminal, a source region, or a source electrode), and current can flow between the source and the drain through the channel formation region. Note that in this specification and the like, a channel formation region refers to a region through which current mainly flows.

Furthermore, functions of a source and a drain might be switched when transistors having different polarities are employed or a direction of current flow is changed in circuit operation, for example. Therefore, the terms “source” and “drain” can be switched in this specification and the like.

Note that in this specification and the like, the term “electrically connected” includes the case where components are connected through an object having any electric function. There is no particular limitation on the “object having any electric function” as long as electric signals can be transmitted and received between components that are connected through the object. Examples of an “object having any electric function” are a switching element such as a transistor, a resistor, an inductor, a capacitor, and an element with a variety of functions as well as an electrode and a wiring.

In this specification and the like, the term “parallel” indicates that the angle formed between two straight lines is greater than or equal to −10° and less than or equal to 10°, and accordingly also includes the case where the angle is greater than or equal to −5° and less than or equal to 5°. The term “perpendicular” indicates that the angle formed between two straight lines is greater than or equal to 80° and less than or equal to 100°. Thus, the case where the angle is greater than or equal to 85° and less than or equal to 950 is also included.

In this specification and the like, the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

Unless otherwise specified, off-state current in this specification and the like refers to drain current of a transistor in an off state (also referred to as a non-conducting state and a cutoff state). Unless otherwise specified, the off state of an n-channel transistor means that a voltage between its gate and source (V_{gs}) is lower than the threshold voltage Vₜₕ, and the off state of a p-channel transistor means that the gate-source voltage V_{gs} is higher than the threshold voltage Vₜₕ. For example, the off-state current of an n-channel transistor sometimes refers to a drain current that flows when the gate-source voltage V_{gs} is lower than the threshold voltage Vₜₕ.

The off-state current of a transistor depends on V_{gs} in some cases. Thus, “the off-state current of a transistor is lower than or equal to I” means “there is V_{gs} with which the off-state current of a transistor becomes lower than or equal to I” in some cases. The off-state current of a transistor may refer to off-state current at a given V_{gs}, at V_{gs} in a given range, at V_{gs} at which sufficiently small off-state current is obtained, or the like.

As an example, the assumption is made of an n-channel transistor where the threshold voltage Vₜₕ is 0.5 V and the drain current is 1×10⁻⁹ A at a voltage V_{gs} of 0.5 V, 1×10⁻¹³ A at a voltage V_{gs} of 0.1 V, 1×10⁻¹⁹ A at a voltage V_{gs} of −0.5 V, and 1×10⁻²² A at a voltage V_{gs} of −0.8 V. The drain current of the transistor is 1×10⁻¹⁹ A or lower at V_{gs} of −0.5 V or at V_{gs} in the range of −0.8 V to −0.5 V; therefore, it can be said that the off-state current of the transistor is 1×10⁻¹⁹ A or lower. Since there is V_{g}s at which the drain current of the transistor is 1×10⁻²² A or lower, it may be said that the off-state current of the transistor is 1×10⁻²² A or lower.

In this specification and the like, the off-state current of a transistor with a channel width W is sometimes represented by a current value per channel width W or by a current value per given channel width (e.g., 1 μm). In the latter case, the off-state current may be expressed in the unit with the dimension of current per length (e.g., A/μm).

The off-state current of a transistor depends on temperature in some cases. Unless otherwise specified, the off-state current in this specification may be an off-state current at room temperature, 60° C., 85° C., 95° C., or 125° C. Alternatively, the off-state current may be an off-state current at a temperature at which the reliability of a semiconductor device or the like including the transistor is ensured or a temperature at which the semiconductor device or the like including the transistor is used (e.g., temperature in the range of 5° C. to 35° C.). The state in which the off-state current of a transistor is lower than or equal to I may indicate that the off-state current of the transistor at room temperature, 60° C., 85° C., 95° C., 125° C., a temperature at which the reliability of a semiconductor device or the like including the transistor is ensured, or a temperature at which the semiconductor device or the like including the transistor is used (e.g., a temperature in the range of 5° C. to 35° C.) is lower than or equal to I at a certain V_{gs}.

The off-state current of a transistor depends on voltage V_{ds} between its drain and source in some cases. Unless otherwise specified, the off-state current in this specification may be off-state current at V_{ds} of 0.1 V, 0.8 V, 1 V, 1.2 V, 1.8 V, 2.5 V, 3 V, 3.3 V, 10 V, 12 V, 16 V, or 20 V. Alternatively, the off-state current may be an off-state current at V_{ds} at which the reliability of a semiconductor device or the like including the transistor is ensured or V_{ds} at which the semiconductor device or the like including the transistor is used. The state in which the off-state current of a transistor is lower than or equal to I may indicate that the off-state current of the transistor at V_{ds} of 0.1 V, 0.8 V, 1 V, 1.2 V, 1.8 V, 2.5 V, 3 V, 3.3 V, 10 V, 12 V, 16 V, or 20 V, at V_{ds} at which the reliability of a semiconductor device or the like including the transistor is ensured, or at V_{ds} at which the semiconductor device or the like including the transistor is used is lower than or equal to I at a certain V_{gs}.

In the above description of off-state current, a drain may be replaced with a source. That is, the off-state current sometimes refers to a current that flows through a source of a transistor in the off state.

In this specification and the like, the term “leakage current” sometimes expresses the same meaning as “off-state current”. In this specification and the like, the off-state current sometimes refers to current that flows between a source and a drain of a transistor in the off state, for example.

Note that a voltage refers to a difference between potentials of two points, and a potential refers to electrostatic energy (electric potential energy) of a unit charge at a given point in an electrostatic field. Note that in general, a difference between a potential of one point and a reference potential (e.g., a ground potential) is merely called a potential or a voltage, and “potential” and “voltage” are used as synonymous words in many cases. Therefore, in this specification, “potential” can be replaced with “voltage” and vice versa, unless otherwise specified.

### Embodiment 1

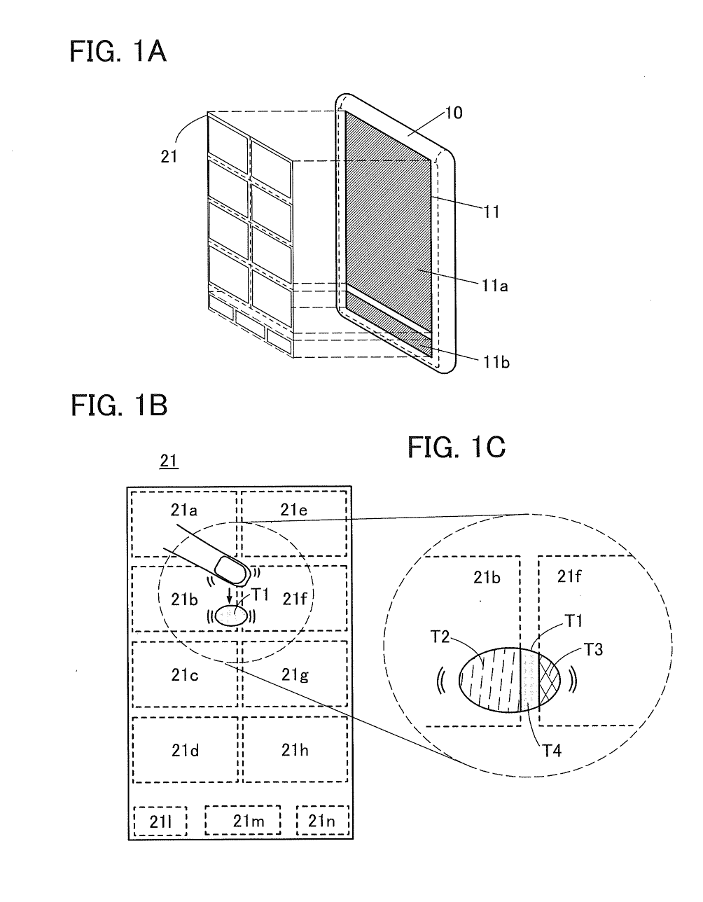

In this embodiment, a touch panel input system is described with reference to FIGS. 1A to 1C through FIG. 10.

FIG. 1A illustrates an electronic device 10. The electronic device 10 includes a display device 11, a touch panel 21, a CPU (not illustrated), a memory (not illustrated), and a communication module (not illustrated).

The display device 11 includes a display region 11a and a display region 11b. FIG. 1A illustrates an example in which a non-display region is provided between the display regions 11a and 11b; however, the non-display region is not necessarily provided. The touch panel 21 includes a region overlapping with the display device 11. The touch panel 21 includes a plurality of touch sensors and a plurality of touch sensing regions.

For the touch panel 21, any sensing method such as a projected capacitive method, a surface capacitive method, a resistive method, or an optical method can be used. By any of the methods, data can be input when an object is in contact with or approaches the touch panel. In this embodiment, the touch panel 21 using a projected capacitive method is described as an example.

FIG. 1B illustrates an example of the touch sensing regions of the touch panel 21. In FIG. 1B, the touch panel 21 includes touch sensing regions 21a to 21h and touch sensing regions 21l to 21n. The other regions are non-touch sensing regions. It is preferable that the touch sensing region be changeable depending on an application to be used.

With the touch panel 21, by a touch on a touch sensing region overlapping with an icon displayed on the display device 11, a variety of applications can be started, displayed, or controlled, for example. A distance between touch sensors is preferably determined in consideration of the contact area where a fingertip touches the touch panel 21 when the operator touches the touch panel 21. The touch panel 21 can sense not only a touch by a fingertip but also a touch by a sensing target such as a stylus.

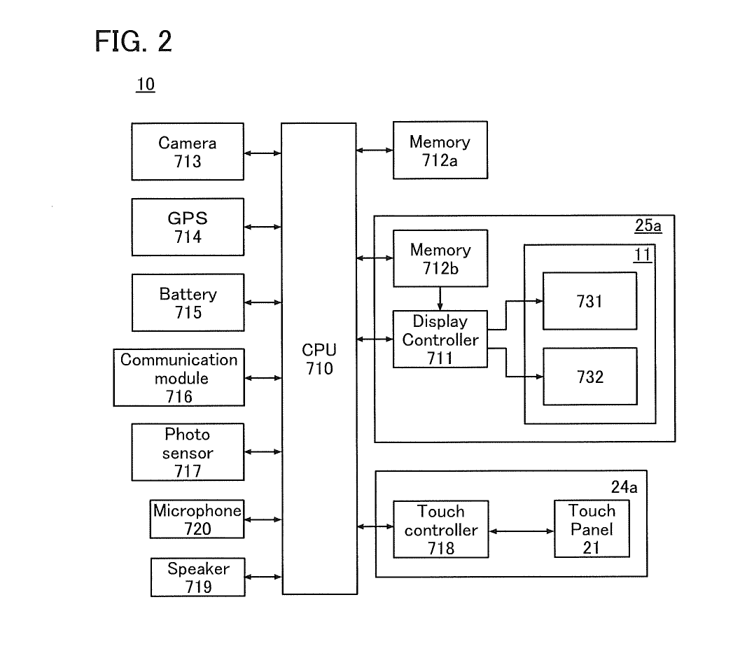

A touch controller 718 described later (see FIG. 2) controls a touched position as coordinates. An icon that is displayed on the display device 11 and has coordinates corresponding to coordinates sensed by the touch panel 21 is determined by the CPU included in the electronic device 10, whereby any of a variety of applications are operated by an application program associated with the icon.

However, it is hard for a person whose fingertips are trembled or a person whose eyesight is poor to select and touch a small icon using the touch panel 21. Even when the person intends to touch a touch sensor placed where the icon is displayed, the touched position may be deviated because of his/her trembling hand or poor eyesight. Alternatively, the person may touch it more than once because of the trembling.

For a person who has disabilities with his/her hand, touch operation with fingertips is difficult, and thus a touch with a large area such as a side of a finger is performed in some cases. Accordingly, a plurality of icons displayed adjacently are touched at the same time, which causes misoperation.

FIG. 1B illustrates an example in which an operator touches the touch sensing region 21b. An example is shown in which although he/she intends to touch the touch sensing region 21b, the position is deviated because of his/her trembling hand, so that the touch sensing regions 21b and 21f are touched at the same time. FIG. 1C is an enlarged view of the touched region.

In FIG. 1B, a range in which a touch is sensed is shown as a touched area T1. FIG. 1C is the enlarged view of T1. The touched area T1 is composed of a touched area T2 that is in the touch sensing region 21b, a touched area T3 that is in the touch sensing region 21f, and a touched area T4 that is a non-touch sensing region.

By sensing which touch sensing region is touched with the largest touched area, the touch panel 21 can identify a touch sensing region that the operator has intended to touch. To identify the touch sensing region that the operator has intended to touch, it is determined which touched area is larger, the touched area T2 or the touched area T3.

In an example illustrated in FIG. 1C, owing to the touched area T4 in the non-touch sensing region, the effective area ratio can be higher in the case of comparing the touched area T2 with the touched area T3 than in the case of comparing the touched area T2 with a touched area that is obtained by adding the touched area T4 to the touched area T3. The effective area ratio indicates a ratio between the touched areas sensed in the touch sensing regions. In FIG. 1C, the effective area ratio can be a ratio between the touched area T2 to the touched area T3.

FIG. 1C illustrates an example in which the touched area extends over the two touch sensing regions; however, the effective area ratio can be increased also in the case where the touched area extends over three or four touch sensing regions. Note that the touch sensing region can be sensed even when the non-touch sensing region is not provided.

A case where the touched position is deviated because of a trembling hand or the like is further described. A touch sensing period is a period after a touch is sensed until the sensing target leaves. With the touch sensing period, the touched areas sensed in the touch sensing regions can be time-integrated. By comparing the sizes of time-integrated touched areas, it can be determined which touch sensing region is selected.

FIG. 2 illustrates the configuration of the electronic device 10. The electronic device 10 includes a CPU 710, a memory 712a, a display device 25a, a touch sensor module 24a, a camera 713, a GPS 714, a battery 715, a communication module 716, a photosensor 717, a speaker 719, a microphone 720, and the like. The memory 712a includes a control program that can control peripheral circuits via the CPU 710.

The display device 25a includes a display controller 711, a memory 712b, and the display device 11. The display device 11 includes a light-emitting display panel 732 using a self-luminous element and a reflective liquid crystal display panel 731 that includes a reflective element capable of performing display using the reflection of external light. By sensing ambient light using the photosensor 717, the light can be modulated so that display is performed with optimal display quality.

Display using the reflective liquid crystal display panel 731 is performed in a bright environment such as an environment under sunlight. Display using the light-emitting display panel 732 is performed in an environment without external light. Hybrid display using both the reflective liquid crystal display panel 731 and the light-emitting display panel 732 can be performed in an environment with insufficiently bright external light such as an environment under a fluorescent lamp or an indoor environment.

The memory 712b functions as a frame memory for the display controller 711. The display controller 711 switches the reflective liquid crystal display panel 731 and the light-emitting display panel 732 depending on use condition, and functions as a temporary storage region of data for transmitting a signal to the display device 11.

The memory 712a or 712b is preferably an internal memory (e.g., a nonvolatile memory, an SRAM, or a DRAM) or an inserted external nonvolatile memory. Alternatively, the memory 712a or 712b may be a work memory (e.g., a nonvolatile memory, an SRAM, or a DRAM) that temporarily stores any of the control program, the application program, and data that are downloaded with a communication module. As the internal memory, a NOSRAM or a DOSRAM in which an oxide semiconductor is included in a semiconductor layer may be used.

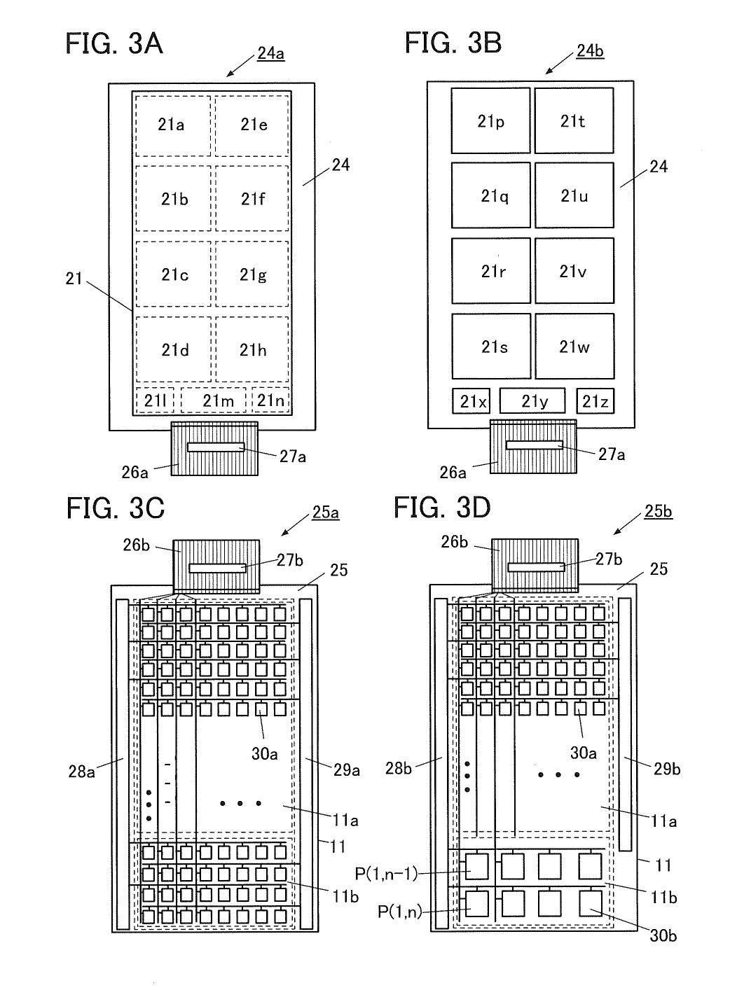

The touch sensor module 24a includes the touch controller 718 and the touch panel 21. The details of the touch sensor module are described with reference to FIGS. 3A and 3B.

FIG. 3A illustrates the touch sensor module 24a. The touch sensor module 24a includes the touch panel 21, an FPC 26a, and a touch sensor control IC 27a. Furthermore, the touch panel 21 includes the touch sensing regions 21a to 21h and the touch sensing regions 21l to 21n. Each touch sensing region includes a plurality of touch sensors.

FIG. 3B illustrates a touch sensor module 24b. The touch sensor module 24b includes touch panels 21p to 21z. Each of the touch panels 21p to 21z includes a plurality of touch sensors.

When the sizes and positions of the touch panels are fixed as in the touch sensor module 24b, each touch panel can be individually controlled. The sizes and positions of the touch panels can be the same as those of the touch sensing regions shown in FIG. 3A. In FIG. 3A, to sense a touch on a touch sensing region, touch sensing processing needs to be performed on all touch sensing regions. In contrast, in FIG. 3B, since the size of the touch panel is reduced, the amount of calculation for identifying the touched region can be reduced, whereby power consumption can be reduced.

In FIG. 3B, the touch panels 21p to 21z are formed in the same process using a semiconductor process or the like; however, the touch panels 21p to 21z may be formed in different processes and attached.

In FIGS. 3A and 3B, the touch sensor control IC 27a has a function of supplying a signal or power to the touch panel 21 and the touch panels 21p to 21z via the FPC 26a. The touch sensor control IC 27a has a function of supplying touch sensing information on the touch panel(s) to the CPU 710 via the FPC 26a. Alternatively, the touch sensor control IC 27a may have a function of calculating a touched area. Further alternatively, the touch sensor control IC 27a may supply touch sensing information to the CPU 710 via the FPC 26a, and the CPU 710 may have a function of calculating a touched area. The touch sensor control IC 27a preferably functions as the touch controller 718 in FIG. 2.

The touch sensor control IC 27a is provided over the FPC 26a by a chip on film (COF) method or the like in the examples illustrated in FIGS. 3A and 3B. Alternatively, the touch sensor control IC 27a may be provided over a substrate 24 by a chip on glass (COG) method or the like. Although the touch sensor control IC 27a is provided over the FPC 26a in the examples, the touch sensor control IC 27a may be included in a driver IC 27b described later.

The display device 25a is described with reference to FIG. 3C. The display device 25a includes the display device 11, an FPC 26b, and the driver IC 27b. The display device 11 includes a gate driver 28a, a gate driver 29a, the display region 11a, and the display region 11b. Note that the display region 11b is not necessarily provided depending on circumstances.

The display regions 11a and 11b illustrated in FIG. 3C include a plurality of pixels 30a, a plurality of scan lines, and a plurality of signal lines. A scan line and a signal line are electrically connected to the pixel 30a.

The display device 11 is positioned to overlap with the touch panel 21 of FIG. 3A, as illustrated in FIG. 1A. To overlap with the display regions 11a and 11b, the touch panel 21 is positioned, and the touch sensing regions 21a to 21h and the touch sensing regions 21l to 21n are arranged in the touch panel 21. Alternatively, the touch panels 21p to 21z illustrated in FIG. 3B may be arranged to overlap with the display device 11.

A display device 25b is described with reference to FIG. 3D. The display device 25b includes the display device 11, the FPC 26b, and the driver IC 27b. The display device 11 includes a gate driver 28b, a gate driver 29b, the display region 11a, and the display region 11b.

In FIGS. 3C and 3D, the driver IC 27b has a function of supplying a signal or power to the display device 11 via the FPC 26b. The CPU 710 can control the driver IC 27b via the display controller 711. The driver IC 27b preferably functions as a source driver that controls the signal lines. Alternatively, the driver IC 27b preferably has a digital-analog conversion function. In the case where the driver IC 27b has a digital-analog conversion function, a digital signal transmitted from the CPU 710 is converted into an analog signal, and the analog signal can be supplied to the signal lines.

In the examples illustrated in FIGS. 3C and 3D, the driver IC 27b is provided over the FPC 26b by a COF method or the like. Alternatively, the driver IC 27b may be provided over a substrate 25 by a COG method or the like. Although the driver IC 27b is provided over the FPC 26b in the examples, the driver IC 27b is not necessarily provided when not needed.

The display region 11a illustrated in FIG. 3D includes the plurality of pixels 30a, a plurality of scan lines electrically connected to the gate driver 28b, a plurality of scan lines electrically connected to the gate driver 29b, and a plurality of signal lines. The plurality of pixels 30a are electrically connected to the scan lines electrically connected to the gate driver 28b or electrically connected to the scan lines electrically connected to the gate driver 29b.

The display region 11b illustrated in FIG. 3D includes a plurality of pixels 30b, a plurality of scan lines electrically connected to the gate driver 28b, and a plurality of signal lines. The scan lines electrically connected to the gate driver 28b are electrically connected to the pixels 30b. The signal lines are electrically connected to the pixels 30b as well as the pixels 30a electrically connected to the gate driver 28b.

In FIG. 3D, display in the display region 11a is updated by driving the gate drivers 28b and 29b. Display in the display region 11b is updated by driving the gate driver 28b.

The resolution of display of the pixel 30a differs from that of the pixel 30b because of the difference in size of the pixels. Thus, the amount of data needed for display in the display region 11b can be reduced. In the case where display is performed only in the display region 11b, display data to be updated also can be reduced by driving only the gate driver 28b; thus, power consumption can be reduced.

The gate drivers illustrated in FIGS. 3C and 3D can select scan lines to update display. The gate driver preferably includes a decoder circuit. When the gate driver 28b includes the decoder circuit, it can selectively update only display in the display region 11b. Note that the gate driver can update display also with a configuration using a shift register circuit.

Even in the case where display in the display regions 11a and 11b is updated, display data of the display region 11b is smaller in FIG. 3D than in FIG. 3C, and thus power consumption in FIG. 3D can be reduced.

The pixel 30b can be larger than the pixel 30a in size. Thus, a storage capacitor for storing display data can be large. When the gray level of display is changed due to leakage of charge from the storage capacitor, a flicker occurs at the time of update of display of a still image. When the storage capacitor is made larger, a change in gray level of display that causes a flicker can be reduced. Thus, the pixel 30b is suitable for displaying text data or a still image, and when the electronic device is shifted to a standby state, the quality of display can be maintained even in the case where power gating is performed on the gate driver.

When the touch sensor module of FIG. 3B and the display device of FIG. 3D are combined, as illustrated in FIG. 1A, a region not including a pixel can be provided between the display regions 11a and 11b. A display device including two display regions can be fabricated using the gate drivers 28b and 29b. Pixels may be continuously arranged between the display regions 11a and 11b. The display device 25b can include display regions whose resolutions are different from each other. The same effect can be obtained by combining the touch sensor module of FIG. 3A and the display device of FIG. 3D.

The touch sensor module of FIG. 3A or 3B and the display device of FIG. 3C or 3D can be used in combination as appropriate.

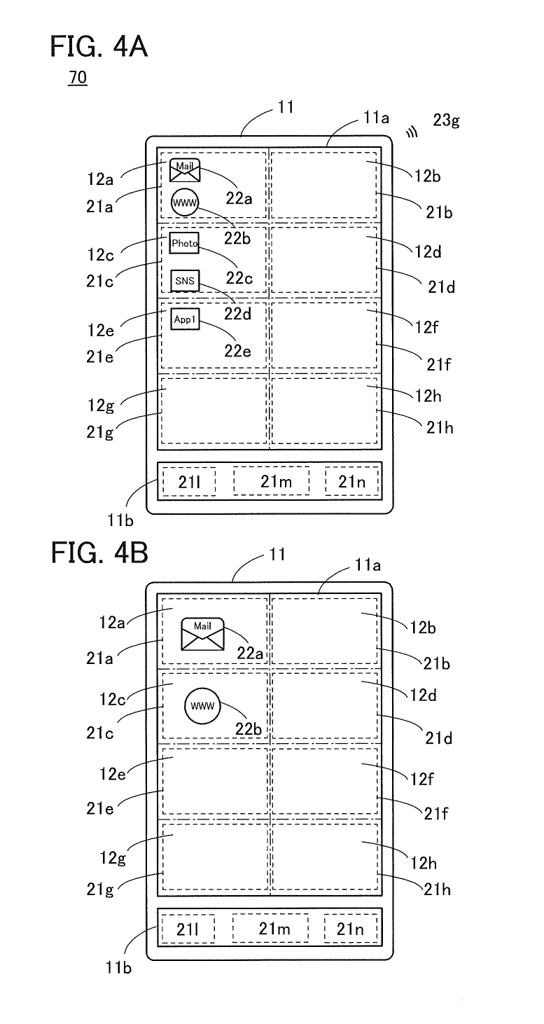

The operation of a touch panel input system is described using a display module 70 with reference to FIGS. 4A and 4B through FIG. 10. As an example, the display module 70 described with reference to FIGS. 4A and 4B includes the touch sensor module 24a illustrated in FIG. 3A and the display device 25a illustrated in FIG. 3C.

FIG. 4A illustrates an example in which a plurality of icons 22a to 22e are displayed on the display device 11. The display device 11 includes the display regions 11a and 11b. Furthermore, the display region 11a includes a plurality of display regions 12a to 12h (regions denoted by dashed-dotted lines in FIG. 4A), and the touch panel 21 includes the touch sensing regions 21a to 21h. The touch sensing regions 21l to 21n are positioned to overlap with the display region 11b. Hereinafter, boundaries of the display regions 12a to 12h are denoted by dashed-dotted lines, and boundaries of the touch sensing regions 21a to 21h are denoted by dashed lines.

The display device 11 includes the plurality of pixels 30a as illustrated in FIG. 3C, and can perform display as one display portion. The display regions 12a to 12h included in the display region 11a are each a unit for control.

In the display region 11b, a plurality of touch sensing regions overlapping with the display region 11b are arranged. Text, a still image, or the like is preferably displayed in the display region 11b. A variety of execution commands such as boot-up, confirmation, cancel, and mode change can be associated with the touch sensing regions 21l to 21n.

A variety of execution commands such as boot-up, confirmation, cancel, and mode change are processed via the CPU 710 by the control program stored in the memory 712a or the like. By the execution command processed by the control program, display in the display regions 11a and 11b can be updated. An application program or data to be displayed may be received by the communication module 716 via a carrier wave 23g.

Execution commands associated with the touch sensing regions 21l to 21n are preferably switched to an execution command needed for the display content of the display device 11 as appropriate.

An example in which the plurality of icons 22a to 22e are displayed in the display region 11a is described. The icons are arranged at regular intervals. As an example, the icons 22a and 22b are displayed in the display region 12a. The touch sensing region 21a is arranged to overlap with the display region 12a.

An operator touches the touch sensing region 21a to execute an application program associated with the icon 22b. Even when he/she touches a slightly deviated position as described with reference to FIG. 1C, a touch on the touch sensing region 21a can be sensed.

The touch sensing region 21a notifies the CPU 710 via the touch controller 718 that the touch is sensed. The control program that controls the CPU 710 extracts icons displayed in the display region 12a overlapping with the touch sensing region 21a on which a touch is sensed by the touch controller 718.

The icons extracted by the control program are displayed as illustrated in FIG. 4B. In FIG. 4B, in accordance with the number of icons displayed in the display region 12a in FIG. 4A, the icons are regenerated in some of the display regions 12a to 12h. Each of the display regions displays one of the icons displayed in the display region 12a in FIG. 4A.

When the operator touches the icon 22b displayed in the display region 12c, the icon 22b can be selected. The application program may be executed by double-clicking the touch sensing region 21c or touching any of the touch sensing regions 21l to 21n that is associated with the execution command.

With the touch panel input system illustrated in FIGS. 4A and 4B, a target icon can be surely selected even when touch operation is unstable because of a trembling arm, poor eyesight, or the like. The target icon can be surely selected and the application program can be surely executed even when an operator operates an electronic device while he/she is on a vibrating vehicle or is moving. The “vehicle” means a vehicle including a motor or an engine such as a car, a train, an airplane, or a ship. Furthermore, “moving” means walking, running, or riding a bicycle or the like, which does not include a motor or an engine.

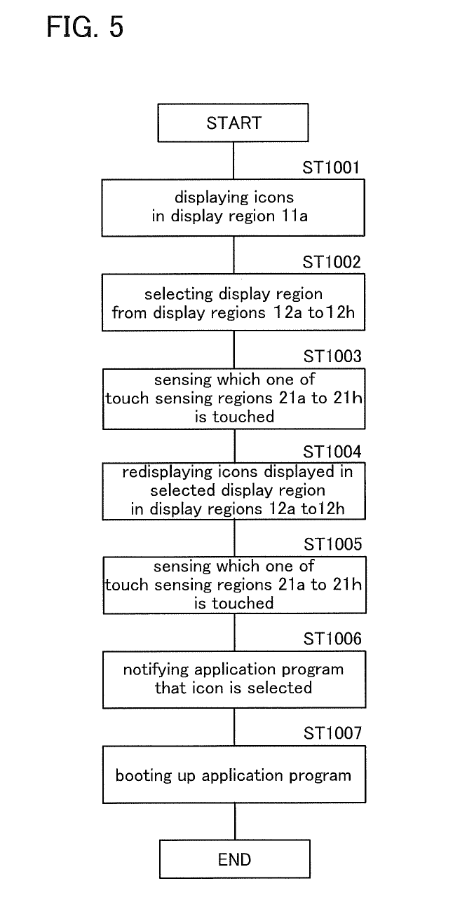

FIG. 5 shows a flow chart of operation of the display module illustrated in FIGS. 4A and 4B. As an example, steps of selecting the icon 22b are described.

ST1001 is a step of displaying a plurality of icons in the display region 11a as illustrated in FIG. 4A.

ST1002 is a step in which an operator touches the icon 22b that is to be executed or the periphery of the icon 22b.

ST1003 is a step in which the touch sensing region 21a senses a touch and the control program is notified of the sensed information via the CPU.

ST1004 is a step in which the control program extracts icons in the display region 12a overlapping with the touch sensing region 21a, and in accordance with the number of extracted icons, the icons are displayed in some of the display regions 12a to 12h. In FIG. 4B, the icon 22a is displayed in the display region 12a, and the icon 22b is displayed in the display region 12c. Note that it is preferable that a touch on a display region in which the icon is not displayed be invalidated in the case where the number of the extracted icons is smaller than that of the display regions 12a to 12h. By invalidating the touch on the display region in which the icon is not displayed in the case where the number of the extracted icons is smaller than that of the display regions 12a to 12h it, a malfunction caused by a touch on the display region in which the icon is not displayed can be prevented. Moreover, the display region in which the icon is not displayed may be associated with a function of canceling the selection of the display region selected in ST1002. Alternatively, an icon for canceling can be further added.

ST1005 is a step in which the touch sensing region 21c senses a touch, the control program is notified of the sensed information via the CPU, and the selected icon is determined. In FIG. 4B, the control program is notified that the icon 22b displayed in the display region 12c is selected.

ST1006 is a step of notifying the application program via the CPU that the selected icon 22b is double-clicked. Alternatively, ST1006 is a step of notifying the application program, by a touch on the touch sensing region 21m that is associated with the execution command, via the CPU that the icon 22b is selected.

ST1007 is a step of booting up the application program associated with the selected icon 22b.

By performing the steps shown in FIG. 5, a touch panel input system that can surely select and boot up an application program can be provided. Although the execution command is associated with the touch sensing region 21in in the flow chart shown in FIG. 5, the execution command may be associated with the touch sensing region 21l or the touch sensing region 21n. The commands associated with the touch sensing regions 21l to 21n can be set by the control program as appropriate.

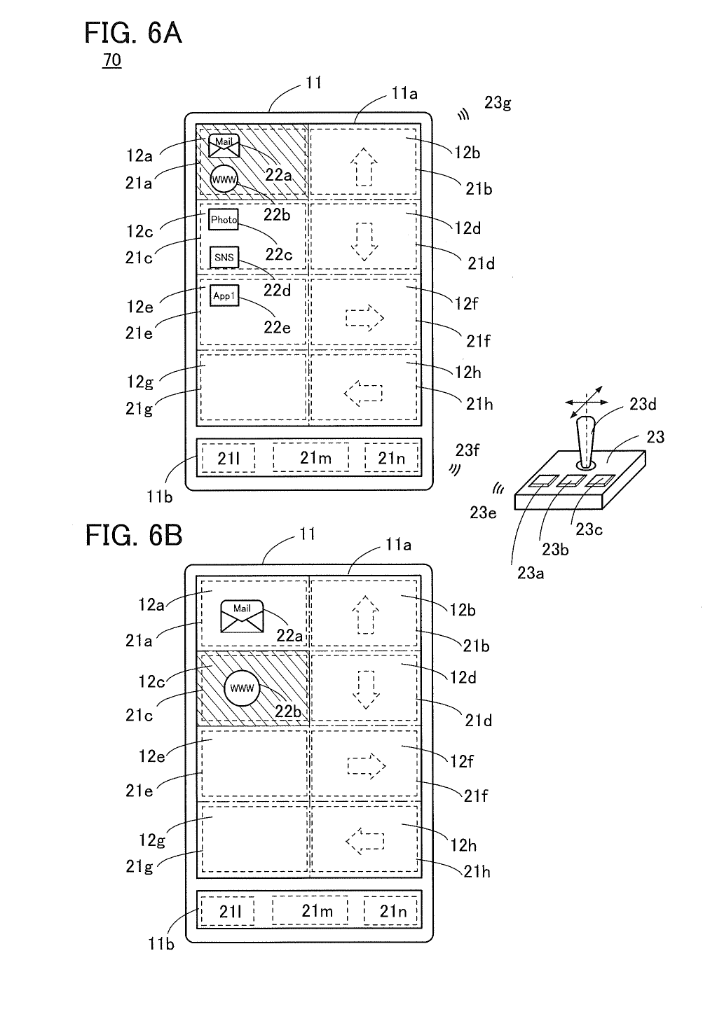

An operation of the touch panel input system that is different from that of FIGS. 4A and 4B is described using the display module 70 with reference to FIGS. 6A and 6B.

The display module 70 illustrated in FIG. 6A displays arrows, and the arrows function as up, down, left and right cursors. Display can be performed by superimposing the arrows on an image that is displayed in the display region 11a. FIG. 6A illustrates an example in which the arrows showing different directions are superimposed on an image displayed in the display regions 12b, 12d, 12f, and 12h. Only the outlines of the arrows may be shown or semi-transmissive display may be performed for the arrows by changing the gray levels of inner regions surrounded by the outlines. Furthermore, it is preferable that touch sensing is valid only in the display regions in which the arrows are displayed. In the case where touch sensing is valid only in the display regions in which the arrows are displayed, a malfunction caused by a touch on a display region other than the display regions in which the arrows are displayed can be prevented.

In regions overlapping with the display regions 12b, 12d, 12f, and 12h in which the arrows are displayed, the touch sensing regions 21b, 21d, 21f, and 21h are positioned respectively. By a touch on any of the display regions in which the arrows are displayed, it can be clearly shown which one is selected from the display regions 12a to 12h. By changing the gray level of display in the selected display region, the selection of the display region can be shown.

FIG. 6A shows that the display region 12a (shown by hatching) is selected. Any one of the display regions in which the arrows are displayed senses a touch, and the control program controls the display controller 711 via the CPU, so that the gray level of display of the selected display region can be changed. The gray level of display may be multiplied by a specified coefficient or a specified gray level may be added to the gray level to obtain the gray level of display after selection.

By a touch on the display region in which the arrow is displayed, a selection position can be moved from the selected display region 12a in the direction of the arrow. For example, when the display region 12f is touched while the display region 12a is in a selected state, the selection position moves to the display region 12b that is positioned on the right side. Then, the display region 12d is touched, whereby the selection position moves to the display region 12d that is positioned on the downside.

Thus, by associating the specified touch sensing regions with function that correspond to cursors indicating moving, the display region can be selected. Moreover, by a touch on any of the touch sensing regions 21l to 21n that is associated with the confirmation command and overlaps with the display region 11b, icons displayed in the selected display region are rearranged and displayed as illustrated in FIG. 6B.

In FIG. 6B, the display region can be selected by a touch on the display regions in which the arrows are displayed as in FIG. 6A. Furthermore, by a touch on any of the touch sensing regions 21l to 21n that is associated with the execution command, the application program associated with the icon 22b can be executed.

The control program can transmit and receive information to/from a peripheral device 23 illustrated in FIG. 6A using the communication module 716 via the CPU. The peripheral device 23 includes a joystick 23d, a switch 23a having the same function as the touch sensing region 21l, a switch 23b having the same function as the touch sensing region 21m, and a switch 23c having the same function as the touch sensing region 21n.

The operation of the joystick 23d can have the same function as the touch sensing regions functioning as cursors. The switches 23a to 23c have the same functions as the touch sensing regions 21l to 21n, respectively.

The communication module 716 can transmit and receive operation information, the control program, display data, or the like using carrier waves 23e and 23f and the carrier wave 23g. The communication module 716 can use a communication standard developed by IEEE such as a wireless local area network (LAN), Wi-Fi (registered trademark), Bluetooth (registered trademark), or ZigBee (registered trademark).

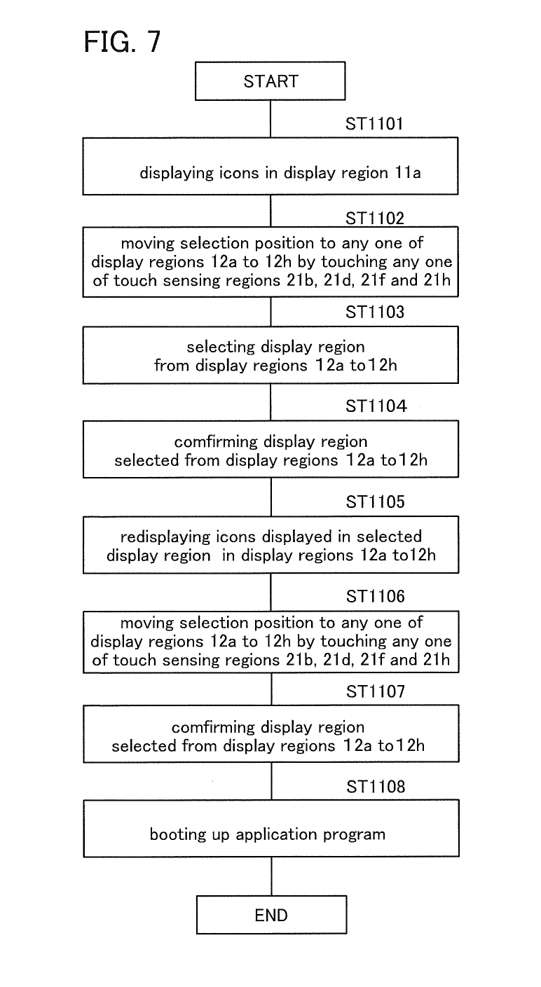

FIG. 7 shows a flow chart of operation of the display module illustrated in FIGS. 6A and 6B. As an example, steps of selecting the icon 22b are described.

ST1101 is a step of displaying a plurality of icons in the display region 11a as illustrated in FIG. 6A.

ST1102 is a step in which the operator touches any of the display regions in which the arrows are displayed, whereby the selection position is moved to any one of the display regions 12a to 12h.

ST1103 is a step in which the control program changes, via the CPU, the gray level of the display region 12a in which the icon 22b to be executed is displayed.

ST1104 is a step of notifying the control program via the CPU, by a touch on any of the touch sensing regions 21l to 21n that is associated with the confirmation command, that the display region 12a is selected by the operator.

ST1105 is a step in which the control program extracts icons displayed in the selected display region 12a, and in accordance with the number of extracted icons, the icons are displayed in some of the display regions 12a to 12h. In FIG. 6B, the icon 22a is displayed in the display region 12a, and the icon 22b is displayed in the display region 12c. Note that it is preferable that a touch on a display region in which the icon is not displayed be invalidated in the case where the number of the extracted icons is smaller than that of the display regions 12a to 12h. By invalidating the touch on the display region in which the icon is not displayed in the case where the number of the extracted icons is smaller than that of the display regions 12a to 12h, a malfunction caused by a touch on the display region in which the icon is not displayed can be prevented. Moreover, the display region in which the icon is not displayed may be associated with a function of canceling the selection of the display region selected in ST1104. Alternatively, an icon for canceling can be further added.

ST1106 is a step in which the operator touches any of the display regions in which the arrow is displayed, so that any of the display regions 12a to 12h is selected. FIG. 6B shows that the icon 22b displayed in the display region 12c is selected.

ST1107 is a step in which any of the touch sensing regions 21l to 21n that is associated with the execution command is touched, so that the application program is notified via the CPU that the icon 22b displayed in the display region 12c is selected by the operator.

ST1108 is a step of booting up the application program associated with the selected icon.

By performing the steps shown in FIG. 7, a touch panel input system that can surely select and boot up an application program can be provided. In the flow chart shown in FIG. 7, as an example, the confirmation command is associated with the touch sensing region 21l, and the execution command is associated with the touch sensing region 21m. Alternatively, the confirmation command and the execution command may be associated with the same touch sensing region. The commands associated with the touch sensing regions 21l to 21n can be set by the control program as appropriate.

The processing illustrated by the flow chart shown in FIG. 7 can be employed also in the case where the peripheral device 23 including the joystick 23d is used.

The touch panel input systems illustrated in FIGS. 4A and 4B and FIGS. 6A and 6B can be switched by a mode selection function associated with any of the touch sensing regions 21l to 21n. By switching the touch panel input systems illustrated in FIGS. 4A and 4B and FIGS. 6A and 6B, a comfortable touch input interface matching the operator's conditions can be provided.

The arrows illustrated in FIGS. 6A and 6B may be displayed using a light-emitting element, and display in the other portions may be performed using a reflective liquid crystal element. The gray level of the selected display region is not necessarily changed to a gray level obtained by calculation, but light or color may be modulated using a light-emitting element. A display panel including a light-emitting element and a reflective liquid crystal element is described in detail in Embodiment 2.

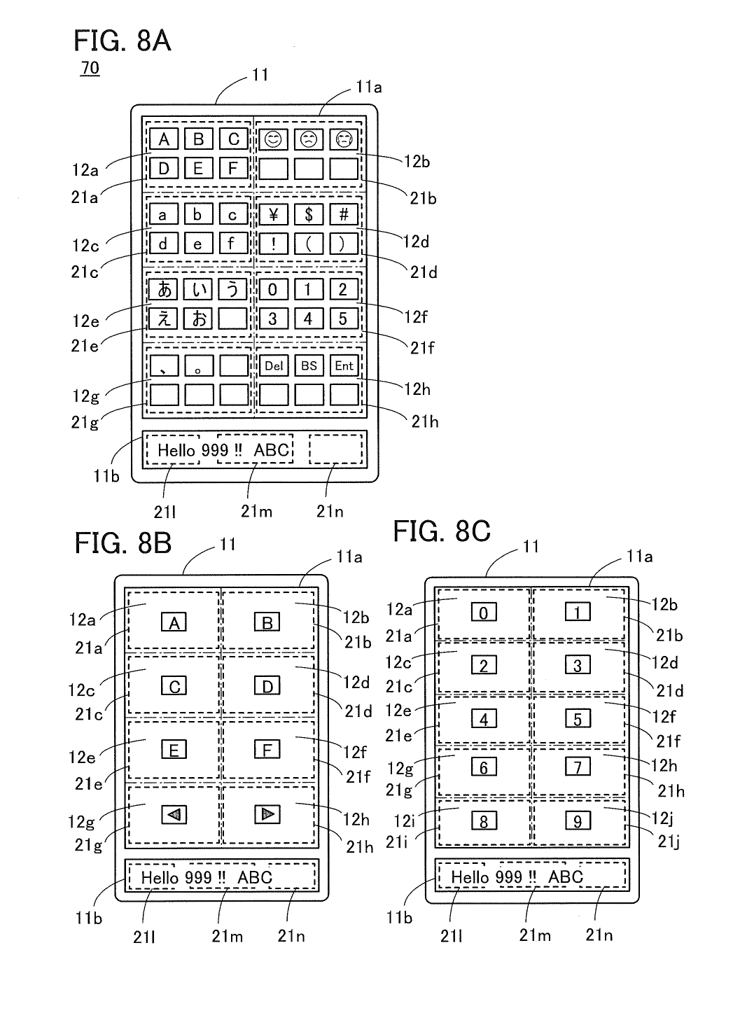

A character input system using the touch panel input systems illustrated in FIGS. 4A and 4B and FIGS. 6A and 6B is described with reference to FIGS. 8A to 8C. FIG. 8A illustrates an example in which a character input screen is displayed in the display region 11a of the display device 11. A character input method using the touch panel input system described with reference to FIGS. 4A and 4B is described as an example. Characters can be easily input also in the case of using the touch panel input system described with reference to FIGS. 6A and 6B.

By a touch on a character input object called by the application program or a touch on any of the touch sensing regions 21l to 21n that is associated with the confirmation command, characters can be input.

Alternatively, by moving the selection position between display regions one by one using the touch sensing regions functioning as cursors illustrated in FIGS. 6A and 6B and selecting an icon, the character input object is called by the application program associated with the icon, so that characters can be input

The control program preferably controls character input and display of the input character string via the CPU 710. When the control program controls character input and display of the input character string via the CPU 710, the control program can be employed for a variety of application programs. Note that when character attributes or the like are controlled by an application program, the application program can control character input and display of the input character string via the CPU 710.

In FIG. 8A, the display region 11a includes the display regions 12a to 12h. The display regions are classified according to the character attributes, so that some of the character attributes are displayed. The display regions 12a to 12h include the touch sensing regions 21a to 21h that overlap with the display regions.

Examples of the character attributes displayed in the display region 11a are described. Uppercase alphabets are displayed in the display region 12a, Emoji (pictograms) are displayed in the display region 12b, lowercase alphabets are displayed in the display region 12c, symbols are displayed in the display region 12d, hiragana letters (one of Japanese syllabaries) are displayed in the display region 12e, numbers are displayed in the display region 12f, symbols such as punctuation marks are displayed in the display region 12g, and function keys are displayed in the display region 12h. The character attributes displayed in the display regions 12a to 12h are not limited to the above and may be different.

Characters selected in the display region 11a are displayed in the display region 11b. FIG. 8A illustrates an example in which an input character string consisting of alphabets, numbers, and symbols is displayed. If needed, conversion can be made by a touch on a touch sensing region associated with any of the touch sensing regions 21l to 21n.

For example, a function of inserting a line break in the input string displayed in the display region 11b can be associated with the touch sensing region 21l. A function of converting characters can be associated with the touch sensing region 21m. A function of returning to the initial screen of the character input screen and a function of closing the character input screen can be associated with the touch sensing region 21n. One embodiment of the present invention is not limited thereto, and other functions may be associated with the touch sensing regions 21l to 21n.

Another function executed by concurrent touches on a plurality of touch sensing regions may be associated with the plurality of touch sensing regions. For example, a function of transmitting the input character string from the character input object to the application program by a touch on the touch sensing regions 21l and 21m at the same time can be associated with the touch sensing regions 21l and 21m.

FIG. 8B illustrates display in the case where the operator touches the touch sensing region 21a overlapping with the display region 12a in FIG. 8A. Uppercase alphabets are displayed in the display region 12a, and a display list of uppercase alphabets is associated with the display region 12a.

In FIG. 8B, the display region 12g has a function of displaying the previous set of alphabets. In the case where alphabets A, B, C, D, E, and F are displayed in the display regions 12a to 12f as illustrated in FIG. 8B, displaying the previous set of alphabets means displaying alphabets U, V, W, X, Y, and Z by a touch on the display region 12g. The display region 12h has a function of displaying the next set of alphabets. Displaying the next set of alphabets means displaying alphabets G, H, I, J, K, and L by a touch on the display region 12h.

When the operator touches a display region in which any character is displayed, the selected character is displayed in the display region 11b.

FIG. 8C illustrates display in the case where the operator touches the touch sensing region 21f overlapping with the display region 12f in FIG. 8A. Numbers are displayed in the display region 12f, and a display list of numbers is associated with the display region 12f. In FIG. 8C, unlike in FIG. 8B, the display region 11a is divided into ten and includes the display regions 12a to 12j. The touch sensing regions 21a to 21h and touch sensing regions 21i and 21j are positioned to overlap with the display regions 12a to 12h and display regions 21i and 21j.

In the case where the touch panel of the touch sensor module 24a that is described with reference to FIG. 3A is used, the touch sensing regions can be arranged to match the display contents. With a function of displaying the previous or next set of alphabets as illustrated in FIG. 8B, the display list associated with the display regions 12a to 12h can be displayed using the touch panel of the touch sensor module 24b that is described with reference to FIG. 3B.

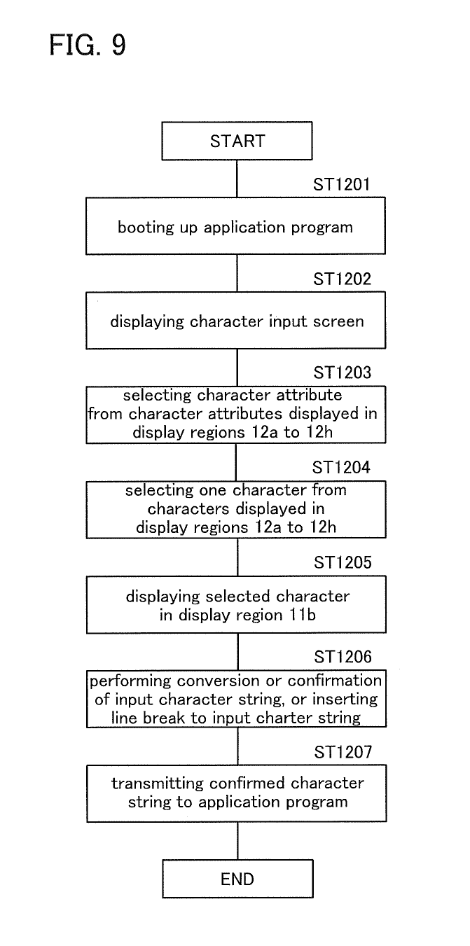

FIG. 9 shows a flow chart of operation of the display module illustrated in FIGS. 8A and 8B.

ST1201 is a step in which an application program is booted up by the touch panel input system described with reference to FIGS. 4A and 4B or FIGS. 6A and 6B.

ST1202 is a step in which a character input screen is displayed.

ST1203 is a step in which the operator touches any of the touch sensing regions 21a to 21h overlapping with the display regions 12a to 12h in which some character attributes are displayed to select the character attribute. Then, one character with the selected character attribute is displayed in each of the display regions 12a to 12h.

ST1204 is a step in which the operator selects one character from the characters displayed in the display regions 12a to 12h. In the case where the character that the operator intends to select is not displayed in the display regions 12a to 12h, the character can be searched by a touch on the symbol indicating “next” or “previous” associated with any of the display regions.

ST1205 is a step in which the operator touches a character displayed in the display region, so that an application program is notified of the information of the selected character via the CPU. The selected character is displayed in the display region 11b by the application program.

ST1206 is a step of performing conversion or confirmation of the input character string or insertion of a line break to the input character string using functions associated with the touch sensing regions 21l to 21n.

ST1207 is a step in which the character string that is displayed in the display region 11b and is confirmed is transmitted to the application program. After the transmission, the character input system is terminated, and the screen is returned to the display screen of the application program.

By performing the steps shown in FIG. 9, the character input system capable of performing character input surely can be provided for the character input object of the application program.

A function of inserting a line break is associated with the touch sensing region 21l. A function of converting characters is associated with the touch sensing region 21m. A function of returning to the initial screen of the character input screen and a function of closing the character input screen are associated with the touch sensing region 21n. A function of transmitting the input character string to the application program by a touch on two touch sensing regions, i.e., the touch sensing regions 21l and 21m at the same time is associated with the touch sensing regions 21l and 21m. However, functions associated with the touch sensing regions are not limited thereto, and it is preferable that the functions be set by an application program as appropriate.

Even in an electronic device that has a display region having a limited area, such as a smartphone, characters can be surely input using the character input system illustrated in FIGS. 8A to 8C. Stable character input can be achieved by displaying the selected character big and enlarging touch sensing regions.

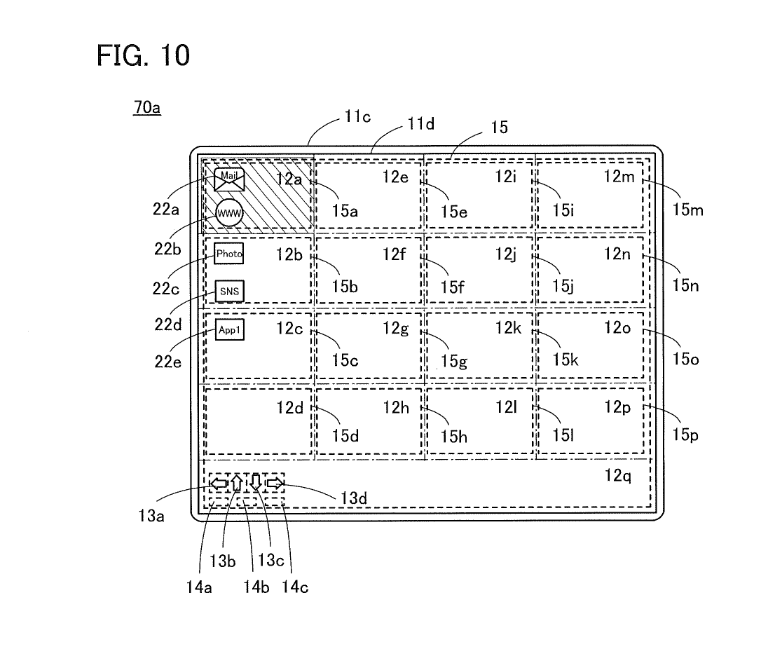

FIG. 10 illustrates a display module 70a that is used for a tablet, a notebook personal computer, or the like. Compared to a smartphone or the like, the display module 70a has a large display region. However, the arm needs to be moved large when the operation range is expanded; thus, there is a problem in operability for an operator with not only a trembling arm but also a narrow movable range due to a stiff arm. Furthermore, an electronic device having a large screen has too large a range of the touch panel, and thus there is a problem in operation with fingers.

Even when a large display region and a large touch sensing region are included like in the display module 70a, the display module can be operated easily by using the touch panel input system described with reference to FIGS. 4A and 4B or FIGS. 6A and 6B. The method for operating the display module including a large display region is described using the touch panel input system described with reference to FIGS. 6A and 6B, as an example.

The display module 70a illustrated in FIG. 10 includes a display device 11c and a touch panel 15. The display device 11c includes a display region 11d. The display region 11d includes the display regions 12a to 12j and display regions 12k to 12q. The touch panel 15 includes touch sensing regions 15a to 15p, touch sensing regions 13a to 13d, and touch sensing regions 14a to 14c.

The touch sensing regions 15a to 15p are positioned to overlap with the display regions 12a to 12p. The touch sensing regions 13a to 13d and the touch sensing regions 14a to 14c are positioned to overlap with the display region 12q.

Arrows are displayed in the display region 12q overlapping with the touch sensing regions 13a to 13d. The arrows function as up, down, left and right cursors. The arrows can be displayed by superimposing the arrows on an image that is displayed in the display region 12q. FIG. 10 illustrates an example in which the arrows showing different directions are superimposed on an image displayed in the display region 12q.

Semi-transmissive switches can be displayed in the display region 12q overlapping with the touch sensing regions 14a to 14c by changing the gray levels. A variety of functions can be associated with the touch sensing regions 14a to 14c, like the touch sensing regions 21l to 21n. The arrows or the semi-transmissive switches can be displayed using a light-emitting element described in Embodiment 2.

Thus, like the display module 70 illustrated in FIGS. 6A and 6B, the display module 70a illustrated in FIG. 10 can be controlled using the touch panel input system. In the display module 70a, all the operation regions are placed in part of the display region 11d. Thus, an easy-to-use touch panel input system with which a large movement is not required can be provided for an electronic device having a large display region, such as a tablet, a notebook personal computer, or a large monitor.

### Embodiment 2

In this embodiment, a display device having the configuration of the display region 11a described in Embodiment 1 is described.

A display device of one embodiment of the present invention includes a first display element that reflects visible light and a second display element that emits visible light.

The display device has a function of displaying an image using one or both of first light reflected by the first display element and second light emitted by the second display element. Alternatively, the display device has a function of producing gray levels by controlling the amount of the first light reflected by the first display element and the amount of the second light emitted by the second display element.

The display device preferably includes first pixel circuits each of which produces gray levels by controlling the amount of light reflected by the first display element and second pixel circuits each of which produces gray levels by controlling the amount of light emitted by the second display element. The first pixel circuits and the second pixel circuits are arranged, for example, in a matrix to form a display portion.

The first pixel circuits and the second pixel circuits are preferably arranged at regular intervals in a display region. The first pixel circuit and the second pixel circuit adjacent to each other can be collectively referred to as a pixel.

Furthermore, the first pixel circuits and the second pixel circuits are preferably mixed in the display region of the display device. In that case, an image displayed only by a plurality of first pixel circuits, an image displayed only by a plurality of second pixel circuits, and an image displayed by both the plurality of first pixel circuits and the plurality of second pixel circuits can be displayed in the same display region, as described later.

As the first display element included in the first pixel circuit, an element that performs display by reflecting external light can be used. Such an element does not include a light source and thus power consumption in display can be significantly reduced.

As the first display element, a reflective liquid crystal element can typically be used. Alternatively, as the first display element, an element using a microcapsule method, an electrophoretic method, an electrowetting method, an Electronic Liquid Powder (registered trademark) method, or the like can be used, other than a Micro Electro Mechanical Systems (MEMS) shutter element or an optical interference type MEMS element.

As the second display element included in the second pixel circuit, an element that includes a light source and performs display using light from the light source can be used. It is particularly preferable to use a light-emitting element in which light emission from a light-emitting substance can be extracted by application of an electric field. Since the luminance and the chromaticity of light emitted from such a pixel circuit are not affected by external light, an image with high color reproducibility (a wide color gamut) and a high contrast, i.e., a clear image can be displayed.

As the second display element, a self-luminous light-emitting element such as an organic light-emitting diode (OLED), a light-emitting diode (LED), and a quantum-dot light-emitting diode (QLED) can be used. Alternatively, a combination of a backlight as a light source and a transmissive liquid crystal element that controls the amount of transmitted light emitted from a backlight may be used as the second display element included in the second pixel circuit.

The first pixel circuit can include subpixels that emit white (W) light or subpixels that emit light of three colors of red (R), green (G), blue (B), for example. The second pixel circuit can also include subpixels which emit white (W) light or subpixels which emit light of three colors of red (R), green (G), and blue (B), for example. Note that the first pixel circuit and the second pixel circuit may each include subpixels of four colors or more. As the number of kinds of subpixels increases, power consumption can be reduced and color reproducibility can be improved.

In one embodiment of the present invention, switching between a first mode in which an image is displayed by the first pixel circuits, a second mode in which an image is displayed by the second pixel circuits, and a third mode in which an image is displayed by the first pixel circuits and the second pixel circuits can be performed.

In the first mode, an image is displayed using light reflected by the first display element. The first mode is a driving mode with extremely low power consumption because a light source is unnecessary, and is effective in the case where, for example, external light has a sufficiently high illuminance and is white light or light near white light. The first mode is a display mode suitable for displaying text information of a book or a document, for example. The first mode can offer eye-friendly display owing to the use of reflected light and thus has an effect of being unlikely to cause eyestrain.

In the second mode, an image is displayed using light emitted by the second display element. Thus, an extremely clear image (with a high contrast and high color reproducibility) can be displayed regardless of the illuminance and chromaticity of external light. For example, the second mode is effective in the case where the illuminance of external light is extremely low, such as during the nighttime or in a dark room. When a bright image is displayed under weak external light, a user may feel that the image is too bright. To prevent this, an image with reduced luminance is preferably displayed in the second mode. In that case, not only a reduction in brightness but also low power consumption can be achieved. The second mode is a mode suitable for displaying a vivid image and a smooth moving image, for example.

In the third mode, display is performed using both light reflected by the first display element and light emitted by the second display element. Specifically, the display device is driven so that light emitted from the first pixel circuit and light emitted from the second pixel circuit adjacent to the first pixel circuit are mixed to express one color. A clearer image than that in the first mode can be displayed and power consumption can be lower than that in the second mode. For example, the third mode is effective when the illuminance of external light is relatively low, such as under indoor illumination or in the morning or evening, or when the external light does not represent a white chromaticity. Furthermore, the use of mixed light of reflected light and emitted light enables display of an image like a real painting.

Note that it is preferable that idling stop (IDS) driving be performed in the first mode and/or the third mode because a reduction in power consumption of the display device can be achieved.

More specific structure examples are described below with reference to drawings.

### Structure Example of Display Device

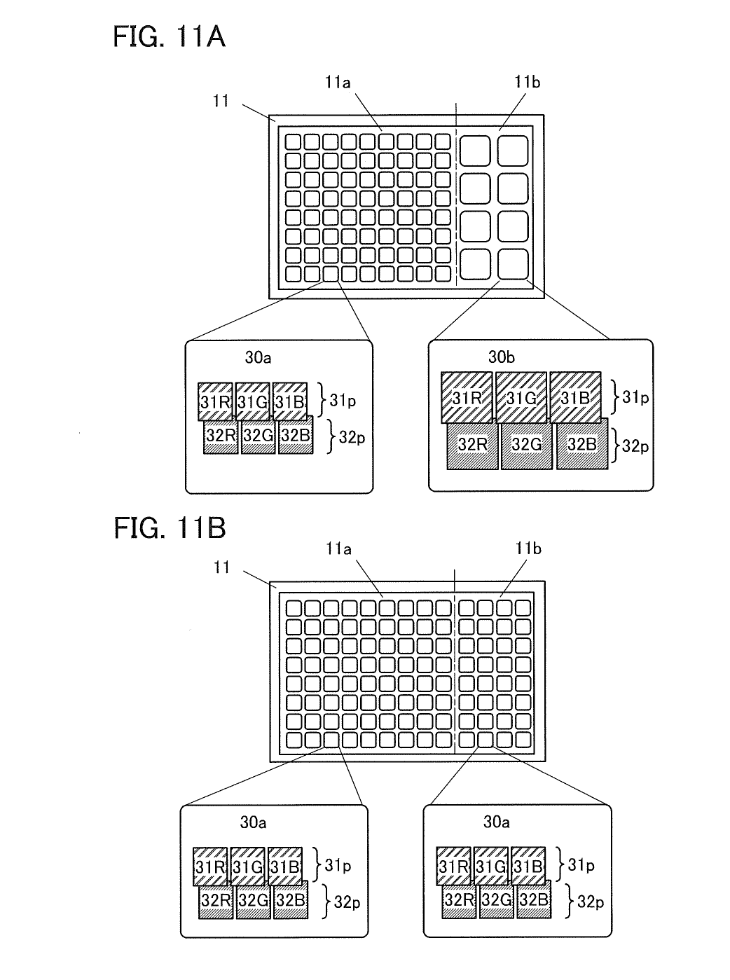

FIG. 11A is a block diagram of the display device 11 including the display regions 11a and 11b described with reference to FIG. 3D. The display regions 11a and 11b have pixels having different sizes, and thus can perform display with different resolutions. Therefore, the amount of display data per display area can be reduced.

The display region 11a includes a plurality of pixels 30a arranged in a matrix. The pixel 30a includes a first pixel circuit 31p and a second pixel circuit 32p.

The display region 11b includes the plurality of pixels 30b arranged in a matrix. The pixel 30b includes the first pixel circuit 31p and the second pixel circuit 32p; however, the sizes of the first pixel circuit 31p and the second pixel circuit 32p are different from those in the display region 11a.

FIG. 11A shows an example where the first pixel circuit 31p and the second pixel circuit 32p each include display elements for three colors of red (R), green (G), and blue (B).

The first pixel circuit 31p includes a display element 31R for red (R), a display element 31G for green (G), and a display element 31B for blue (B). The display elements 31R, 31G, and 31B each utilize reflection of external light.

The second pixel circuit 32p includes a display element 32R for red (R), a display element 32G for green (G), and a display element 32B for blue (B). The display elements 32R, 32G, and 32B each utilize light of a light source.

FIG. 11B is a block diagram of the display device 11 including the pixels 30a having the same size in the display regions 11a and 11b described with reference to FIG. 3C. Since the pixels having the same size are used, the resolution of the display region 11a and the resolution of the display region 11b become the same; thus, display can be seamlessly expanded as an expanded display region of the display region 11a.

### Structure Examples of Pixel

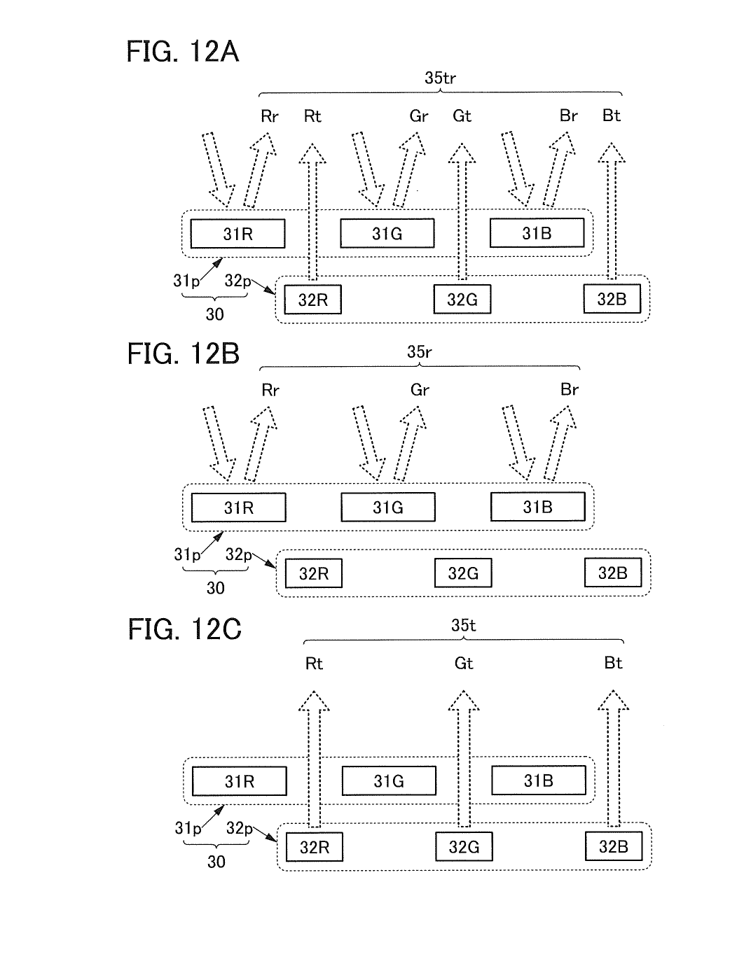

FIGS. 12A to 12C are schematic views illustrating structure examples of the pixels 30a and 30b. Since the pixels 30a and 30b have the same configuration, the pixels 30a and 30b are described as a pixel 30. The pixel 30 shown in FIGS. 12A to 12C includes the first pixel circuit 31p and the second pixel circuit 32p.

The first pixel circuit 31p includes the display elements 31R, 31G, and 31B. The display elements 31R, 31G, and 31B are each an element that performs display by reflecting external light. The display element 31R reflects external light and emits red light Rr to the display surface side. Similarly, the display element 31G and the display element 31B emit green light Gr and blue light Br, respectively, to the display surface side.

The second pixel circuit 32p includes the display elements 32R, 32G, and 32B. The display elements 32R, 32G, and 32B are each a light-emitting element. The display element 32R emits red light Rt to the display surface side. Similarly, the display element 32G and the display element 32B emit green light Gt and blue light Bt, respectively, to the display surface side. Accordingly, a clear image can be displayed with low power consumption. Furthermore, an image like a real painting can be displayed.

FIG. 12A corresponds to a mode (third mode) in which display is performed by driving both the first pixel circuit 31p and the second pixel circuit 32p. The pixel 30 can emit light 35tr of a predetermined color to the display surface side by mixing six kinds of light, the light Rr, the light Gr, the light Br, the light Rt, the light Gt, and the light Bt.

Here, there are many combinations of luminance of light selected from the six kinds of light, the light Rr, the light Gr, the light Br, the light Rt, the light Gt, and the light Bt, where the light 35tr has predetermined luminance and chromaticity. Thus, in one embodiment of the present invention, a combination where the luminance (a gray level) of the light Rr, the light Gr, and the light Br emitted from the first pixel circuit 31p is the largest is preferably selected from the combinations of luminance (gray levels) of six kinds of light that provide the light 35tr with the same luminance and chromaticity. In that case, power consumption can be reduced without impairing color reproducibility.

FIG. 12B corresponds to a mode (first mode) in which display is performed with only reflected light by driving the first pixel circuit 31p. In the case where the illuminance of external light is sufficiently high, for example, the pixel 30 can emit light 35r of a predetermined color, which is a reflected light combination, to the display surface side by mixing only light from the first pixel circuit 31p (the light Rr, the light Gr, and the light Br) without driving the second pixel circuit 32p. This enables driving with extremely low power consumption. Furthermore, eye-friendly display can be performed.

FIG. 12C corresponds to a mode (second mode) in which display is performed with only emitted light (transmitted light) by driving the second pixel circuit 32p. In the case where the illuminance of external light is extremely low, for example, the pixel 30 can emit the light 35t of a predetermined color to the display surface side by mixing only light from the second pixel circuit 32p (the light Rt, the light Gt, and the light Bt) without driving the first pixel circuit 31p. Accordingly, a clear image can be displayed. Furthermore, luminance is lowered when the illuminance of external light is low, which can prevent a user from feeling glare and reduce power consumption.

### Modification Examples

Although the example in which the first pixel circuit 31p and the second pixel circuit 32p each include display elements for three colors of red (R), green (G), and blue (B) is described above, one embodiment of the present invention is not limited thereto. A structure example different from the above is described below.

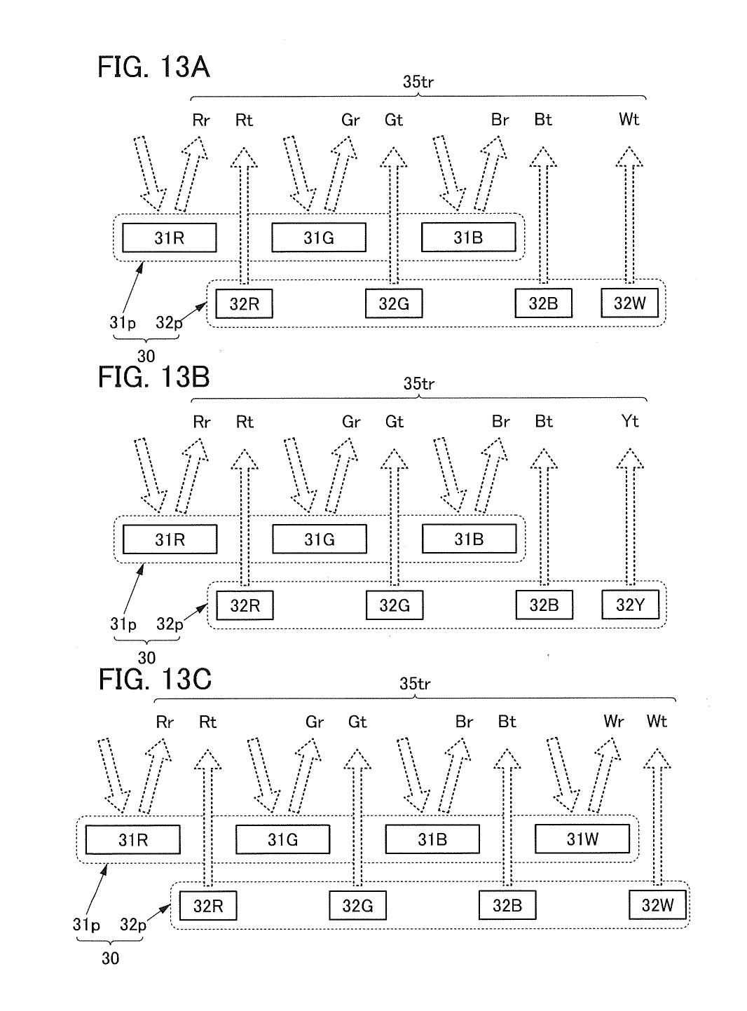

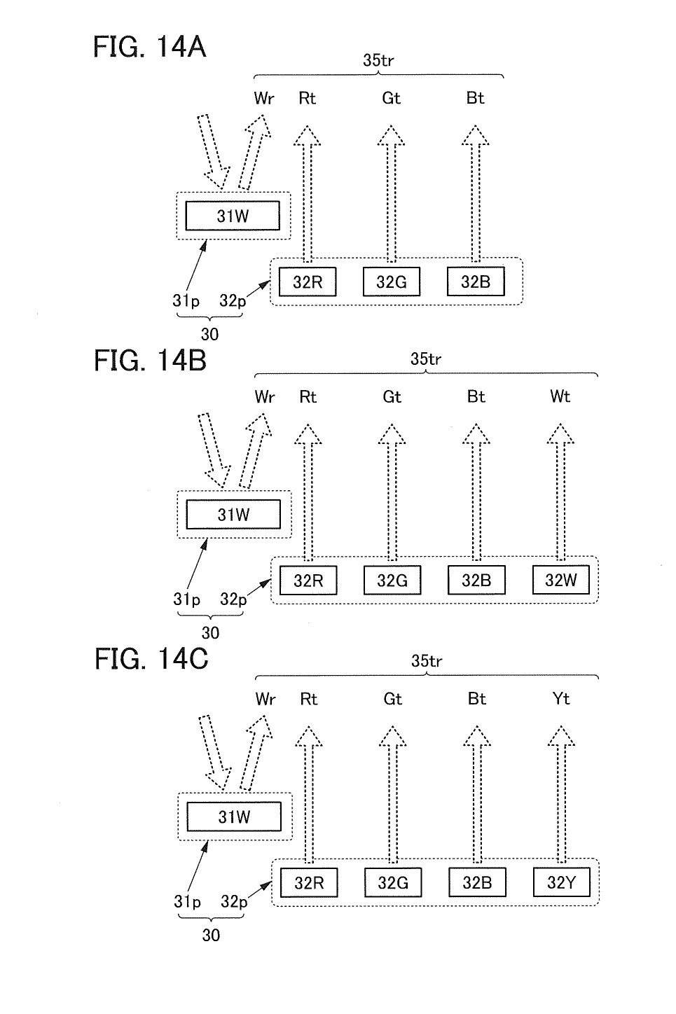

FIGS. 13A to 13C and FIGS. 14A to 14C each illustrate a structure example of the pixel 30. Although schematic views corresponding to a mode (third mode) in which display is performed by driving both the first pixel circuit 31p and the second pixel circuit 32p are illustrated here, display can be performed using either the mode (first mode) in which display is performed with only reflected light by driving the first pixel circuit 31p or the mode (second mode) in which display is performed with only emitted light (transmitted light) by driving the second pixel circuit 32p, as in the above cases.

FIG. 13A illustrates an example in which the second pixel circuit 32p includes a display element 32W that exhibits white (W) light in addition to the display element 32R, the display element 32G, and the display element 32B. This can reduce power consumption in the display modes each using the second pixel circuit 32p (the second mode and the third mode).

FIG. 13B illustrates an example in which the second pixel circuit 32p includes a display element 32Y that exhibits yellow (Y) light in addition to the display element 32R, the display element 32G, and the display element 32B. This can reduce power consumption in the display modes each using the second pixel circuit 32p (the second mode and the third mode).

FIG. 13C illustrates an example in which the first pixel circuit 31p includes a display element 31W that exhibits white (W) light in addition to the display element 31R, the display element 31G, and the display element 31B. Furthermore, FIG. 13C illustrates an example in which the second pixel circuit 32p includes the display element 32W that exhibits white (W) light in addition to the display element 32R, the display element 32G, and the display element 32B. This can reduce power consumption in the display modes each using the first pixel circuit 31p (the first mode and the third mode) and in the display modes each using the second pixel circuit 32p (the second mode and the third mode).

FIG. 14A illustrates an example in which the first pixel circuit 31p includes only the display element 31W that exhibits white light. In this case, in the display mode using only the first pixel circuit 31p (first mode), monochrome or grayscale images can be displayed, and in the display modes each using the second pixel circuit 32p (the second mode and the third mode), color images can be displayed.

Furthermore, such a structure can increase the aperture ratio and the reflectivity of the first pixel circuit 31p, allowing a brighter image to be displayed.

The mode (first mode) in which display is performed using only the first pixel circuit 31p is suitable for displaying information that does not need to be displayed in color, such as text information. When display is performed in the first mode, an electronic device incorporating the display device can be used like an e-book reader or a textbook, for example.

FIG. 14B illustrates an example in which the second pixel circuit 32p includes the display element 32W that exhibits white (W) light in addition to the display element 32R, the display element 32G, and the display element 32B shown in FIG. 14A. This can reduce power consumption in the display modes each using the second pixel circuit 32p (the second mode and the third mode).

FIG. 14C illustrates an example in which the second pixel circuit 32p includes the display element 32Y that exhibits yellow (Y) light in addition to the display element 32R, the display element 32G, and the display element 32B shown in FIG. 14A. This can reduce power consumption in the display modes each using the second pixel circuit 32p (the second mode and the third mode).

The above is the description of the structure examples of display units.

### Cross-Sectional Structure Example of Display Device

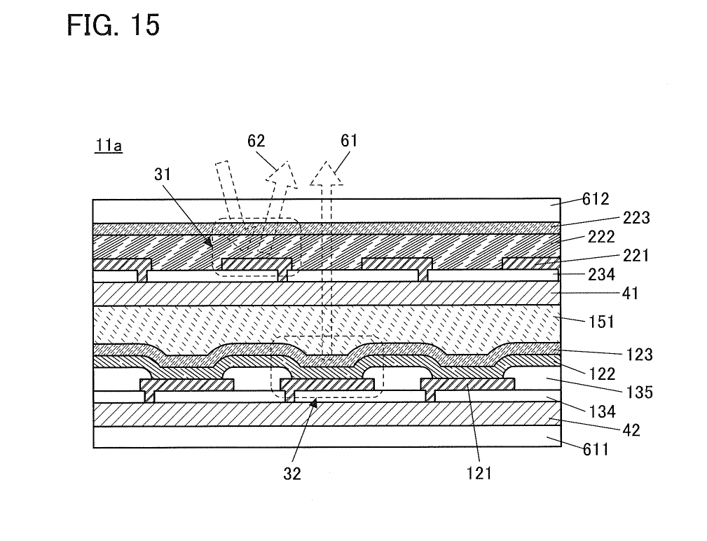

FIG. 15 illustrates an example of a cross-sectional structure of the display region 11a of the display device 11.

The display region 11a includes, between a substrate 611 and a substrate 612, a first layer 41, an insulating layer 134, an insulating layer 135, a display element 32, an adhesive layer 151, a second layer 42, an insulating layer 234, a display element 31, and the like.

The display element 31 includes a conductive layer 221, a conductive layer 223, and liquid crystal 222 between the conductive layers 221 and 223. The conductive layer 221 reflects visible light, and the conductive layer 223 transmits visible light. Thus, the display element 31 is a reflective liquid crystal element that emits reflected light 62 to the substrate 612 side. Here, the conductive layer 221 is provided for each pixel and functions as each pixel electrode. The conductive layer 223 is shared by a plurality of pixels. The conductive layer 223 is connected to a wiring supplied with a constant potential in a region that is not illustrated and functions as a common electrode.

The display element 32 includes a conductive layer 121, a conductive layer 123, and an EL layer 122 between the conductive layers 121 and 123. The EL layer 122 includes at least a light-emitting substance. The conductive layer 121 reflects visible light, and the conductive layer 123 transmits visible light. Thus, the display element 32 is a light-emitting element that emits light 61 to the substrate 612 side by application of voltage between the conductive layers 121 and 123. Here, the conductive layer 121 is provided for each pixel and functions as each pixel electrode. The EL layer 122 and the conductive layer 123 are shared by a plurality of pixels. The conductive layer 123 is connected to a wiring supplied with a constant potential in a region that is not illustrated and functions as a common electrode.

The first layer 41 includes a circuit that drives the display element 31. The second layer 42 includes a circuit that drives the display element 32. For example, the first layer 41 and the second layer 42 each include a pixel circuit including a transistor, a capacitor, a wiring, an electrode, or the like. Note that the circuit that drives the display element 31 and the circuit that drives the display element 32 may be formed in one layer.

The insulating layer 234 is provided between the first layer 41 and the conductive layer 221. The conductive layer 221 and the first layer 41 are electrically connected to each other through an opening formed in the insulating layer 234, whereby the first layer 41 and the display element 31 are electrically connected to each other.

The insulating layer 134 is provided between the second layer 42 and the conductive layer 121. The conductive layer 121 and the second layer 42 are electrically connected to each other through an opening formed in the insulating layer 134, whereby the second layer 42 and the display element 32 are electrically connected to each other.

The first layer 41 and the conductive layer 123 are bonded to each other with the adhesive layer 151. The adhesive layer 151 also functions as a sealing layer that seals the display element 32.

In the case where the pixel circuit of the first layer 41 includes a transistor using an oxide semiconductor and thus having a significantly low off-state current or the case where the pixel circuit includes a memory element, for example, the gray level can be maintained even when writing operation to a pixel is stopped in displaying a still image using the display element 31. That is, display can be maintained even when the frame rate is set to an extremely small value.

The above is the description of a cross-sectional structure example of the display device 11.

### Modification Example of Display Mode

Note that in the third mode, in which display is performed by driving both the first pixel circuit 31p and the second pixel circuit 32p, different images can be displayed at the same time. For example, a background image can be displayed by one of the first pixel circuit 31p and the second pixel circuit 32p, and a moving image can be displayed by the other of the first pixel circuit 31p and the second pixel circuit 32p. Thus, a more realistic image can be displayed.

At least part of this embodiment can be implemented in combination with any of the other embodiments described in this specification as appropriate.

### Embodiment 3

In this embodiment, a basic structure of a display device of one embodiment of the present invention is described.

The display region 11a described in Embodiment 1 has a structure where a first display panel and a second display panel are bonded to each other with an adhesive layer therebetween. In the first display panel, first pixel circuits that include reflective liquid crystal elements are provided. In the second display panel, second pixel circuits that include light-emitting elements are provided. The reflective liquid crystal elements can produce gray levels by controlling the amount of reflected light. The light-emitting elements can produce gray levels by controlling the amount of light emission.

The display device can perform display by using only reflected light, display by using only light emitted from the light-emitting elements, and display by using both reflected light and light emitted from the light-emitting elements, for example.

The first display panel is provided on the viewing side. The second display panel is provided on the side opposite to the viewing side. The first display panel includes a first resin layer in a position closest to the adhesive layer. The second display panel includes a second resin layer in a position closest to the adhesive layer.

It is preferable that a third resin layer be provided on the display surface side of the first display panel and a fourth resin layer be provided on the rear surface side (the side opposite to the display surface side) of the second display panel. Thus, the display panel can be extremely lightweight and less likely to be broken.

The first to fourth resin layers (hereinafter also collectively referred to as a resin layer) have a feature of being extremely thin. Specifically, it is preferable that each of the resin layers have a thickness of 0.1 μm or more and 3 μm or less. Thus, even a structure where the two display panels are stacked can have a small thickness. Furthermore, light absorption due to the resin layer positioned in the path of light emitted from the light-emitting element in the second pixel can be reduced, so that light can be extracted with higher efficiency and the power consumption can be reduced.

The resin layer can be formed in the following manner, for example. A thermosetting resin material with a low viscosity is applied to a support substrate and cured by heat treatment to form the resin layer. Then, a structure is formed over the resin layer. Then, the resin layer and the support substrate are separated from each other, whereby one surface of the resin layer is exposed.

As a method of reducing adhesion between the support substrate and the resin layer to separate the support substrate and the resin layer from each other, laser light irradiation is given. For example, it is preferable to perform the irradiation by scanning using linear laser light. By the method, the process time of the case of using a large support substrate can be shortened. As the laser light, excimer laser light with a wavelength of 308 nm can be suitably used.

A thermosetting polyimide is a typical example of a material that can be used for the resin layer. It is particularly preferable to use a photosensitive polyimide. A photosensitive polyimide is a material that is suitably used for formation of a planarization film or the like of the display panel, and therefore, the formation apparatus and the material can be shared. Thus, there is no need to prepare another apparatus and another material to obtain the structure of one embodiment of the present invention.

Furthermore, the resin layer that is formed using a photosensitive resin material can be processed by light exposure and development treatment. For example, an opening can be formed and an unnecessary portion can be removed. Moreover, by optimizing a light exposure method or light exposure conditions, an uneven shape can be formed in a surface of the resin layer. For example, an exposure technique using a half-tone mask or a gray-tone mask or a multiple exposure technique may be used.

Note that a non-photosensitive resin material may be used. In that case, a method of forming an opening or an uneven shape using a resist mask or a hard mask that is formed over the resin layer can be used.

In this case, part of the resin layer that is positioned in the path of light emitted from the light-emitting element is preferably removed. That is, an opening overlapping with the light-emitting element is provided in the first resin layer and the second resin layer. Thus, a reduction in color reproducibility and light extraction efficiency that is caused by absorption of part of light emitted from the light-emitting element by the resin layer can be inhibited.

Alternatively, the resin layer may be provided with a concave portion so that a portion of the resin layer that is positioned in the path of light emitted from the light-emitting element is thinner than the other portion. That is, the resin layer may have a structure where two portions with different thicknesses are included and the portion with a smaller thickness overlaps with the light-emitting element. The resin layer that has the structure can also reduce absorption of light emitted from the light-emitting element.

In the case where the first display panel includes the third resin layer, an opening overlapping with the light-emitting element is preferably provided in a manner similar to that described above. Thus, color reproducibility and light extraction efficiency can be further increased.

In the case where the first display panel includes the third resin layer, part of the third resin layer that is positioned in the path of light of the reflective liquid crystal element is preferably removed. That is, an opening overlapping with the reflective liquid crystal element is provided in the third resin layer. This can increase the reflectivity of the reflective liquid crystal element.

In the case where the opening is formed in the resin layer, a light absorption layer is formed over the support substrate, the resin layer having the opening is formed over the light absorption layer, and a light-transmitting layer covering the opening is formed. The light absorption layer is a layer that emits a gas such as hydrogen or oxygen by absorbing light and being heated. By performing light irradiation from the support substrate side to make the light absorption layer emit a gas, adhesion at the interface between the light absorption layer and the support substrate or between the light absorption layer and the light-transmitting layer can be reduced to cause separation, or the light absorption layer itself can be broken to cause separation.

As another example, the following method can be used. That is, a thin part is formed in a portion where the opening of the resin layer is to be formed, and the support substrate and the resin layer are separated from each other by the above-described method. Then, plasma treatment or the like is performed on a separated surface of the resin layer to reduce the thickness of the resin layer, whereby the opening can be formed in the thin part of the resin layer.

Each of the first pixel and the second pixel preferably includes a transistor. Furthermore, an oxide semiconductor is preferably used as a semiconductor where a channel of the transistor is formed. An oxide semiconductor can achieve high on-state current and high reliability even when the highest temperature in the manufacturing process of the transistor is reduced (e.g., 400° C. or lower, preferably 350° C. or lower). Furthermore, in the case of using an oxide semiconductor, high heat resistance is not required for a material of the resin layer positioned on the surface side on which the transistor is formed; thus, the material of the resin layer can be selected from a wider range of alternatives. For example, the material can be the same as a resin material of the planarization film.

In the case of using low-temperature polysilicon (LTPS), for example, processes such as a laser crystallization process, a baking process before crystallization, and a baking process for activating impurities are required, and the highest temperature in the manufacturing process of the transistor is higher than that in the case of using an oxide semiconductor (e.g., higher than or equal to 500° C., higher than or equal to 550° C., or higher than or equal to 600° C.), though high field-effect mobility can be obtained. Therefore, high heat resistance is required for the resin layer positioned on the surface side on which the transistor is formed. In addition, the thickness of the resin layer needs to be comparatively large (e.g., larger than or equal to 10 μm, or larger than or equal to 20 μm) because the resin layer is also irradiated with laser light in the laser crystallization process.

In contrast, in the case of using an oxide semiconductor, a special material having high heat resistance is not required for the resin layer, and the resin layer need not be formed thick. Thus, the proportion of the cost of the resin layer in the cost of the whole display panel can be reduced.

An oxide semiconductor has a wide band gap (e.g., 2.5 eV or more, or 3.0 eV or more) and transmits light. Thus, even when an oxide semiconductor is irradiated with laser light in a step of separating the support substrate and the resin layer, the laser light is hardly absorbed, so that the electrical characteristics can be less affected. Therefore, the resin layer can be thin as described above.

In one embodiment of the present invention, a display panel excellent in productivity can be obtained by using both a resin layer that is formed thin using a photosensitive resin layer with a low viscosity typified by a photosensitive polyimide and an oxide semiconductor with which a transistor having excellent electrical characteristics can be obtained even at a low temperature.

Next, a pixel structure is described. The first pixel circuits and the second pixel circuits are arranged in a matrix to form the display portion. In addition, the display panel preferably includes a first driver portion for driving the first pixel circuits and a second driver portion for driving the second pixel circuits. It is preferable that the first driver portion be provided in the first display panel and the second driver portion be provided in the second display panel.

The first pixel circuits and the second pixel circuits are preferably arranged in a display region with the same pitch. Furthermore, the first pixel circuits and the second pixel circuits are preferably mixed in the display region of the display panel. Accordingly, as described later, an image displayed by a plurality of first pixel circuits, an image displayed by a plurality of second pixel circuits, and an image displayed by both the plurality of first pixel circuits and the plurality of second pixel circuits can be displayed in the same display region.

The first pixel circuit is preferably formed of one pixel circuit that emits white (W) light, for example. The second pixel circuit preferably includes subpixel circuits that emit light of three colors of red (R), green (G), and blue (B), for example. In addition, a subpixel circuit that emits white (W) light or yellow (Y) light may be included. By arranging such first pixel circuits and second pixel circuits with the same pitch, the area of the first pixel circuits can be increased and the aperture ratio of the first pixel circuits can be increased.

Note that the first pixel circuit may include subpixel circuits that emit light of three colors of red (R), green (G), and blue (B), and may further include a subpixel circuit that emits white (W) light or yellow (Y) light.

Next, transistors that can be used in the first display panel and the second display panel are described. A transistor provided in the first pixel circuit of the first display panel and a transistor provided in the second pixel circuit of the second display panel may have either the same structure or different structures.

As a structure of the transistor, a bottom-gate structure is given, for example. A transistor having a bottom-gate structure includes a gate electrode below a semiconductor layer (on the formation surface side). A source electrode and a drain electrode are provided in contact with a top surface and a side end portion of the semiconductor layer, for example.

As another structure of the transistor, a top-gate structure is given, for example. A transistor having a top-gate structure includes a gate electrode above a semiconductor layer (on the side opposite to the formation surface side). A source electrode and a drain electrode are provided over an insulating layer covering part of a top surface and a side end portion of the semiconductor layer and are electrically connected to the semiconductor layer through openings provided in the insulating layer, for example.

The transistor preferably includes a first gate electrode and a second gate electrode that face each other with the semiconductor layer provided therebetween.

A more specific example of the display device of one embodiment of the present invention is described below with reference to drawings.

### Structure Example 1

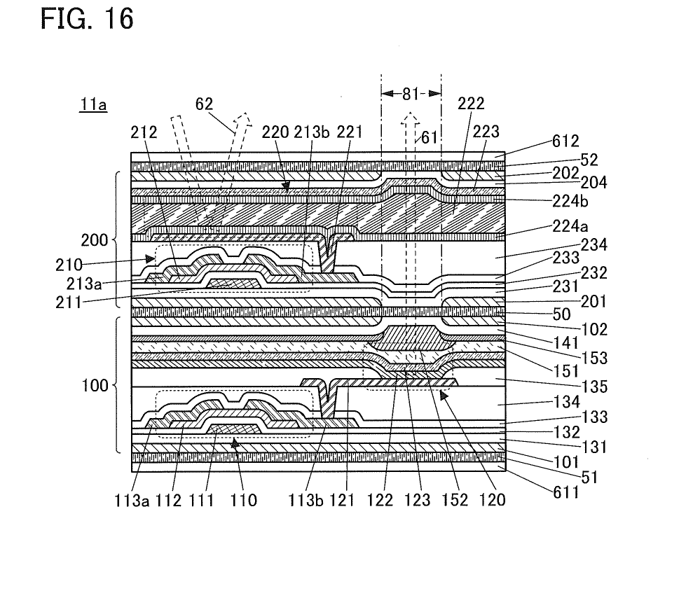

FIG. 16 is a schematic cross-sectional view of the display region 11a in the display device 11 illustrated in FIGS. 11A and 11B. In the display device 11, a display panel 100 and a display panel 200 are bonded to each other using an adhesive layer 50. The display device 11 includes the substrate 611 on the rear side (the side opposite to the viewing side) and the substrate 612 on the front side (the viewing side).

The display panel 100 includes a transistor 110 and a light-emitting element 120 between a resin layer 101 and a resin layer 102. The display panel 200 includes a transistor 210 and a liquid crystal element 220 between a resin layer 201 and a resin layer 202. The resin layer 101 is bonded to the substrate 611 with an adhesive layer 51 positioned therebetween. The resin layer 202 is bonded to the substrate 612 with an adhesive layer 52 positioned therebetween.

The resin layer 102, the resin layer 201, and the resin layer 202 are each provided with an opening. A region 81 shown in FIG. 16 is a region overlapping with the light-emitting element 120 and overlapping with the opening of the resin layer 102, the opening of the resin layer 201, and the opening of the resin layer 202.

### [Display Panel 100]

The resin layer 101 is provided with the transistor 110, the light-emitting element 120, an insulating layer 131, an insulating layer 132, an insulating layer 133, the insulating layer 134, the insulating layer 135, and the like. The resin layer 102 is provided with a light-blocking layer 153, a coloring layer 152, and the like. The resin layer 101 and the resin layer 102 are bonded to each other using the adhesive layer 151.

The transistor 110 is provided over the insulating layer 131 and includes a conductive layer 111 serving as a gate electrode, part of the insulating layer 132 serving as a gate insulating layer, a semiconductor layer 112, a conductive layer 113a serving as one of a source electrode and a drain electrode, and a conductive layer 113b serving as the other of the source electrode and the drain electrode.

The semiconductor layer 112 preferably includes an oxide semiconductor.

The insulating layer 133 and the insulating layer 134 cover the transistor 110. The insulating layer 134 serves as a planarization layer.

The light-emitting element 120 includes the conductive layer 121, the EL layer 122, and the conductive layer 123 that are stacked. The conductive layer 121 has a function of reflecting visible light, and the conductive layer 123 has a function of transmitting visible light. Therefore, the light-emitting element 120 is a light-emitting element having a top-emission structure that emits light to the side opposite to the formation surface side.

The conductive layer 121 is electrically connected to the conductive layer 113b through an opening provided in the insulating layer 134 and the insulating layer 133. The insulating layer 135 covers an end portion of the conductive layer 121 and is provided with an opening to expose a top surface of the conductive layer 121. The EL layer 122 and the conductive layer 123 are provided in this order to cover the insulating layer 135 and the exposed portion of the conductive layer 121.

An insulating layer 141 is provided on the resin layer 101 side of the resin layer 102. The light-blocking layer 153 and the coloring layer 152 are provided on the resin layer 101 side of the insulating layer 141. The coloring layer 152 is provided in a region overlapping with the light-emitting element 120. The light-blocking layer 153 includes an opening in a portion overlapping with the light-emitting element 120.

The insulating layer 141 covers the opening of the resin layer 102. A portion of the insulating layer 141 that overlaps with the opening of the resin layer 102 is in contact with the adhesive layer 50.

### [Display Panel 200]

The resin layer 201 is provided with the transistor 210, the conductive layer 221, an alignment film 224a, an insulating layer 231, an insulating layer 232, an insulating layer 233, the insulating layer 234, and the like. The resin layer 202 is provided with an insulating layer 204, the conductive layer 223, an alignment film 224b, and the like. The liquid crystal 222 is sandwiched between the alignment film 224a and the alignment film 224b. The resin layer 201 and the resin layer 202 are bonded to each other using an adhesive layer in a region not shown.

The transistor 210 is provided over the insulating layer 231 and includes a conductive layer 211 serving as a gate electrode, part of the insulating layer 232 serving as a gate insulating layer, a semiconductor layer 212, a conductive layer 213a serving as one of a source electrode and a drain electrode, and a conductive layer 213b serving as the other of the source electrode and the drain electrode.

The semiconductor layer 212 preferably includes an oxide semiconductor.

The insulating layer 233 and the insulating layer 234 cover the transistor 210. The insulating layer 234 serves as a planarization layer.

The liquid crystal element 220 includes the conductive layer 221, the conductive layer 223, and the liquid crystal 222 positioned therebetween. The conductive layer 221 has a function of reflecting visible light, and the conductive layer 223 has a function of transmitting visible light. Therefore, the liquid crystal element 220 is a reflective liquid crystal element.

The conductive layer 221 is electrically connected to the conductive layer 213b through an opening provided in the insulating layer 234 and the insulating layer 233. The alignment film 224a covers surfaces of the conductive layer 221 and the insulating layer 234.

The conductive layer 223 and the alignment film 224b are stacked on the resin layer 201 side of the resin layer 202. Note that the insulating layer 204 is provided between the resin layer 202 and the conductive layer 223. In addition, a coloring layer for coloring light reflected by the liquid crystal element 220 may be provided.

The insulating layer 231 covers the opening of the resin layer 201. A portion of the insulating layer 231 that overlaps with the opening of the resin layer 201 is in contact with the adhesive layer 50. The insulating layer 204 covers the opening of the resin layer 202. A portion of the insulating layer 204 that overlaps with the opening of the resin layer 202 is in contact with the adhesive layer 52.

### [Display Device 11]

The display device 11 includes a portion where the light-emitting element 120 does not overlap with the reflective liquid crystal element 220 when the display region 11a is seen from above. Thus, the light 61 that is colored by the coloring layer 152 is emitted from the light-emitting element 120 to the viewing side as shown in FIG. 16. Furthermore, the reflected light 62 that is external light reflected by the conductive layer 221 is emitted through the liquid crystal 222 of the liquid crystal element 220.

The light 61 emitted from the light-emitting element 120 is emitted to the viewing side through the opening of the resin layer 102, the opening of the resin layer 201, and the opening of the resin layer 202. Since the resin layer 102, the resin layer 201, and the resin layer 202 are not provided in the path of the light 61, even in the case where the resin layer 102, the resin layer 201, and the resin layer 202 absorb part of visible light, high light extraction efficiency and high color reproducibility can be obtained.

Note that the substrate 612 serves as a polarizing plate or a circular polarizing plate. A polarizing plate or a circular polarizing plate may be located outward from the substrate 612.

In the above-described structure of the display panel 200, a coloring layer is not included and color display is not performed, but a coloring layer may be provided on the resin layer 202 side to perform color display.

The above is the description of the structure example.

### Modification Example of Structure Example

A structure example that is partly different from the structure example shown in FIG. 16 is described below.

In FIG. 16, the opening is provided in a portion of the resin layer that is positioned in the path of light emitted from the light-emitting element 120, but an opening may be provided also in a portion of the resin layer that is positioned in the path of light of the reflective liquid crystal element 220.

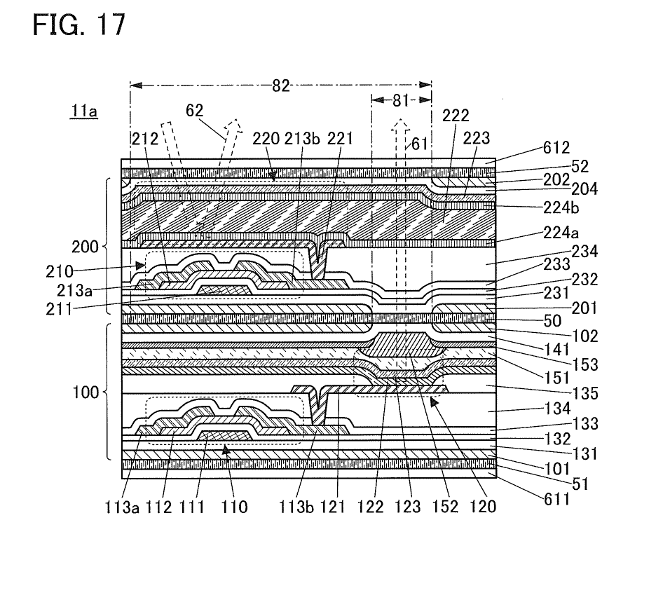

FIG. 17 shows an example where a region 82 is included in addition to the region 81. The region 82 overlaps with the opening of the resin layer 202 and the liquid crystal element 220.

Although the resin layer 202 is provided with one opening portion overlapping with both the light-emitting element 120 and the liquid crystal element 220 in the example shown in FIG. 17, an opening portion overlapping with the light-emitting element 120 and an opening portion overlapping with the liquid crystal element 220 may be separately provided.

### [Transistor]

The display device 11 exemplified in FIG. 16 shows an example of using bottom-gate transistors as the transistor 110 and the transistor 210.

In the transistor 110, the conductive layer 111 serving as a gate electrode is in a position closer to the formation surface (the resin layer 101 side) than the semiconductor layer 112. The insulating layer 132 covers the conductive layer 111. The semiconductor layer 112 covers the conductive layer 111. A region of the semiconductor layer 112 that overlaps with the conductive layer 111 corresponds to a channel formation region. The conductive layer 113a and the conductive layer 113b are provided in contact with the top surface and side end portions of the semiconductor layer 112.

Note that in the transistor 110 shown as an example, the width of the semiconductor layer 112 is wider than that of the conductive layer 111. In such a structure, the semiconductor layer 112 is positioned between the conductive layer 111 and each of the conductive layer 113a and the conductive layer 113b. Thus, the parasitic capacitance between the conductive layer 111 and each of the conductive layer 113a and the conductive layer 113b can be reduced.

The transistor 110 is a channel-etched transistor and can be suitably used for a high-resolution display device because the occupation area of the transistor can be reduced comparatively easily.

The transistor 210 and the transistor 110 have common characteristics.

A structure example of a transistor that can be used for the transistor 110 and the transistor 210 is described.

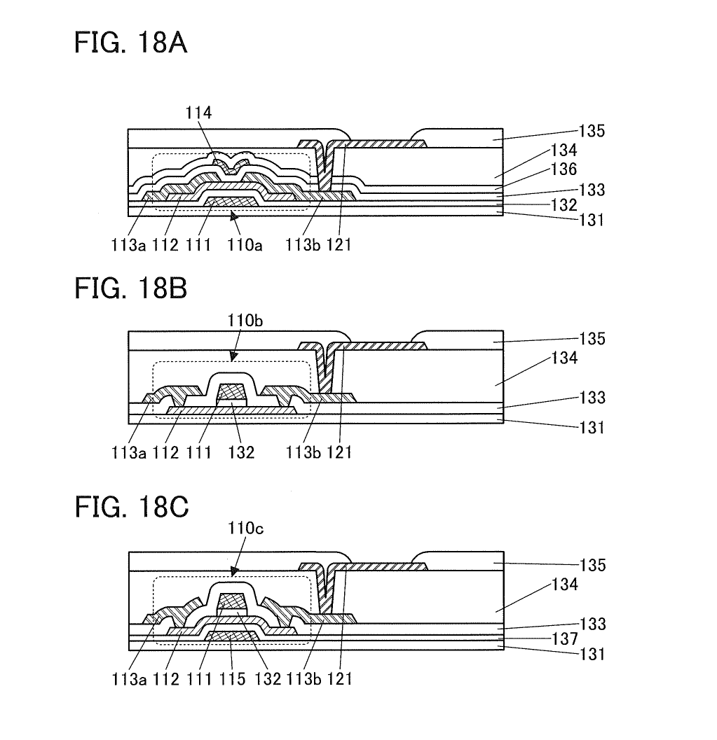

A transistor 110a shown in FIG. 18A is different from the transistor 110 in that the transistor 110a includes a conductive layer 114 and an insulating layer 136. The conductive layer 114 is provided over the insulating layer 133 and includes a region overlapping with the semiconductor layer 112. The insulating layer 136 covers the conductive layer 114 and the insulating layer 133.

The conductive layer 114 is positioned to face the conductive layer 111 with the semiconductor layer 112 therebetween. In the case where the conductive layer 111 is used as a first gate electrode, the conductive layer 114 can serve as a second gate electrode. By supplying the same potential to the conductive layer 111 and the conductive layer 114, the on-state current of the transistor 110a can be increased. By supplying a potential for controlling the threshold voltage to one of the conductive layer 111 and the conductive layer 114 and a potential for driving to the other, the threshold voltage of the transistor 110a can be controlled.

A conductive material including an oxide is preferably used as the conductive layer 114. In that case, a conductive film to be the conductive layer 114 is formed in an atmosphere containing oxygen, whereby oxygen can be supplied to the insulating layer 133. The proportion of an oxygen gas in a film formation gas in a sputtering method is preferably higher than or equal to 90% and lower than or equal to 100%. Oxygen supplied to the insulating layer 133 is supplied to the semiconductor layer 112 by heat treatment to be performed later, so that oxygen vacancies in the semiconductor layer 112 can be reduced.

It is particularly preferable to use, as the conductive layer 114, an oxide semiconductor whose resistance is reduced. In this case, the insulating layer 136 is preferably formed using an insulating film that releases hydrogen, e.g., a silicon nitride film. Hydrogen is supplied to the conductive layer 114 during the formation of the insulating layer 136 or by heat treatment to be performed after that, whereby the electrical resistance of the conductive layer 114 can be reduced effectively. Note that the details of the oxide semiconductor example are described in Embodiment 6.

A transistor 110b shown in FIG. 18B is a top-gate transistor.

In the transistor 110b, the conductive layer 111 serving as a gate electrode is provided over the semiconductor layer 112 (provided on the side opposite to the formation surface side). The semiconductor layer 112 is formed over the insulating layer 131. The insulating layer 132 and the conductive layer 111 are stacked over the semiconductor layer 112. The insulating layer 133 covers the top surface and the side end portions of the semiconductor layer 112, side surfaces of the insulating layer 132, and the conductive layer 111. The conductive layer 113a and the conductive layer 113b are provided over the insulating layer 133. The conductive layer 113a and the conductive layer 113b are electrically connected to the top surface of the semiconductor layer 112 through openings provided in the insulating layer 133.

Note that although the insulating layer 132 is not present in a portion that does not overlap with the conductive layer 111 in the example, the insulating layer 132 may be provided in a portion covering the top surface and the side end portion of the semiconductor layer 112.

In the transistor 110b, the physical distance between the conductive layer 111 and the conductive layer 113a or the conductive layer 113b can be easily increased, so that the parasitic capacitance therebetween can be reduced.

A transistor 110c shown in FIG. 18C is different from the transistor 110b in that the transistor 110c includes a conductive layer 115 and an insulating layer 137. The conductive layer 115 is provided over the insulating layer 131 and includes a region overlapping with the semiconductor layer 112. The insulating layer 137 covers the conductive layer 115 and the insulating layer 131.

The conductive layer 115 serves as a second gate electrode like the conductive layer 114. Thus, the on-state current can be increased and the threshold voltage can be controlled, for example.

In the display device 11, the transistor included in the display panel 100 and the transistor included in the display panel 200 may be different from each other. For example, the transistor 110a or the transistor 110c can be used as the transistor that is electrically connected to the light-emitting element 120 because a comparatively large amount of current needs to be fed to the transistor, and the transistor 110 can be used as the other transistor to reduce the occupation area of the transistor.

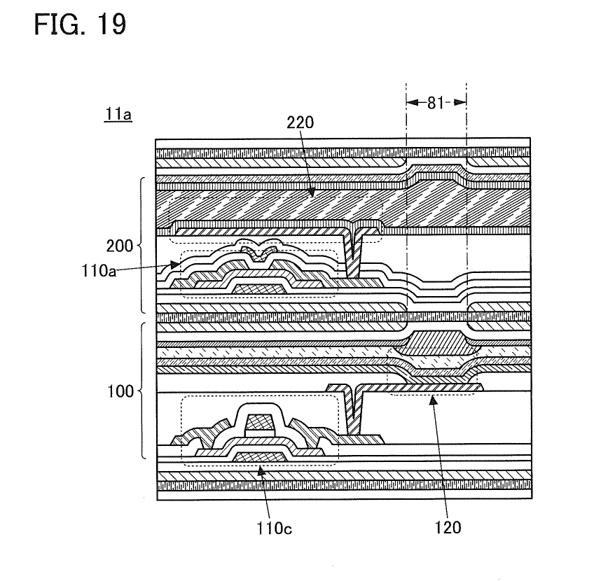

FIG. 19 shows an example of the case where the transistor 110a is used instead of the transistor 210 in FIG. 16 and the transistor 110c is used instead of the transistor 110 in FIG. 16.

The above is the description of the transistor.

In this embodiment, one embodiment of the present invention has been described. Other embodiments of the present invention are described in in the other embodiments. Note that one embodiment of the present invention is not limited to the above examples. In other words, various embodiments of the invention are described in this embodiment and the other embodiments, and one embodiment of the present invention is not limited to a particular embodiment. The example in which one embodiment of the present invention is applied to a display device is described; however, one embodiment of the present invention is not limited thereto. Depending on circumstances or conditions, one embodiment of the present invention is not necessarily applied to a display device. One embodiment of the present invention may be applied to a semiconductor device with another function, for example. Although an example in which a channel formation region, a source region, a drain region, or the like of a transistor includes an oxide semiconductor is described as one embodiment of the present invention, one embodiment of the present invention is not limited thereto. Depending on the circumstances or conditions, a variety of semiconductors may be used for transistors in one embodiment of the present invention, the channel formation regions of the transistors, the source and drain regions of the transistors, and the like. Depending on the circumstances or conditions, transistors in one embodiment of the present invention, the channel formation regions of the transistors, the source and drain regions of the transistors, and the like may include, for example, at least one of silicon, germanium, silicon germanium, silicon carbide, gallium arsenide, aluminum gallium arsenide, indium phosphide, gallium nitride, and an organic semiconductor. Depending on the circumstances or case, transistors in one embodiment of the present invention, the channel formation regions of the transistors, the source and drain regions of the transistors, and the like do not necessarily include an oxide semiconductor.

At least part of this embodiment can be implemented in combination with any of the other embodiments described in this specification as appropriate.

### Embodiment 4

In this embodiment, a specific example of a display panel of one embodiment of the present invention is described. A display panel 400 described below includes both a reflective liquid crystal element and a light-emitting element that can be used in the display region 11a described in Embodiment 1 and can perform display in a transmission mode and in a reflection mode.

### Structure Example

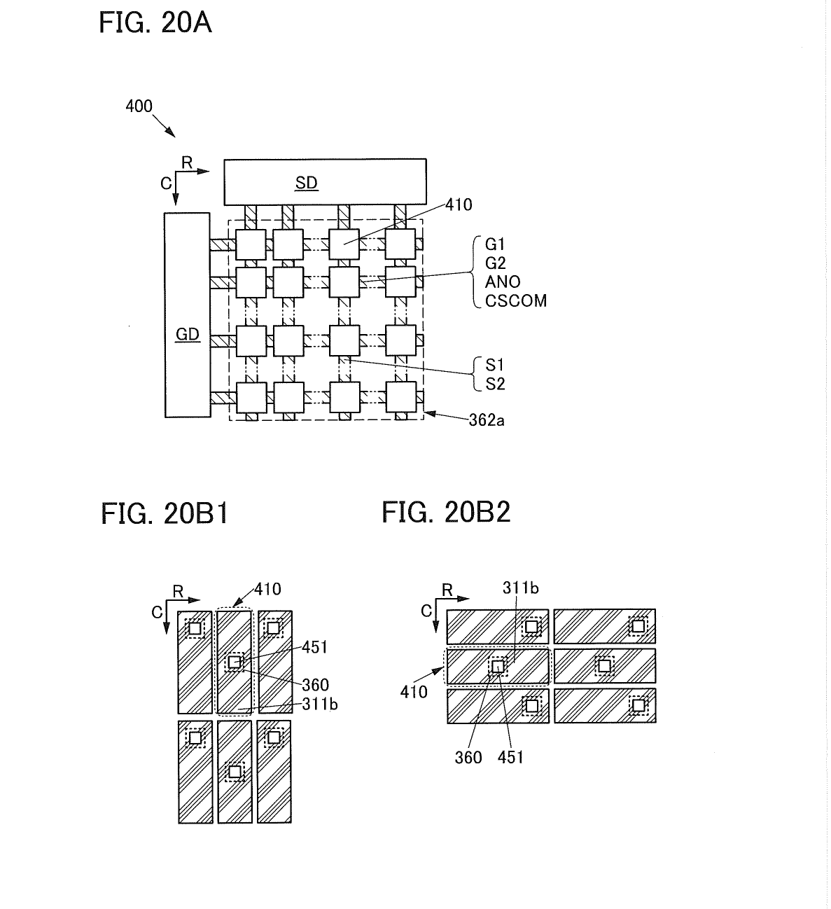

FIG. 20A is a block diagram illustrating an example of the structure of the display panel 400. The display panel 400 includes a plurality of pixels 410 that are arranged in a matrix in a display portion 362a. The display panel 400 also includes a gate driver GD and a source driver SD. In addition, the display panel 400 includes a plurality of wirings G1, a plurality of wirings G2, a plurality of wirings ANO, and a plurality of wirings CSCOM, which are electrically connected to the gate driver GD and the plurality of pixels 410 arranged in a direction R. Moreover, the display panel 400 includes a plurality of wirings S1 and a plurality of wirings S2, which are electrically connected to the source driver SD and the plurality of pixels 410 arranged in a direction C.

Although the configuration including one gate driver GD and one source driver SD is illustrated here for simplicity, the gate driver GD and the source driver SD for driving the liquid crystal element and those for driving the light-emitting element may be provided separately.

The pixel 410 includes a reflective liquid crystal element and a light-emitting element. In the pixel 410, the liquid crystal element and the light-emitting element partly overlap with each other.

FIG. 20B1 illustrates a structure example of an electrode 311b included in the pixel 410. The electrode 311b serves as a reflective electrode of the liquid crystal element in the pixel 410. The electrode 311b includes an opening 451.

In FIG. 20B1, a light-emitting element 360 in a region overlapping with the electrode 311b is shown by a dashed line. The light-emitting element 360 overlaps with the opening 451 included in the electrode 311b. Thus, light from the light-emitting element 360 is emitted to the display surface side through the opening 451.

In FIG. 20B 1, the pixels 410 adjacent in the direction R correspond to different emission colors. As illustrated in FIG. 20B1, the openings 451 are preferably provided in different positions in the electrodes 311b so as not to be aligned in the two pixels adjacent to each other in the direction R. This allows the two light-emitting elements 360 to be apart from each other, thereby preventing light emitted from the light-emitting element 360 from entering a coloring layer in the adjacent pixel 410 (such a phenomenon is also referred to as “crosstalk”). Furthermore, since the two adjacent light-emitting elements 360 can be arranged apart from each other, a high-resolution display device can be obtained even when EL layers of the light-emitting elements 360 are separately formed with a shadow mask or the like.

Alternatively, arrangement illustrated in FIG. 20B2 may be employed.

If the ratio of the total area of the opening 451 to the total area except for the opening is too large, display performed using the liquid crystal element is dark. If the ratio of the total area of the opening 451 to the total area except for the opening is too small, display performed using the light-emitting element 360 is dark.

If the area of the opening 451 in the electrode 311b serving as a reflective electrode is too small, light emitted from the light-emitting element 360 is not efficiently extracted.

The opening 451 may have a polygonal shape, a quadrangular shape, an elliptical shape, a circular shape, a cross-like shape, a stripe shape, a slit-like shape, or a checkered pattern, for example. The opening 451 may be close to the adjacent pixel. Preferably, the opening 451 is provided close to another pixel that emits light of the same color, in which case crosstalk can be suppressed.

### Circuit Configuration Example

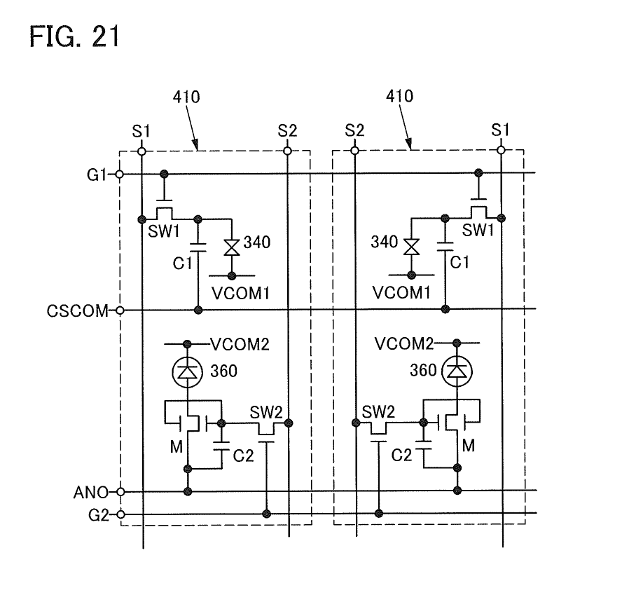

FIG. 21 is a circuit diagram illustrating a configuration example in which the pixel 30 described in Embodiment 2 is described as the pixel 410. FIG. 21 shows two adjacent pixels 410.

The pixel 410 includes a switch SW1, a capacitor C1, a liquid crystal element 340, a switch SW2, a transistor M, a capacitor C2, the light-emitting element 360, and the like. The pixel 410 is electrically connected to a wiring G1, a wiring G2, a wiring ANO, a wiring CSCOM, a wiring S1, and a wiring S2. FIG. 21 also illustrates a wiring VCOM1 electrically connected to the liquid crystal element 340 and a wiring VCOM2 electrically connected to the light-emitting element 360. The wirings G1 and G2 are supplied with a scan signal, and the wirings S1 and S2 are supplied with a grayscale signal.

FIG. 21 illustrates an example in which a transistor is used as each of the switches SW1 and SW2.

A gate of the switch SW1 is connected to the wiring G1. One of a source and a drain of the switch SW1 is connected to the wiring S1, and the other of the source and the drain is connected to one electrode of the capacitor C1 and one electrode of the liquid crystal element 340. The other electrode of the capacitor C1 is connected to the wiring CSCOM. The other electrode of the liquid crystal element 340 is connected to the wiring VCOM1.

A gate of the switch SW2 is connected to the wiring G2. One of a source and a drain of the switch SW2 is connected to the wiring S2, and the other of the source and the drain is connected to one electrode of the capacitor C2 and a gate of the transistor M. The other electrode of the capacitor C2 is connected to one of a source and a drain of the transistor M and the wiring ANO. The other of the source and the drain of the transistor M is connected to one electrode of the light-emitting element 360. The other electrode of the light-emitting element 360 is connected to the wiring VCOM2.

FIG. 21 illustrates an example in which the transistor M includes two gates between which a semiconductor is provided and which are connected to each other. This structure can increase the amount of current flowing through the transistor M.

The wiring G1 can be supplied with a signal for changing the on/off state of the switch SW1. A predetermined potential can be supplied to the wiring VCOM1. The wiring S1 can be supplied with a signal for changing the orientation of a liquid crystal of the liquid crystal element 340. A predetermined potential can be supplied to the wiring CSCOM.

The wiring G2 can be supplied with a signal for changing the on/off state of the switch SW2. The wiring VCOM2 and the wiring ANO can be supplied with potentials having a difference large enough to make the light-emitting element 360 emit light. The wiring S2 can be supplied with a signal for changing the conduction state of the transistor M.

In the pixel 410 of FIG. 21, for example, an image can be displayed in the reflective mode by driving the pixel with the signals supplied to the wiring G1 and the wiring S1 and utilizing the optical modulation of the liquid crystal element 340. In the case where an image is displayed in the transmissive mode, the pixel is driven with the signals supplied to the wiring G2 and the wiring S2 and the light-emitting element 360 emits light. In the case where both modes are performed at the same time, the pixel can be driven with the signals supplied to the wiring G1, the wiring G2, the wiring S1, and the wiring S2.

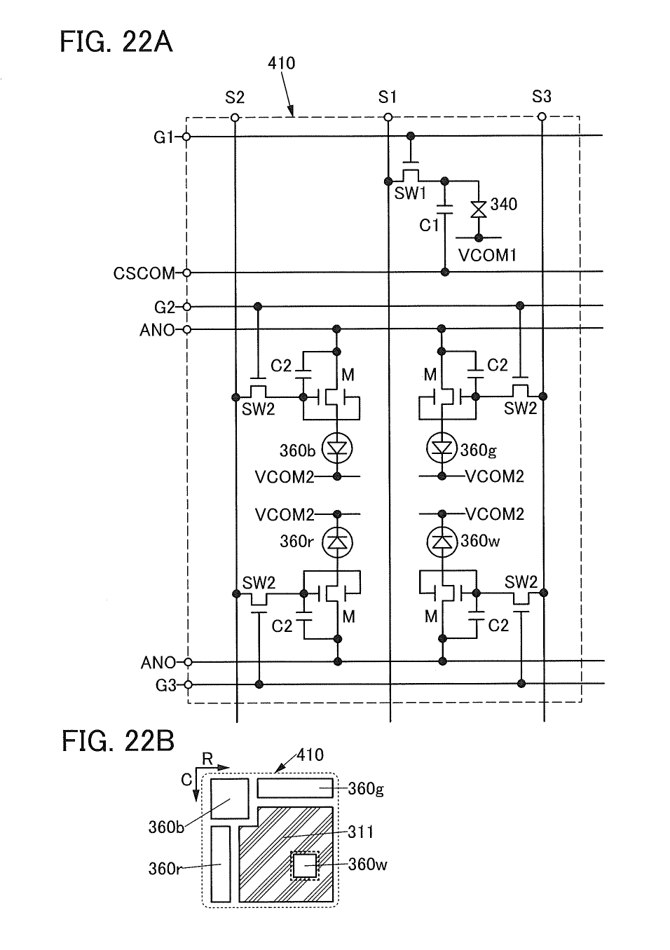

Although FIG. 21 illustrates the example in which one pixel 410 includes one liquid crystal element 340 and one light-emitting element 360, one embodiment of the present invention is not limited to this example. FIG. 22A illustrates an example in which one pixel 410 includes one liquid crystal element 340 and four light-emitting elements 360 (light-emitting elements 360r, 360g, 360b, and 360w). The pixel 410 illustrated in FIG. 22A differs from that in FIG. 21 in being capable of performing full-color display by one pixel.

In addition to the example in FIG. 21, the pixel 410 in FIG. 22A is connected to a wiring G3 and a wiring S3.

In the example illustrated in FIG. 22A, for example, light-emitting elements that exhibit red (R), green (G), blue (B), and white (W) can be used as the four light-emitting elements 360. A reflective liquid crystal element that exhibits white can be used as the liquid crystal element 340. This enables white display with high reflectance in the reflective mode. This also enables display with excellent color-rendering properties and low power consumption in the transmissive mode.

FIG. 22B illustrates a configuration example of the pixel 410. The pixel 410 includes the light-emitting element 360w that overlaps with the opening in an electrode 311 and the light-emitting elements 360r, 360g, and 360b located near the electrode 311. It is preferred that the light-emitting elements 360r, 360g, and 360b have substantially the same light-emitting area.

### Structure Example of Display Device

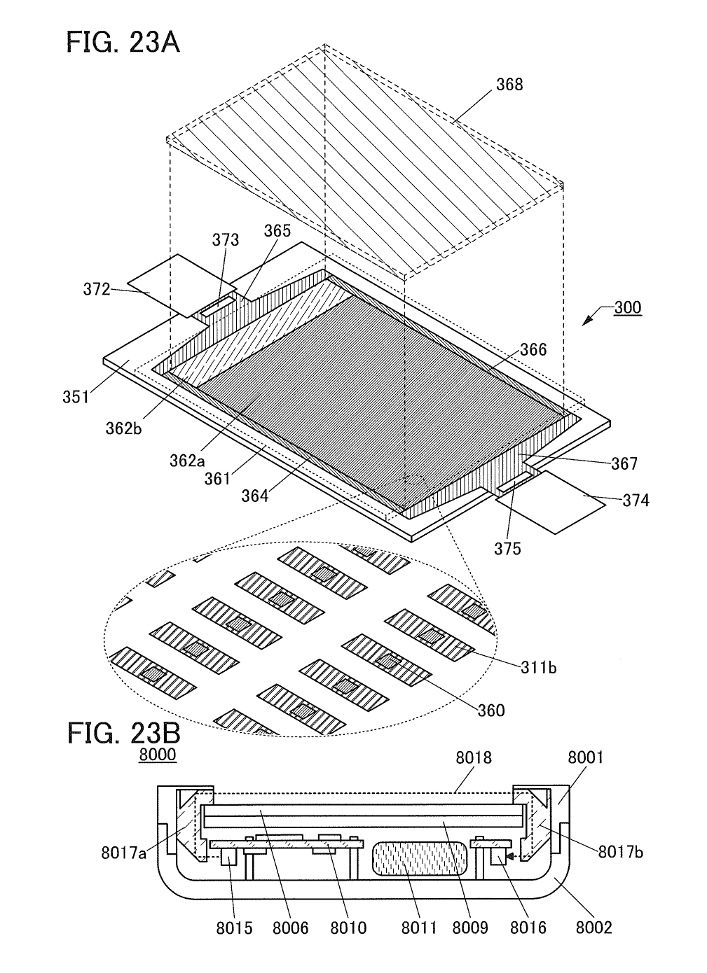

FIG. 23A is a schematic perspective view illustrating a display device 300 of one embodiment of the present invention. In the display device 300, a substrate 351 and a substrate 361 are attached to each other. In FIG. 23A, the substrate 361 is shown by a dashed line.

A touch sensor can be provided over the substrate 361. For example, a sheet-like capacitive touch sensor 368 is provided to overlap with the display portion 362a and a display portion 362b. Alternatively, a touch sensor may be provided between the substrate 361 and the substrate 351. In the case where a touch sensor is provided between the substrate 361 and the substrate 351, as the touch sensor 368, a touch sensor using any sensing method such as a projected capacitive method, a surface capacitive method, or a resistive method can be used. Alternatively, an optical touch sensor including a photoelectric conversion element may be used.

In FIG. 23B, a display module 8000 includes the display device 300. An example is shown in which the display module 8000 includes a touch sensor different from the touch panel described in Embodiment 1. In the display module 8000, a display panel 8006 connected to an FPC, a frame 8009, a printed circuit board 8010, and a battery 8011 are provided between an upper cover 8001 and a lower cover 8002.

The display device 300 in FIG. 23A can be used for the display panel 8006. Thus, the display module can be manufactured with high yield.

The shapes and sizes of the upper cover 8001 and the lower cover 8002 can be changed as appropriate in accordance with the size of the display panel 8006.

A touch panel may be provided so as to overlap with the display panel 8006. The touch panel can be a resistive touch panel or a capacitive touch panel and may be formed to overlap with the display panel 8006. Instead of providing the touch panel, the display panel 8006 can have a touch panel function.

The frame 8009 protects the display panel 8006 and functions as an electromagnetic shield for blocking electromagnetic waves generated by the operation of the printed circuit board 8010. The frame 8009 can also function as a radiator plate.

The printed circuit board 8010 has a power supply circuit and a signal processing circuit for outputting a video signal and a clock signal. As a power source for supplying power to the power supply circuit, an external commercial power source or the battery 8011 provided separately may be used. The battery 8011 can be omitted in the case of using a commercial power source.

The display module 8000 may be additionally provided with a member such as a polarizing plate, a retardation plate, or a prism sheet.

FIG. 23B is a schematic cross-sectional view of the display module 8000 with an optical touch sensor.

The display module 8000 includes a light-emitting portion 8015 and a light-receiving portion 8016 that are provided on the printed circuit board 8010. A pair of light guide portions (a light guide portion 8017a and a light guide portion 8017b) is provided in a region surrounded by the upper cover 8001 and the lower cover 8002.

The display panel 8006 overlaps with the printed circuit board 8010 and the battery 8011 with the frame 8009 located therebetween. The display panel 8006 and the frame 8009 are fixed to the light guide portion 8017a and the light guide portion 8017b.

Light 8018 emitted from the light-emitting portion 8015 travels over the display panel 8006 through the light guide portion 8017a and reaches the light-receiving portion 8016 through the light guide portion 8017b. For example, blocking of the light 8018 by a sensing target such as a finger or a stylus can be detected as touch operation.

A plurality of light-emitting portions 8015 are provided along two adjacent sides of the display panel 8006, for example. A plurality of light-receiving portions 8016 are provided so as to face the light-emitting portions 8015. Accordingly, information about the position of touch operation can be obtained.

As the light-emitting portion 8015, a light source such as an LED element can be used. It is particularly preferable to use a light source that emits infrared light, which is not visually recognized by users and is harmless to users, as the light-emitting portion 8015.

As the light-receiving portion 8016, a photoelectric element that receives light emitted by the light-emitting portion 8015 and converts it into an electrical signal can be used. A photodiode that can receive infrared light can be favorably used.

For the light guide portions 8017a and 8017b, members that transmit at least the light 8018 can be used. With the use of the light guide portions 8017a and 8017b, the light-emitting portion 8015 and the light-receiving portion 8016 can be placed under the display panel 8006, and a malfunction of the touch sensor due to external light reaching the light-receiving portion 8016 can be suppressed. It is particularly preferable to use a resin that absorbs visible light and transmits infrared light. This is more effective in suppressing the malfunction of the touch sensor.

The display device 300 is described again. The display device 300 includes the display portion 362a, the display portion 362b, a circuit portion 364, a wiring 365, a circuit portion 366, a wiring 367, and the like. The substrate 351 is provided with the circuit portion 364, the wiring 365, the circuit portion 366, the wiring 367, the electrode 311b functioning as a pixel electrode, and the like. In FIG. 23A, an IC 373, an FPC 372, an IC 375, and an FPC 374 are mounted on the substrate 351. Thus, the structure illustrated in FIG. 23A can be referred to as a display module including the display device 300, the IC 373, the FPC 372, the IC 375, and the FPC 374.

The display device 300 corresponds to the display device 11 described in Embodiment 1, and the display portions 362a and 362b correspond to the display regions 11a and 11b, respectively.

For the circuit portion 364 and the circuit portion 366, a circuit functioning as a scan line driver circuit can be used, for example.

The wirings 365 and 367 each have a function of supplying signals and electric power to the display portions and the circuit portion 364. The signals and electric power are input to the wiring 365 from the outside through the FPC 372 or from the IC 373.

FIG. 23A shows an example in which the ICs 373 and 375 are provided on the substrate 351 by a chip on glass (COG) method or the like. As the ICs 373 and 375, an IC functioning as a scan line driver circuit or the like can be used. Note that it is possible that the ICs 373 and 375 are not provided, for example, when the display device 300 includes circuits functioning as a scan line driver circuit and a signal line driver circuit and when the circuits functioning as a scan line driver circuit and a signal line driver circuit are provided outside and signals for driving the display device 300 are input through the FPCs 372 and 374. Alternatively, the ICs 373 and 375 may be mounted on the substrate 351 by a chip on film (COF) method or the like.

FIG. 23A is an enlarged view of part of the display portion 362a. The display portion 362a corresponds to the display regions 11a and 11b described in Embodiment 1. Electrodes 311b included in a plurality of display elements are arranged in a matrix in the display portion 362a. The electrode 311b has a function of reflecting visible light and serves as a reflective electrode of the liquid crystal element 340 described later.

As illustrated in FIG. 23A, the electrode 311b has an opening. The light-emitting element 360 is positioned closer to the substrate 351 than the electrode 311b is. Light is emitted from the light-emitting element 360 to the substrate 361 side through the opening in the electrode 311b.

Note that the display region 11b described in Embodiment 1 corresponds to the display portion 362b. The display portion 362b may have a display element having a size different from that of the display portion 362a.

### Cross-Sectional Structure Examples

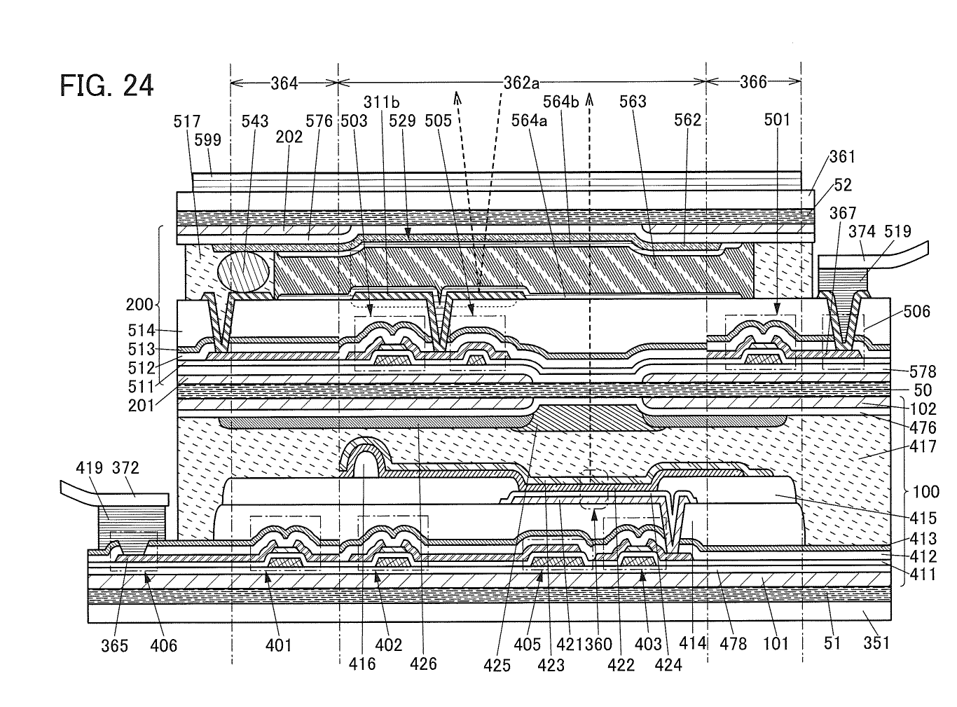

FIG. 24 illustrates an example of cross sections of part of a region including the FPC 372, part of a region including the circuit portion 364, part of a region including the display portion 362a, part of a region including the circuit portion 366, and part of a region including the FPC 374 of the display device 300 illustrated in FIG. 23A.

The display device illustrated in FIG. 24 includes a structure in which the display panels 100 and 200 are stacked. The display panel 100 includes the resin layers 101 and 102. The display panel 200 includes the resin layers 201 and 202.

The resin layers 102 and 201 are bonded to each other with the adhesive layer 50. The resin layer 101 is bonded to the substrate 351 with the adhesive layer 51. The resin layer 202 is bonded to the substrate 361 with the adhesive layer 52.

### [Display Panel 100]

The display panel 100 includes the resin layer 101, an insulating layer 478, a plurality of transistors, a capacitor 405, the wiring 365, an insulating layer 411, an insulating layer 412, an insulating layer 413, an insulating layer 414, an insulating layer 415, the light-emitting element 360, a spacer 416, an adhesive layer 417, a coloring layer 425, a light-blocking layer 426, an insulating layer 476, and the resin layer 102.

The resin layer 102 has an opening in a region overlapping with the light-emitting element 360.

The circuit portion 364 includes a transistor 401. The display portion 362a includes a transistor 402 and a transistor 403.

Each of the transistors includes a gate, the insulating layer 411, a semiconductor layer, a source, and a drain. The gate and the semiconductor layer overlap with each other with the insulating layer 411 provided therebetween. Part of the insulating layer 411 functions as a gate insulating layer, and another part of the insulating layer 411 functions as a dielectric of the capacitor 405. A conductive layer that functions as the source or the drain of the transistor 402 also functions as one electrode of the capacitor 405.

The transistors illustrated in FIG. 24 have bottom-gate structures. The transistor structures may be different between the circuit portion 364 and the display portion 362a. The circuit portion 364 and the display portion 362a may each include a plurality of kinds of transistors.

The capacitor 405 includes a pair of electrodes and the dielectric therebetween. The capacitor 405 includes a conductive layer that is formed using the same material and the same process as the gates of the transistors, and a conductive layer that is formed using the same material and the same process as the sources and the drains of the transistors.

The insulating layer 412, the insulating layer 413, and the insulating layer 414 are each provided to cover the transistors and the like. There is no particular limitation on the number of the insulating layers covering the transistors and the like. The insulating layer 414 functions as a planarization layer. It is preferred that at least one of the insulating layer 412, the insulating layer 413, and the insulating layer 414 be formed using a material inhibiting diffusion of impurities such as water and hydrogen. Diffusion of impurities from the outside into the transistors can be effectively inhibited, leading to improved reliability of the display panel.

In the case of using an organic material for the insulating layer 414, impurities such as moisture might enter the light-emitting element 360 or the like from the outside of the display panel through the insulating layer 414 exposed at an end portion of the display panel. Deterioration of the light-emitting element 360 due to the entry of impurities can lead to deterioration of the display panel. For this reason, the insulating layer 414 is preferably not positioned at the end portion of the display panel, as illustrated in FIG. 24. Since an insulating layer formed using an organic material is not positioned at the end portion of the display panel in the structure of FIG. 24, entry of impurities into the light-emitting element 360 can be inhibited.

The light-emitting element 360 includes an electrode 421, an EL layer 422, and an electrode 423. The light-emitting element 360 may include an optical adjustment layer 424. The light-emitting element 360 has a top-emission structure with which light is emitted to the coloring layer 425 side.

The transistors, the capacitor, the wiring, and the like are positioned so as to overlap with a light-emitting region of the light-emitting element 360; accordingly, the aperture ratio of the display portion 362a can be increased.

One of the electrode 421 and the electrode 423 functions as an anode and the other functions as a cathode. When a voltage higher than the threshold voltage of the light-emitting element 360 is applied between the electrode 421 and the electrode 423, holes are injected to the EL layer 422 from the anode side and electrons are injected to the EL layer 422 from the cathode side. The injected electrons and holes are recombined in the EL layer 422 and a light-emitting substance contained in the EL layer 422 emits light.

The electrode 421 is electrically connected to the source or the drain of the transistor 403 directly or through a conductive layer. The electrode 421 functioning as a pixel electrode is provided for each light-emitting element 360. Two adjacent electrodes 421 are electrically insulated from each other by the insulating layer 415.

The EL layer 422 contains a light-emitting substance.

The electrode 423 functioning as a common electrode is shared by a plurality of light-emitting elements 360. A fixed potential is supplied to the electrode 423.

The light-emitting element 360 overlaps with the coloring layer 425 with the adhesive layer 417 provided therebetween. The spacer 416 overlaps with the light-blocking layer 426 with the adhesive layer 417 provided therebetween. Although FIG. 24 illustrates the case where a space is provided between the electrode 423 and the light-blocking layer 426, the electrode 423 and the light-blocking layer 426 may be in contact with each other. Although the spacer 416 is provided on the substrate 351 side in the structure illustrated in FIG. 24, the spacer 416 may be provided on the substrate 361 side (e.g., in a position closer to the substrate 351 than the light-blocking layer 426).

Owing to the combination of a color filter (the coloring layer 425) and a microcavity structure (the optical adjustment layer 424), light with high color purity can be extracted from the display panel. The thickness of the optical adjustment layer 424 is varied depending on the color of the pixel.

The coloring layer 425 is a coloring layer that transmits light in a specific wavelength range. For example, a color filter for transmitting light in a red, green, blue, or yellow wavelength range can be used.

Note that one embodiment of the present invention is not limited to a color filter method, and a separate coloring method, a color conversion method, a quantum dot method, and the like may be employed.

The light-blocking layer 426 is provided between the adjacent coloring layers 425. The light-blocking layer 426 blocks light emitted from the adjacent light-emitting element 360 to inhibit color mixture between the adjacent light-emitting elements 360. Here, the coloring layer 425 is provided such that its end portion overlaps with the light-blocking layer 426, whereby light leakage can be reduced. For the light-blocking layer 426, a material that blocks light emitted from the light-emitting element 360 can be used. Note that it is preferable to provide the light-blocking layer 426 in a region other than the display portion 362a, such as the circuit portion 364, in which case undesired leakage of guided light or the like can be inhibited.

The insulating layer 478 is formed on a surface of the resin layer 101. The insulating layer 476 is formed on a surface of the resin layer 102. The insulating layer 476 and the insulating layer 478 are preferably highly resistant to moisture. The light-emitting element 360, the transistors, and the like are preferably provided between a pair of insulating layers that are highly resistant to moisture, in which case impurities such as water can be prevented from entering these elements, leading to an increase in the reliability of the display panel.

Examples of the insulating film highly resistant to moisture include a film containing nitrogen and silicon (e.g., a silicon nitride film and a silicon nitride oxide film) and a film containing nitrogen and aluminum (e.g., an aluminum nitride film). Alternatively, a silicon oxide film, a silicon oxynitride film, an aluminum oxide film, or the like may be used.

For example, the moisture vapor transmission rate of the insulating film highly resistant to moisture is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

A connection portion 406 includes the wiring 365. The wiring 365 can be formed using the same material and the same process as those of the sources and the drains of the transistors. The connection portion 406 is electrically connected to an external input terminal through which a signal and a potential from the outside are transmitted to the circuit portion 364. Here, an example in which the FPC 372 is provided as the external input terminal is described. The FPC 372 is electrically connected to the connection portion 406 through a connection layer 419.

The connection layer 419 can be formed using any of various kinds of anisotropic conductive films (ACF), anisotropic conductive pastes (ACP), and the like.

The above is the description of the display panel 100.

### [Display Panel 200]

The display panel 200 is a reflective liquid crystal display panel employing a vertical electric field mode.

The display panel 200 includes the resin layer 201, an insulating layer 578, a plurality of transistors, a capacitor 505, the wiring 367, an insulating layer 511, an insulating layer 512, an insulating layer 513, an insulating layer 514, a liquid crystal element 529, an alignment film 564a, an alignment film 564b, an adhesive layer 517, an insulating layer 576, and the resin layer 202.

The resin layers 201 and 202 are bonded to each other with the adhesive layer 517. Liquid crystal 563 is sealed in a region surrounded by the resin layer 201, the resin layer 202, and the adhesive layer 517. A polarizing plate 599 is positioned on an outer surface of the substrate 361.

Furthermore, an opening overlapping with the light-emitting element 360 is formed in the resin layer 201. An opening overlapping with the liquid crystal element 529 and the light-emitting element 360 is formed in the resin layer 202.

The liquid crystal element 529 includes the electrode 311b, an electrode 562, and the liquid crystal 563. The electrode 311b functions as a pixel electrode. The electrode 562 functions as a common electrode. Alignment of the liquid crystal 563 can be controlled with an electric field generated between the electrode 311b and the electrode 562. The alignment film 564a is provided between the liquid crystal 563 and the electrode 311b. The alignment film 564b is provided between the liquid crystal 563 and the electrode 562.

The resin layer 202 is provided with the insulating layer 576, the electrode 562, the alignment film 564b, and the like.

The resin layer 201 is provided with the electrode 311b, the alignment film 564a, a transistor 501, a transistor 503, the capacitor 505, a connection portion 506, the wiring 367, and the like.

Insulating layers such as the insulating layer 511, the insulating layer 512, the insulating layer 513, and the insulating layer 514 are provided over the resin layer 201.

Note that a portion of the conductive layer functioning as the source or the drain of the transistor 503 that is not electrically connected to the electrode 311b may function as part of a signal line. The conductive layer functioning as the gate of the transistor 503 may function as part of a scan line.

FIG. 24 illustrates a structure without a coloring layer as an example of the display portion 362a. Thus, the liquid crystal element 529 is an element that performs monochrome display.

FIG. 24 illustrates an example of the circuit portion 366 in which the transistor 501 is provided.

A material inhibiting diffusion of impurities such as water and hydrogen is preferably used for at least one of the insulating layers 512 and 513 that cover the transistors.

The electrode 311b is provided over the insulating layer 514. The electrode 311b is electrically connected to one of a source and a drain of the transistor 503 through an opening formed in the insulating layer 514, the insulating layer 513, the insulating layer 512, and the like. The electrode 311b is electrically connected to one electrode of the capacitor 505.

Since the display panel 200 is a reflective liquid crystal display panel, a conductive material that reflects visible light is used for the electrode 311b and a conductive material that transmits visible light is used for the electrode 562.

For example, a material containing one or more of indium (In), zinc (Zn), and tin (Sn) is preferably used as the conductive material that transmits visible light. Specifically, indium oxide, indium tin oxide (ITO), indium zinc oxide, indium oxide containing tungsten oxide, indium zinc oxide containing tungsten oxide, indium oxide containing titanium oxide, indium tin oxide containing titanium oxide, indium tin oxide containing silicon oxide (ITSO), zinc oxide, and zinc oxide containing gallium are given, for example. Note that a film including graphene can be used as well. The film including graphene can be formed, for example, by reducing a film containing graphene oxide.

Examples of the conductive material that reflects visible light include aluminum, silver, and an alloy including any of these metal materials. A metal material such as gold, platinum, tungsten, chromium, molybdenum, iron, cobalt, copper, or palladium, or an alloy including any of these metal materials can also be used. Lanthanum, neodymium, germanium, or the like may be added to the metal material or the alloy. Furthermore, an alloy containing aluminum (an aluminum alloy) such as an alloy of aluminum and titanium, an alloy of aluminum and nickel, an alloy of aluminum and neodymium, or an alloy of aluminum, nickel, and lanthanum (Al—Ni—La), or an alloy containing silver such as an alloy of silver and copper, an alloy of silver, palladium, and copper (also referred to as Ag—Pd—Cu or APC), or an alloy of silver and magnesium may be used.

As the polarizing plate 599, a linear polarizing plate or a circularly polarizing plate can be used. An example of a circularly polarizing plate is a stack including a linear polarizing plate and a quarter-wave retardation plate. Such a structure can reduce reflection of external light. The cell gap, alignment, drive voltage, and the like of the liquid crystal element used as the liquid crystal element 529 are controlled in accordance with the kind of the polarizing plate 599 so that desirable contrast is obtained.

The electrode 562 is electrically connected to a conductive layer on the resin layer 201 side through a connector 543 in a portion close to an end portion of the resin layer 202. Thus, a potential or a signal can be supplied from the FPC 374, an IC, or the like placed on the resin layer 201 side to the electrode 562.

As the connector 543, a conductive particle can be used, for example. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. As the connector 543, a material capable of elastic deformation or plastic deformation is preferably used. As illustrated in FIG. 24, the connector 543, which is the conductive particle, has a shape that is vertically crushed in some cases. With the crushed shape, the contact area between the connector 543 and a conductive layer electrically connected to the connector 543 can be increased, thereby reducing contact resistance and suppressing the generation of problems such as disconnection.

The connector 543 is preferably provided so as to be covered with the adhesive layer 517. For example, the connectors 543 are dispersed in the adhesive layer 517 before curing of the adhesive layer 517.

The connection portion 506 is provided in a region near an end portion of the resin layer 201. The connection portion 506 is electrically connected to the FPC 374 through a connection layer 519. In the example of the structure illustrated in FIG. 24, the connection portion 506 is formed by stacking part of the wiring 367 and a conductive layer that is obtained by processing the same conductive film as the electrode 311b.

The above is the description of the display panel 200.

### [Components]

The above components are described below.

### [Substrate]

A material having a flat surface can be used as the substrate included in the display panel. The substrate on the side from which light from the display element is extracted is formed using a material transmitting the light. For example, a material such as glass, quartz, ceramics, sapphire, or an organic resin can be used.

The weight and thickness of the display panel can be reduced by using a thin substrate. A flexible display panel can be obtained by using a substrate that is thin enough to have flexibility.

Since the substrate through which light is not extracted does not need to have a light-transmitting property, a metal substrate or the like can be used, other than the above-mentioned substrates. A metal substrate, which has high thermal conductivity, is preferable because it can easily conduct heat to the whole substrate and accordingly can prevent a local temperature rise in the display panel. To obtain flexibility and bendability, the thickness of a metal substrate is preferably greater than or equal to 10 μm and less than or equal to 400 μm, further preferably greater than or equal to 20 μm and less than or equal to 50 μm.

Although there is no particular limitation on a material of a metal substrate, it is favorable to use, for example, a metal such as aluminum, copper, and nickel, an aluminum alloy, or an alloy such as stainless steel.

It is possible to use a substrate subjected to insulation treatment, e.g., a metal substrate whose surface is oxidized or provided with an insulating film. The insulating film may be formed by, for example, a coating method such as a spin-coating method or a dipping method, an electrodeposition method, an evaporation method, or a sputtering method. An oxide film may be formed on the substrate surface by exposure to or heating in an oxygen atmosphere or by an anodic oxidation method or the like.

Examples of the material that has flexibility and transmits visible light include glass that is thin enough to have flexibility, polyester resins such as polyethylene terephthalate (PET) and polyethylene naphthalate (PEN), a polyacrylonitrile resin, a polyimide resin, a polymethyl methacrylate resin, a polycarbonate (PC) resin, a polyethersulfone (PES) resin, a polyamide resin, a cycloolefin resin, a polystyrene resin, a polyamide imide resin, a polyvinyl chloride resin, and a polytetrafluoroethylene (PTFE) resin. It is particularly preferable to use a material with a low thermal expansion coefficient, for example, a material with a thermal expansion coefficient lower than or equal to 30×10⁻⁶/K, such as a polyamide imide resin, a polyimide resin, or PET. A substrate in which a glass fiber is impregnated with an organic resin or a substrate whose thermal expansion coefficient is reduced by mixing an inorganic filler with an organic resin can also be used. A substrate using such a material is lightweight, and thus a display panel using this substrate can also be lightweight.

In the case where a fibrous body is included in the above material, a high-strength fiber of an organic compound or an inorganic compound is used as the fibrous body. The high-strength fiber is specifically a fiber with a high tensile elastic modulus or a fiber with a high Young's modulus. Typical examples thereof include a polyvinyl alcohol-based fiber, a polyester-based fiber, a polyamide-based fiber, a polyethylene-based fiber, an aramid-based fiber, a polyparaphenylene benzobisoxazole fiber, a glass fiber, and a carbon fiber. As the glass fiber, a glass fiber using E glass, S glass, D glass, Q glass, or the like can be used. These fibers may be used in a state of a woven or nonwoven fabric, and a structure body in which this fibrous body is impregnated with a resin and the resin is cured may be used as the flexible substrate. The structure body including the fibrous body and the resin is preferably used as the flexible substrate, in which case the reliability against breaking due to bending or local pressure can be increased.

Alternatively, glass, metal, or the like that is thin enough to have flexibility can be used as the substrate. Alternatively, a composite material where glass and a resin material are attached to each other with an adhesive layer may be used.

A hard coat layer (e.g., a silicon nitride layer and an aluminum oxide layer) by which a surface of a display panel is protected from damage, a layer (e.g., an aramid resin layer) that can disperse pressure, or the like may be stacked over the flexible substrate. Furthermore, to suppress a decrease in lifetime of the display element due to moisture and the like, an insulating film with low water permeability may be stacked over the flexible substrate. For example, an inorganic insulating material such as silicon nitride, silicon oxynitride, silicon nitride oxide, aluminum oxide, or aluminum nitride can be used.

The substrate may be formed by stacking a plurality of layers. When a glass layer is used, a barrier property against water and oxygen can be improved and thus a highly reliable display panel can be provided.

### [Transistor]

The transistor includes a conductive layer serving as a gate electrode, a semiconductor layer, a conductive layer serving as a source electrode, a conductive layer serving as a drain electrode, and an insulating layer serving as a gate insulating layer. In the above, a bottom-gate transistor is used.

Note that there is no particular limitation on the structure of the transistor included in the display device of one embodiment of the present invention. For example, a planar transistor, a staggered transistor, or an inverted staggered transistor can be used. A top-gate transistor or a bottom-gate transistor may also be used. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. It is preferred that a semiconductor having crystallinity be used, in which case deterioration of the transistor characteristics can be suppressed.

As a semiconductor material used for the transistors, an oxide semiconductor whose energy gap is greater than or equal to 2 eV, preferably greater than or equal to 2.5 eV, further preferably greater than or equal to 3 eV can be used. A typical example thereof is an oxide semiconductor containing indium, and for example, a CAC-OS described later or the like can be used.

A transistor with an oxide semiconductor having a larger band gap and a lower carrier density than silicon has a low off-state current, and therefore, charges stored in a capacitor that is series-connected to the transistor can be held for a long time.

The semiconductor layer can be, for example, a film represented by an In-M-Zn-based oxide that contains indium, zinc, and M (a metal such as aluminum, titanium, gallium, germanium, yttrium, zirconium, lanthanum, cerium, tin, neodymium, or hafnium).

In the case where the oxide semiconductor contained in the semiconductor layer is an In-M-Zn-based oxide, it is preferable that the atomic ratio of metal elements of a sputtering target used to deposit a film of the In-M-Zn oxide satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, or In:M:Zn=5:1:8. Note that the atomic ratio of metal elements in the formed oxide semiconductor layer varies from the above atomic ratios of metal elements of the sputtering targets in a range of ±40%.

The bottom-gate transistor described in this embodiment is preferable because the number of manufacturing steps can be reduced. When an oxide semiconductor, which can be formed at a lower temperature than polycrystalline silicon, is used, materials with low heat resistance can be used for a wiring, an electrode, or a substrate below the semiconductor layer, so that the range of choices of materials can be widened. For example, an extremely large glass substrate can be favorably used.

### [Conductive Layer]

As materials for the gates, the source, and the drain of a transistor, and the conductive layers serving as the wirings and electrodes included in the display device, any of metals such as aluminum, titanium, chromium, nickel, copper, yttrium, zirconium, molybdenum, silver, tantalum, and tungsten, or an alloy containing any of these metals as its main component can be used. A single-layer structure or a layered structure including a film containing any of these materials can be used. For example, the following structures can be given: a single-layer structure of an aluminum film containing silicon, a two-layer structure in which an aluminum film is stacked over a titanium film, a two-layer structure in which an aluminum fihn is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which a titanium film or a titanium nitride film, an aluminum film or a copper film, and a titanium film or a titanium nitride film are stacked in this order, and a three-layer structure in which a molybdenum film or a molybdenum nitride film, an aluminum film or a copper film, and a molybdenum film or a molybdenum nitride film are stacked in this order. Note that an oxide such as indium oxide, tin oxide, or zinc oxide may be used. Copper containing manganese is preferably used because controllability of a shape by etching is increased.

As a light-transmitting conductive material, a conductive oxide such as indium oxide, indium tin oxide, indium zinc oxide, zinc oxide, or zinc oxide to which gallium is added, or graphene can be used. Alternatively, a metal material such as gold, silver, platinum, magnesium, nickel, tungsten, chromium, molybdenum, iron, cobalt, copper, palladium, or titanium or an alloy material containing any of these metal materials can be used. Alternatively, a nitride of the metal material (e.g., titanium nitride) or the like may be used. In the case of using the metal material or the alloy material (or the nitride thereof), the thickness is set small enough to allow light transmission. Alternatively, a layered film of any of the above materials can be used as the conductive layer. For example, a layered film of indium tin oxide and an alloy of silver and magnesium is preferably used because the conductivity can be increased. They can also be used for conductive layers such as a variety of wirings and electrodes included in a display device, and conductive layers (e.g., conductive layers serving as a pixel electrode or a common electrode) included in a display element.

### [Insulating Layer]

As an insulating material that can be used for the insulating layers, polyimide, acrylic, epoxy, a silicone resin, or an inorganic insulating material such as silicon oxide, silicon oxynitride, silicon nitride oxide, silicon nitride, or aluminum oxide can be used.

The light-emitting element is preferably provided between a pair of insulating films with low water permeability, in which case entry of impurities such as water into the light-emitting element can be inhibited. Thus, a decrease in device reliability can be suppressed.

As an insulating film with low water permeability, a film containing nitrogen and silicon, such as a silicon nitride film or a silicon nitride oxide film, a film containing nitrogen and aluminum, such as an aluminum nitride film, or the like can be used. Alternatively, a silicon oxide film, a silicon oxynitride film, an aluminum oxide film, or the like may be used.

For example, the amount of water vapor transmission of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

### [Display Element]

As a display element included in the first pixel located on the display surface side, an element that performs display by reflecting external light can be used. Such an element does not include a light source and thus power consumption in display can be significantly reduced. As the display element included in the first pixel, a reflective liquid crystal element can typically be used. Alternatively, as the display element included in the first pixel, an element using a microcapsule method, an electrophoretic method, an electrowetting method, an Electronic Liquid Powder (registered trademark) method, or the like can be used, other than a Micro Electro Mechanical Systems (MEMS) shutter element or an optical interference type MEMS element.

As a display element included in the second pixel located on the side opposite to the display surface side, an element that includes a light source and performs display using light from the light source can be used. Since the luminance and the chromaticity of light emitted from such a pixel are not affected by external light, an image with high color reproducibility (a wide color gamut) and a high contrast, i.e., a clear image can be displayed. As the display element included in the second pixel, a self-luminous light-emitting element such as an organic light-emitting diode (OLED), a light-emitting diode (LED), and a quantum-dot light-emitting diode (QLED) can be used. Alternatively, a combination of a backlight as a light source and a transmissive liquid crystal element that controls the amount of transmitted light emitted from a backlight may be used as the display element included in the second pixel.

### [Liquid Crystal Element]

The liquid crystal element can employ, for example, a vertical alignment (VA) mode. Examples of the vertical alignment mode include a multi-domain vertical alignment (MVA) mode, a patterned vertical alignment (PVA) mode, and an advanced super view (ASV) mode.

The liquid crystal element can employ a variety of modes; for example, other than the VA mode, a twisted nematic (TN) mode, an in-plane switching (IPS) mode, an in-plane switching-vertical alignment (IPS-VA) mode, a fringe field switching (FFS) mode, an axially symmetric aligned micro-cell (ASM) mode, an optically compensated birefringence (OCB) mode, a ferroelectric liquid crystal (FLC) mode, or an antiferroelectric liquid crystal (AFLC) mode can be used.

The liquid crystal element controls transmission or non-transmission of light utilizing an optical modulation action of liquid crystal. Note that the optical modulation action of liquid crystal is controlled by an electric field applied to the liquid crystal (including a horizontal electric field, a vertical electric field, and an oblique electric field). As the liquid crystal used for the liquid crystal element, thermotropic liquid crystal, low-molecular liquid crystal, high-molecular liquid crystal, polymer dispersed liquid crystal (PDLC), ferroelectric liquid crystal, anti-ferroelectric liquid crystal, or the like can be used. These liquid crystal materials exhibit a cholesteric phase, a smectic phase, a cubic phase, a chiral nematic phase, an isotropic phase, or the like depending on conditions.

As the liquid crystal material, either a positive liquid crystal or a negative liquid crystal may be used, and an appropriate liquid crystal material can be used depending on the mode or design to be used.

An alignment film can be provided to adjust the alignment of liquid crystal. In the case where a horizontal electric field mode is employed, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which a chiral material is mixed to account for several weight percent or more is used for the liquid crystal layer in order to improve the temperature range. The liquid crystal composition that includes liquid crystal exhibiting a blue phase and a chiral material has a short response time and has optical isotropy. In addition, the liquid crystal composition that includes liquid crystal exhibiting a blue phase and a chiral material does not need alignment treatment and has small viewing angle dependence. An alignment film is not necessarily provided and rubbing treatment is thus not necessary; accordingly, electrostatic discharge damage caused by the rubbing treatment can be prevented and defects and damage of the liquid crystal display panel in the manufacturing process can be reduced.

The dielectric anisotropy and resistivity of the liquid crystal layer are preferably greater than or equal to 2 and less than or equal to 3.8 and higher than or equal to 1.0×10¹⁴ Ωcm and lower than or equal to 1.0×10¹⁵ Ωcm, respectively. In that case, the IDS driving can be performed and power consumption of the display device can be reduced.

In one embodiment of the present invention, in particular, a reflective liquid crystal element can be used.

In the case where a reflective liquid crystal element is used, a polarizing plate is provided on the display surface side. In addition, a light diffusion plate is preferably provided on the display surface side to improve visibility.

In the case where the reflective or the semi-transmissive liquid crystal element is used, a front light may be provided outside the polarizing plate. As the front light, an edge-light front light is preferably used. A front light including a light-emitting diode (LED) is preferably used to reduce power consumption.

### [Light-Emitting Element]

As the light-emitting element, a self-luminous element can be used, and an element whose luminance is controlled by current or voltage is included in the category of the light-emitting element. For example, an LED, a QLED, an organic EL element, an inorganic EL element, or the like can be used.

In one embodiment of the present invention, in particular, the light-emitting element preferably has a top emission structure. A conductive film that transmits visible light is used as the electrode through which light is extracted. A conductive film that reflects visible light is preferably used as the electrode through which light is not extracted.

The EL layer includes at least a light-emitting layer. In addition to the light-emitting layer, the EL layer may further include one or more layers containing any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

For the EL layer, either a low-molecular compound or a high-molecular compound can be used, and an inorganic compound may also be used. Each of the layers included in the EL layer can be formed by any of the following methods: an evaporation method (including a vacuum evaporation method), a transfer method, a printing method, an inkjet method, a coating method, and the like.

When a voltage higher than the threshold voltage of the light-emitting element is applied between a cathode and an anode, holes are injected to the EL layer from the anode side and electrons are injected to the EL layer from the cathode side. The injected electrons and holes are recombined in the EL layer and a light-emitting substance contained in the EL layer emits light.

In the case where a light-emitting element emitting white light is used as the light-emitting element, the EL layer preferably contains two or more kinds of light-emitting substances. For example, the two or more kinds of light-emitting substances are selected so as to emit light of complementary colors to obtain white light emission. Specifically, it is preferable to contain two or more selected from light-emitting substances that emit light of red (R), green (G), blue (B), yellow (Y), orange (O), and the like and light-emitting substances that emit light containing two or more of spectral components of R, G, and B. The light-emitting element preferably emits light with a spectrum having two or more peaks in the wavelength range of a visible light region (e.g., 350 nm to 0.750 nm). An emission spectrum of a material that emits light having a peak in a yellow wavelength range preferably includes spectral components also in green and red wavelength ranges.

A light-emitting layer containing a light-emitting material that emits light of one color and a light-emitting layer containing a light-emitting material that emits light of another color are preferably stacked in the EL layer. For example, the plurality of light-emitting layers in the EL layer may be stacked in contact with each other or may be stacked with a region not including any light-emitting material therebetween. For example, between a fluorescent layer and a phosphorescent layer, a region containing the same material as one in the fluorescent layer or the phosphorescent layer (for example, a host material or an assist material) and no light-emitting material may be provided. This facilitates the manufacture of the light-emitting element and reduces the drive voltage.

The light-emitting element may be a single element including one EL layer or a tandem element in which a plurality of EL layers are stacked with a charge generation layer therebetween.

Note that the aforementioned light-emitting layer and layers containing a substance with a high hole-injection property, a substance with a high hole-transport property, a substance with a high electron-transport property, a substance with a high electron-injection property, a substance with a bipolar property, and the like may include an inorganic compound such as a quantum dot or a high molecular compound (e.g., an oligomer, a dendrimer, and a polymer). For example, when used for the light-emitting layer, the quantum dot can function as a light-emitting material.

The quantum dot material may be a colloidal quantum dot material, an alloyed quantum dot material, a core-shell quantum dot material, a core quantum dot material, or the like. A material containing elements belonging to Groups 12 and 16, elements belonging to Groups 13 and 15, or elements belonging to Groups 14 and 16 may be used. Alternatively, a quantum dot material containing an element such as cadmium, selenium, zinc, sulfur, phosphorus, indium, tellurium, lead, gallium, arsenic, or aluminum may be used.

The conductive film that transmits visible light can be formed using, for example, indium oxide, indium tin oxide, indium zinc oxide, zinc oxide, or zinc oxide to which gallium is added. Alternatively, a film of a metal material such as gold, silver, platinum, magnesium, nickel, tungsten, chromium, molybdenum, iron, cobalt, copper, palladium, or titanium; an alloy containing any of these metal materials; or a nitride of any of these metal materials (e.g., titanium nitride) can be formed thin so as to have a light-transmitting property. Alternatively, a stack of any of the above materials can be used for the conductive layers. For example, a stack of indium tin oxide and an alloy of silver and magnesium is preferably used, in which case conductivity can be increased. Still alternatively, graphene or the like may be used.

For the conductive film that reflects visible light, for example, a metal material such as aluminum, gold, platinum, silver, nickel, tungsten, chromium, molybdenum, iron, cobalt, copper, or palladium or an alloy containing any of these metal materials can be used. Furthermore, lanthanum, neodymium, germanium, or the like may be added to the metal material or the alloy. Alternatively, an alloy containing aluminum (an aluminum alloy) such as an alloy of aluminum and titanium, an alloy of aluminum and nickel, or an alloy of aluminum and neodymium may be used. Alternatively, an alloy containing silver such as an alloy of silver and copper, an alloy of silver and palladium, or an alloy of silver and magnesium may be used. An alloy containing silver and copper is preferable because of its high heat resistance. Furthermore, when a metal film or a metal oxide film is stacked in contact with an aluminum film or an aluminum alloy film, oxidation can be suppressed. Examples of a material for the metal film or the metal oxide film include titanium and titanium oxide. Alternatively, the above conductive film that transmits visible light and a film containing a metal material may be stacked. For example, a stack of silver and indium tin oxide, a stack of an alloy of silver and magnesium and indium tin oxide, or the like can be used.

Each of the electrodes may be formed by an evaporation method or a sputtering method. Alternatively, a discharging method such as an inkjet method, a printing method such as a screen printing method, or a plating method can be used.

Note that the aforementioned light-emitting layer and layers containing a substance with a high hole-injection property, a substance with a high hole-transport property, a substance with a high electron-transport property, a substance with a high electron-injection property, and a substance with a bipolar property may include an inorganic compound such as a quantum dot or a high molecular compound (e.g., an oligomer, a dendrimer, and a polymer). For example, used for the light-emitting layer, the quantum dot can serve as a light-emitting material.

The quantum dot material may be a colloidal quantum dot material, an alloyed quantum dot material, a core-shell quantum dot material, a core quantum dot material, or the like. A material containing elements belonging to Groups 12 and 16, elements belonging to Groups 13 and 15, or elements belonging to Groups 14 and 16 may be used. Alternatively, a quantum dot material containing an element such as cadmium, selenium, zinc, sulfur, phosphorus, indium, tellurium, lead, gallium, arsenic, or aluminum may be used.

### [Adhesive Layer]

As the adhesive layer, any of a variety of curable adhesives, e.g., a photo-curable adhesive such as an ultraviolet curable adhesive, a reactive curable adhesive, a thermosetting curable adhesive, and an anaerobic adhesive can be used. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene vinyl acetate (EVA) resin. In particular, a material with low moisture permeability, such as an epoxy resin, is preferred. Alternatively, a two-component-mixture-type resin may be used. Still alternatively, an adhesive sheet or the like may be used.

Furthermore, the resin may include a drying agent. For example, a substance that adsorbs moisture by chemical adsorption, such as oxide of an alkaline earth metal (e.g., calcium oxide or barium oxide), can be used. Alternatively, a substance that adsorbs moisture by physical adsorption, such as zeolite or silica gel, may be used. The drying agent is preferably included because it can inhibit entry of impurities such as moisture into an element, leading to an improvement in the reliability of the display panel.

In addition, a filler with a high refractive index or a light-scattering member may be mixed into the resin, in which case light extraction efficiency can be improved. For example, titanium oxide, barium oxide, zeolite, or zirconium can be used.

### [Connection Layer]

As a connection layer, an anisotropic conductive film (ACF), an anisotropic conductive paste (ACP), or the like can be used.

### [Coloring Layer]

Examples of materials that can be used for the coloring layer include a metal material, a resin material, and a resin material containing a pigment or dye.

### [Light-Blocking Layer]

Examples of a material that can be used for the light-blocking layer include carbon black, titanium black, a metal, a metal oxide, and a composite oxide containing a solid solution of a plurality of metal oxides. The light-blocking layer may be a film containing a resin material or a thin film of an inorganic material such as a metal. Stacked films containing the material of the coloring layer can also be used for the light-blocking layer. For example, a stacked structure of a film containing a material of a coloring layer that transmits light of a certain color and a film containing a material of a coloring layer that transmits light of another color can be employed. It is preferred that the coloring layer and the light-blocking layer be formed using the same material because the same manufacturing apparatus can be used and the process can be simplified.

The above is the description of each of the components.

### Modification Example

Structure examples that partly differ from the display panel described in the above cross-sectional structure example are described below. Note that the description of the portions already described above is omitted and only different portions are described.

### Modification Example 1 of Cross-Sectional Structure Example

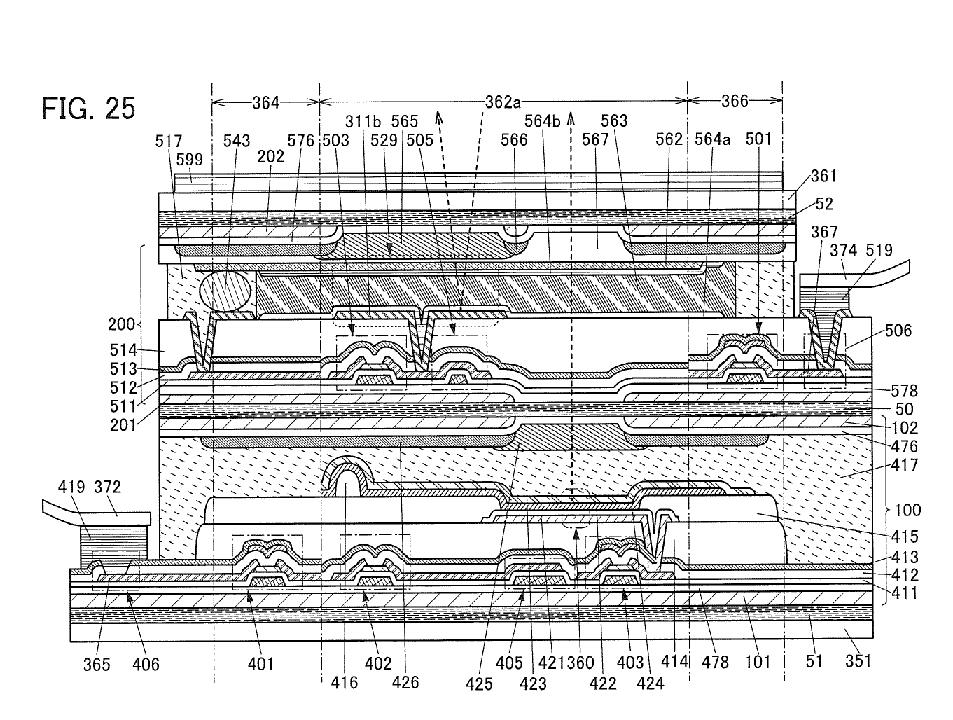

FIG. 25 is different from FIG. 24 in the structures of transistors and the resin layer 202 and in that a coloring layer 565, a light-blocking layer 566, and an insulating layer 567 are provided.

The transistors 401, 403, and 501 illustrated in FIG. 25 each include a second gate electrode. In this manner, a transistor including a pair of gates is preferably used as each of the transistors provided in the circuit portion 364 and the circuit portion 366 and the transistor that controls current flowing to the light-emitting element 360.

In the resin layer 202, an opening overlapping with the liquid crystal element 529 and an opening overlapping with the light-emitting element 360 are separately formed, whereby the reflectance of the liquid crystal element 529 can be increased.

The light-blocking layer 566 and the coloring layer 565 are provided on a surface of the insulating layer 576 on the liquid crystal element 529 side. The coloring layer 565 is provided so as to overlap with the liquid crystal element 529. Thus, the display panel 200 can perform color display. The light-blocking layer 566 has an opening overlapping with the liquid crystal element 529 and an opening overlapping with the light-emitting element 360. This allows fabrication of a display device that suppresses mixing of colors between adjacent pixels and thus has high color reproducibility.

### Modification Example 2 of Cross-Sectional Structure Example

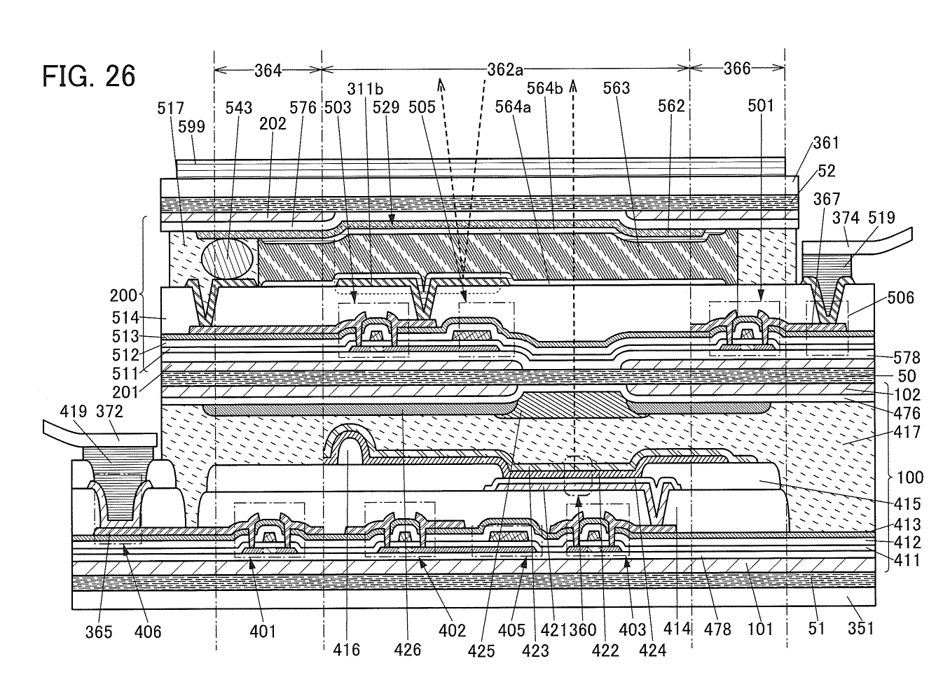

FIG. 26 illustrates an example in which a top-gate transistor is used as each transistor. The use of a top-gate transistor can reduce parasitic capacitance, leading to an increase in the frame frequency of display. Furthermore, a top-gate transistor can favorably be used for a large display panel with a size of 8 inches or more.

### Modification Example 3 of Cross-Sectional Structure Example

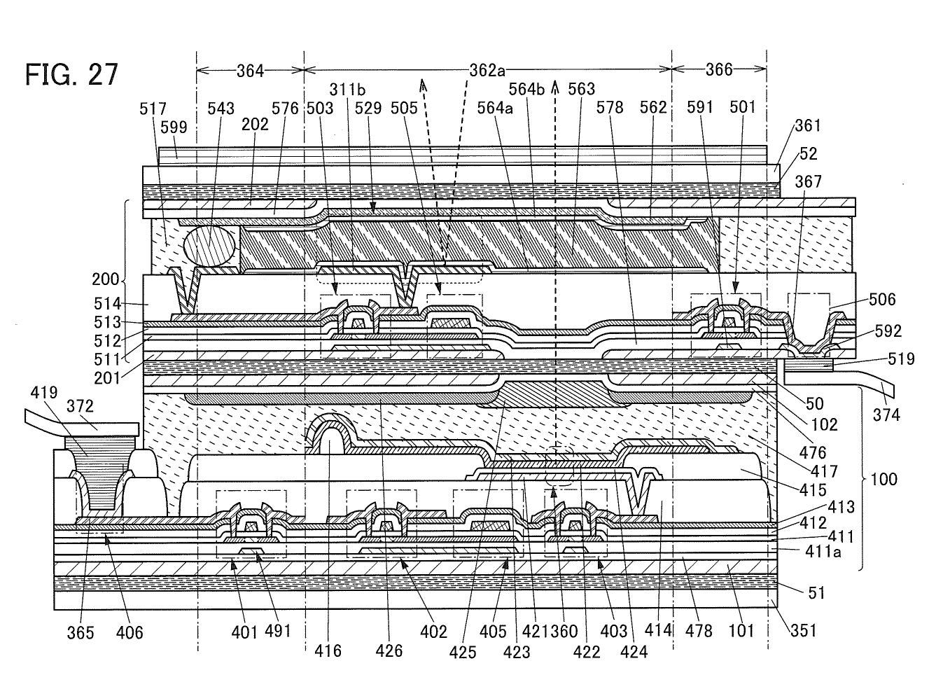

FIG. 27 illustrates an example in which a top-gate transistor including a second gate electrode is used as each transistor.

Each of the transistors includes a conductive layer 491 or a conductive layer 591 over and in contact with the resin layer 478 or the resin layer 201. The insulating layer 578 is provided to cover the conductive layer 591. Furthermore, the insulating layer 411a is provided to cover the conductive layer 491.

In the connection portion 506 of the display panel 200, part of the resin layer 201 is opened, and a conductive layer 592 is provided so as to fill the opening. The conductive layer 592 is provided such that the back surface (a surface on the display panel 100 side) thereof is exposed. The conductive layer 592 is electrically connected to the wiring 367. The FPC 374 is electrically connected to the exposed surface of the conductive layer 592 through the connection layer 519. The conductive layer 592 can be formed by processing the conductive film with which the conductive layer 591 is formed. The conductive layer 592 functions as an electrode that can also be called a back electrode.

Such a structure can be obtained by using a photosensitive organic resin for the resin layer 201. For example, in forming the resin layer 201 over a support substrate, an opening is formed in the resin layer 201 and the conductive layer 592 is formed so as to fill the opening. When the resin layer 201 and the support substrate are separated from each other, the conductive layer 592 and the support substrate are also separated from each other, whereby the conductive layer 592 illustrated in FIG. 27 can be formed.

Such a structure allows the FPC 374 connected to the display panel 200 located on the display surface side to be positioned on the side opposite to the display surface. Thus, a space for bending the FPC 374 in incorporating a display device in an electronic device can be eliminated, which enables the electronic device to be smaller.

The above is the description of the modification example.

At least part of this embodiment can be implemented in combination with any of the other embodiments described in this specification as appropriate.

### Embodiment 5

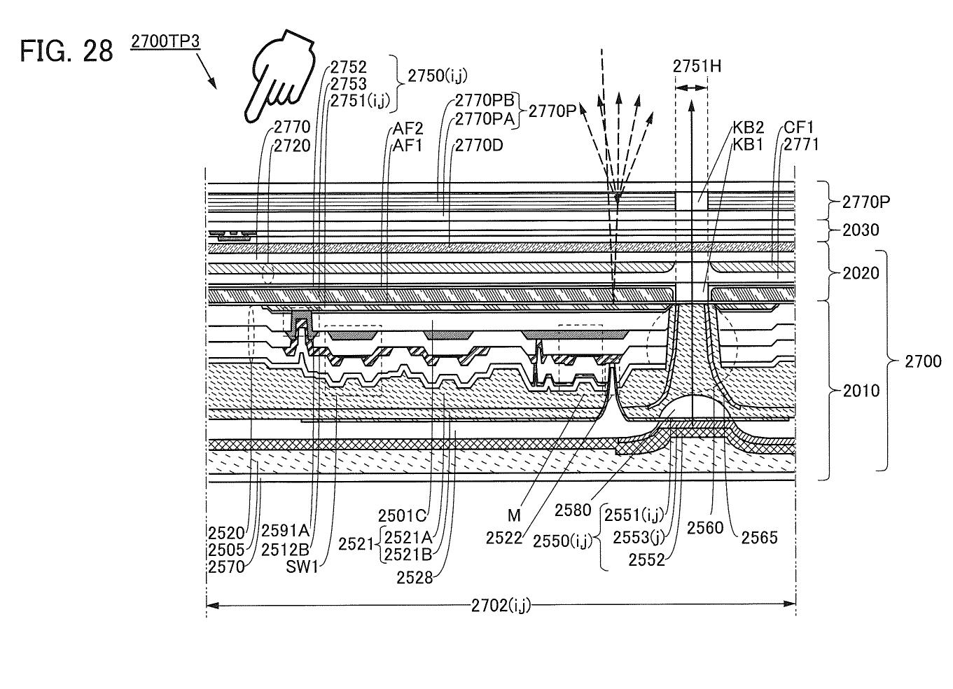

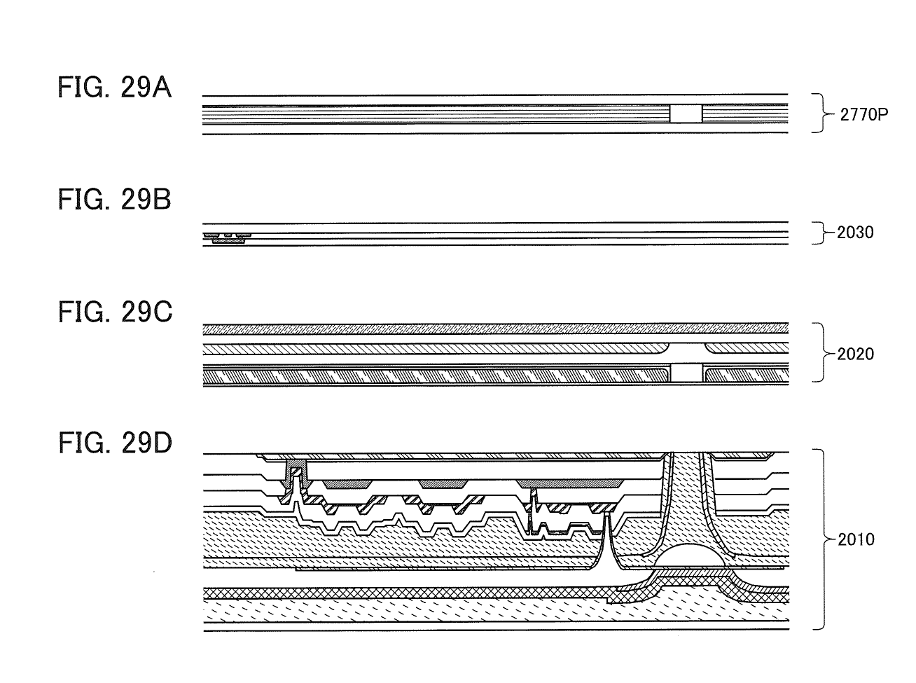

A display panel having a structure different from that in Embodiment 2 is described. In a display panel 2700 illustrated in FIG. 28, a first pixel circuit and a second pixel circuit are formed using transistors over the same insulating layer. An input/output panel 2700TP3 in which a touch sensor is provided on the display surface of the display panel 2700 is described with reference to FIG. 28 and FIGS. 29A to 29D.

FIG. 28 is a cross-sectional view of a pixel included in the input/output panel 2700TP3.

Note that in this specification, an integral variable of 1 or more may be used for reference numerals. For another example, “(i,j)” where i and j are each an integral variable of 1 or more may be used for part of a reference numeral that specifies any one of components (i×j components at a maximum).

FIGS. 29A to 29D illustrate the structure of the input/output panel of one embodiment of the present invention. FIG. 29A is a cross-sectional view illustrating a structure of a functional film of the input/output panel illustrated in FIG. 28, FIG. 29B is a cross-sectional view illustrating a structure of an input unit, FIG. 29C is a cross-sectional view illustrating a structure of a second unit, and FIG. 29D is a cross-sectional view illustrating a structure of a first unit.

An input/output panel 2700TP3 illustrated in this structure example includes a pixel 2702(i,j) (see FIG. 28). The input/output panel 2700TP3 includes a first unit 2010, a second unit 2020, an input unit 2030, and a functional film 2770P (see FIGS. 29A to 29D). The first unit 2010 includes a functional layer 2520, and the second unit 2020 includes a functional layer 2720.

<<Pixel 2702(i,j)>>

The pixel 2702(i,j) includes a portion of the functional layer 2520, a first display element 2750(i,j), and a second display element 2550(i,j) (see FIG. 28).

The functional layer 2520 includes a first conductive film, a second conductive film, an insulating film 2501C, and a pixel circuit. The pixel circuit includes the transistor M, for example. The functional layer 2520 may include an optical element 2560, a covering film 2565, and a lens 2580. The functional layer 2520 may include an insulating film 2528 and an insulating film 2521. A stack including an insulating film 2521A and an insulating film 2521B can be used as the insulating film 2521.

For example, a material whose refractive index is around 1.55 can be used for the insulating film 2521A or the insulating film 2521B. Alternatively, a material whose refractive index is around 1.6 can be used for the insulating film 2521A or the insulating film 2521B. Further alternatively, an acrylic resin or polyimide can be used for the insulating film 2521A or the insulating film 2521B.

The insulating film 2501C includes a region positioned between the first conductive film and the second conductive film and has an opening 2591A.

The first conductive film is electrically connected to the first display element 2750(i,j). Specifically, the first conductive film is electrically connected to an electrode 2751(i,j) of the first display element 2750(i,j). The electrode 2751(i,j) can be used as the first conductive film.

The second conductive film includes a region overlapping with the first conductive film. The second conductive film is electrically connected to the first conductive film through the opening 2591A. For example, a conductive film 2512B can be used as the second conductive film. The second conductive film is electrically connected to the pixel circuit. For example, a conductive film that functions as a source electrode or a drain electrode of a transistor used as the switch SW1 of the pixel circuit can be used as the second conductive film. Note that the first conductive film electrically connected to the second conductive film in the opening 2591A that is formed in the insulating film 2501C can be referred to as a through electrode.

The second display element 2550(i,j) is electrically connected to the pixel circuit. The second display element 2550(i,j) has a function of emitting light toward the functional layer 2520. The second display element 2550(i,j) has a function of emitting light toward the lens 2580 or the optical element 2560, for example.

The second display element 2550(i,j) is provided so that the display using the second display element 2550(i,j) can be seen from part of a region from which the display using the first display element 2750(i,j) can be seen. For example, the electrode 2751(i,j) of the first display element 2750(i,j) includes a region 2751H where light emitted from the second display element 2550(i,j) is not blocked. Note that dashed arrows shown in FIG. 28 denote the directions in which external light is incident on and reflected by the first display element 2750(i,j) that displays image data by controlling the intensity of external light reflection. In addition, a solid arrow shown in FIG. 28 denotes the direction in which the second display element 2550(i,j) emits light to the part of the region from which the display using the first display element 2750(i,j) can be seen.

Accordingly, display using the second display element can be seen from part of the region from which display using the first display element can be seen. Alternatively, a user can see display without changing the attitude or the like of the input/output panel. Alternatively, an object color expressed by light reflected by the first display element and a light source color expressed by light emitted from the second display element can be mixed. Alternatively, an object color and a light source color can be used to display an image like a painting. As a result, a novel input/output panel that is highly convenient or reliable can be provided.

For example, the first display element 2750(i,j) includes the electrode 2751(i,j), an electrode 2752, and a layer 2753 containing a liquid crystal material. The first display element 2750(i,j) further includes an alignment film AF1 and an alignment film AF2. Specifically, a reflective liquid crystal element can be used as the first display element 2750(i,j).

For example, a transparent conductive film whose refractive index is around 2.0 can be used as the electrode 2752 or the electrode 2751(i,j). Specifically, an oxide including indium, tin, and silicon can be used for the electrode 2752 or the electrode 2751(i,j). Alternatively, a material whose refractive index is around 1.6 can be used for the alignment film.

For example, the second display element 2550(i,j) includes an electrode 2551(i,j), an electrode 2552, and a layer 2553(j) containing a light-emitting material. The electrode 2552 includes a region overlapping with the electrode 2551(i,j). The layer 2553(j) containing a light-emitting material includes a region positioned between the electrode 2551(i,j) and the electrode 2552. The electrode 2551(i,j) is electrically connected to the pixel circuit at a connection portion 2522. Specifically, an organic EL element can be used as the second display element 2550(i,j).

For example, a transparent conductive film having a refractive index of around 2.0 can be used as the electrode 2551(i,j). Specifically, an oxide including indium, tin, and silicon can be used for the electrode 2551(i,j). Alternatively, a material whose refractive index is around 1.8 can be used for the layer 2553(j) containing a light-emitting material.

The optical element 2560 has a light-transmitting property and includes a first region, a second region, and a third region.

The first region includes a region to which visible light is supplied from the second display element 2550(i,j), the second region includes a region in contact with the covering film 2565, and the third region has a function of emitting part of visible light. The third region has an area smaller than or equal to the area of the region of the first region to which visible light is supplied.

The covering film 2565 has reflectivity with respect to visible light and has a function of reflecting part of visible light and supplying it to the third region.

For example, a metal can be used for the covering film 2565. Specifically, a material containing silver can be used for the covering film 2565. For example, a material containing silver, palladium, and the like or a material containing silver, copper, and the like can be used for the covering film 2565.

### <<Lens 2580>>

A material that transmits visible light can be used for the lens 2580. Alternatively, a material whose refractive index is greater than or equal to 1.3 and less than or equal to 2.5 can be used for the lens 2580. For example, an inorganic material or an organic material can be used for the lens 2580.

For example, a material including an oxide or a sulfide can be used for the lens 2580.

Specifically, cerium oxide, hafnium oxide, lanthanum oxide, magnesium oxide, niobium oxide, tantalum oxide, titanium oxide, yttrium oxide, zinc oxide, an oxide including indium and tin, an oxide including indium, gallium, and zinc, or the like can be used for the lens 2580. Alternatively, zinc sulfide or the like can be used for the lens 2580.

For example, the lens 2580 can be formed using a material including resin. Specifically, the lens 2580 can be formed using a resin to which chlorine, bromine, or iodine is introduced, a resin to which a heavy metal atom is introduced, a resin to which an aromatic ring is introduced, a resin to which sulfur is introduced, or the like. Alternatively, the lens 2580 can be formed using a material containing a resin and nanoparticles of a material whose refractive index is higher than that of the resin. Titanium oxide, zirconium oxide, or the like can be used for the nanoparticle.

### <<Functional Layer 2720>>

The functional layer 2720 includes a region positioned between a substrate 2770 and the insulating film 2501C. The functional layer 2720 further includes an insulating film 2771 and a coloring film CF1.

The coloring film CF1 includes a region positioned between the substrate 2770 and the first display element 2750(i,j).

The insulating film 2771 includes a region positioned between the coloring film CF1 and the layer 2753 containing a liquid crystal material. The insulating film 2771 can reduce unevenness due to the thickness of the coloring film CF1. Furthermore, the insulating film 2771 can prevent impurities from diffusing from the coloring film CF1 or the like to the layer 2753 containing a liquid crystal material.

For example, an acrylic resin whose refractive index is around 1.55 can be used for the insulating film 2771.

### <<Substrate 2570 and Substrate 2770>>

The input/output panel described in this embodiment includes a substrate 2570 and the substrate 2770.

The substrate 2770 includes a region overlapping with the substrate 2570. The substrate 2770 includes a region provided so that the functional layer 2520 is positioned between the substrate 2770 and the substrate 2570.

The substrate 2770 includes a region overlapping with the first display element 2750(i,j). For example, a material with low birefringence can be used for the region.

For example, a resin material whose refractive index is around 1.5 can be used for the substrate 2770.

### <<Bonding Layer 2505>>

The input/output panel described in this embodiment also includes a bonding layer 2505.

The bonding layer 2505 includes a region positioned between the functional layer 2520 and the substrate 2570, and has a function of bonding the functional layer 2520 and the substrate 2570 together.

### <<Structure Body KB1 and Structure Body KB2>>

The input/output panel described in this embodiment includes a structure body KB1 and a structure body KB2.

The structure body KB1 has a function of providing a certain space between the functional layer 2520 and the substrate 2770. The structure body KB1 includes a region overlapping with the region 2751H and has a light-transmitting property. Thus, light emitted from the second display element 2550(i,j) can be supplied to one surface of the structure body KB1 and emitted from the other surface.

Furthermore, the structure body KB1 includes a region overlapping with the optical element 2560 and is formed using a material whose refractive index is different from that of a material used for the optical element 2560 by 0.2 or less, for example. Thus, light emitted from the second display element can be efficiently utilized. The area of the second display element can be increased. The density of current flowing through the organic EL element can be decreased.

The structure body KB2 has a function of controlling the thickness of a polarizing layer 2770PB to a predetermined thickness. The structure body KB2 includes a region overlapping with the second display element 2550(i,j) and has a light-transmitting property.

Alternatively, a material that transmits light of a predetermined color can be used for the structure body KB1 or KB2. Thus, the structure body KB1 or KB2 can be used, for example, as a color filter. For example, a material that transmits blue light, green light, or red light can be used for the structure body KB1 or KB2. A material that transmits yellow light, white like, or the like can be used for the structure body KB1 or KB2.

Specifically, for the structure body KB1 or KB2, polyester, polyolefin, polyamide, polyimide, polycarbonate, polysiloxane, an acrylic resin, or the like, or a composite material of a plurality of resins selected from these can be used. Alternatively, a photosensitive material may be used.

For example, an acrylic resin whose refractive index is around 1.5 can be used for the structure body KB1. An acrylic resin whose refractive index is around 1.55 can be used for the structure body KB2.

### <<Input Unit 2030>>

The input unit 2030 includes a sensor element. The sensor element has a function of sensing an object that approaches a region overlapping with the pixel 2702(i,j). Thus, a finger or the like is used as a pointer to input positional data by approaching the display portion.

For example, a capacitive proximity sensor, an electromagnetic inductive proximity sensor, an optical proximity sensor, a resistive proximity sensor, or a surface acoustic wave proximity sensor can be used as the input unit 2030. Specifically, a surface capacitive proximity sensor, a projection capacitive proximity sensor, an infrared light detection type proximity sensor, or the like can be used.

For example, a touch sensor that includes a capacitive proximity sensor and whose refractive index is around 1.6 can be used as the input unit 2030.

### <<Functional Film 2770D, Functional Film 2770P, and the Like>>

The input/output panel 2700TP3 described in this embodiment includes a functional film 2770D and the functional film 2770P.

The functional film 2770D includes a region overlapping with the first display element 2750(i,j). The functional film 2770D includes a region provided so that the first display element 2750(i,j) is positioned between the functional film 2770D and the functional layer 2520.

For example, a light diffusion film can be used as the functional film 2770D. Specifically, a material with a columnar structure having an axis along the direction intersecting a surface of a base can be used for the functional film 2770D. In that case, light can be easily transmitted in the direction along the axis and scattered in other directions. For example, light reflected by the first display element 2750(i,j) can be diffused.

The functional film 2770P includes the polarizing layer 2770PB, a retardation film 2770PA, and the structure body KB2. The polarizing layer 2770PB includes an opening, and the retardation film 2770PA includes a region overlapping with the polarizing layer 2770PB. Note that the structure body KB2 is provided in the opening.

For example, a dichromatic pigment, a liquid crystal material, and a resin can be used for the polarizing layer 2770PB. The polarizing layer 2770PB has a polarization property. In that case, the functional film 2770P can be used as a polarizing plate.

The polarizing layer 2770PB includes a region overlapping with the first display element 2750(i,j), and the structure body KB2 includes a region overlapping with the second display element 2550(i,j). Thus, a liquid crystal element can be used as the first display element. For example, a reflective liquid crystal element can be used as the first display element. Light emitted from the second display element can be extracted efficiently. The density of current flowing through the organic EL element can be decreased. The reliability of the organic EL element can be increased.

For example, an anti-reflection film, a polarizing film, or a retardation film can be used as the functional film 2770P. Specifically, a film including a dichromatic pigment and a retardation film can be used as the functional film 2770P.

Alternatively, an antistatic film preventing the attachment of a foreign substance, a water repellent film suppressing the attachment of stain, a hard coat film suppressing a scratch in use, or the like can be used as the functional film 2770P.

For example, a material whose refractive index is around 1.6 can be used for the diffusion film. A material whose refractive index is around 1.6 can be used for the retardation film 2770PA.

Note that this embodiment can be combined with any of the other embodiments in this specification as appropriate.

### Embodiment 6

### [Transistor]

The transistor includes a conductive layer serving as a gate electrode, a semiconductor layer, a conductive layer serving as a source electrode, a conductive layer serving as a drain electrode, and an insulating layer serving as a gate insulating layer.

In FIG. 16, a bottom-gate transistor is used.

Note that there is no particular limitation on the structure of the transistor included in the display device of one embodiment of the present invention. For example, a planar transistor, a staggered transistor, or an inverted staggered transistor may be used. A top-gate transistor or a bottom-gate transistor may be used. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single-crystal semiconductor, or a semiconductor partly including crystal regions) may be used. It is preferable that a semiconductor having crystallinity be used, in which case deterioration of the transistor characteristics can be suppressed.

As a semiconductor material used for the transistors, a metal oxide whose energy gap is greater than or equal to 2 eV, preferably greater than or equal to 2.5 eV, further preferably greater than or equal to 3 eV can be used. A typical example thereof is a metal oxide containing indium, and for example, a CAC-OS described later or the like can be used.

A transistor with a metal oxide having a larger band gap and a lower carrier density than silicon has a low off-state current; therefore, charges stored in a capacitor that is series-connected to the transistor can be held for a long time.

The semiconductor layer can be, for example, a film represented by an In-M-Zn-based oxide that contains at least indium, zinc, and M (a metal such as aluminum, titanium, gallium, germanium, yttrium, zirconium, lanthanum, cerium, tin, neodymium, or hafnium).

In the case where the metal oxide contained in the semiconductor layer contains an In-M-Zn-based oxide, it is preferable that the atomic ratio of metal elements of a sputtering target used for forming a film of the In-M-Zn oxide satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:6, In:M:Zn=5:1:7, or In:M:Zn=5:1:8. Note that the atomic ratio of metal elements in the formed semiconductor layer varies from the above atomic ratios of metal elements of the sputtering targets in a range of ±40%.

The bottom-gate transistor described in this embodiment is preferable because the number of manufacturing steps can be reduced. When a metal oxide, which can be formed at a lower temperature than polycrystalline silicon, is used, materials with low heat resistance can be used for a wiring, an electrode, or a substrate below the semiconductor layer, so that the range of choices of materials can be widened. For example, an extremely large glass substrate can be favorably used.

A metal oxide film with low carrier density is used as the semiconductor layer. For example, the semiconductor layer is a metal oxide whose carrier density is lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, even further preferably lower than 1×10¹⁰/cm³, and higher than or equal to 1×10⁻⁹/cm³. Such a metal oxide is referred to as a highly purified intrinsic or substantially highly purified intrinsic metal oxide. The metal oxide has a low impurity concentration and a low density of defect states and can thus be referred to as a metal oxide having stable characteristics.

Note that, without limitation to those described above, a material with an appropriate composition may be used depending on required semiconductor characteristics and electrical characteristics (e.g., field-effect mobility and threshold voltage) of a transistor. To obtain the required semiconductor characteristics of the transistor, it is preferable that the carrier density, the impurity concentration, the defect density, the atomic ratio between a metal element and oxygen, the interatomic distance, the density, and the like of the semiconductor layer be set to appropriate values.

When silicon or carbon that is one of elements belonging to Group 14 is contained in the metal oxide contained in the semiconductor layer, oxygen vacancies are increased in the semiconductor layer, and the semiconductor layer becomes n-type. Thus, the concentration of silicon or carbon (measured by secondary ion mass spectrometry) in the semiconductor layer is lower than or equal to 2×10¹⁸ atoms/cm³, preferably lower than or equal to 2×10¹⁷ atoms/cm³.

Alkali metal and alkaline earth metal might generate carriers when bonded to a metal oxide, in which case the off-state current of the transistor might be increased. Therefore, the concentration of alkali metal or alkaline earth metal of the semiconductor layer, which is measured by secondary ion mass spectrometry, is lower than or equal to 1×10¹⁸ atoms/cm³, preferably lower than or equal to 2×10¹⁶ atoms/cm³.

When nitrogen is contained in the metal oxide contained in the semiconductor layer, electrons serving as carriers are generated and the carrier density increases, so that the semiconductor layer easily becomes n-type. Thus, a transistor including a metal oxide that contains nitrogen is likely to be normally on. Hence, the concentration of nitrogen that is measured by secondary ion mass spectrometry is preferably set to lower than or equal to 5×10¹⁸ atoms/cm³.

The semiconductor layer may have a non-single-crystal structure, for example. The non-single-crystal structure includes CAAC-OS (c-axis aligned crystalline oxide semiconductor, or c-axis aligned a-b-plane-anchored crystalline oxide semiconductor) including a c-axis aligned crystal, a polycrystalline structure, a microcrystalline structure, or an amorphous structure, for example. Among the non-single-crystal structures, an amorphous structure has the highest density of defect states, whereas CAAC-OS has the lowest density of defect states.

A metal oxide film having an amorphous structure has disordered atomic arrangement and no crystalline component, for example. Alternatively, an oxide film having an amorphous structure has, for example, an absolutely amorphous structure and no crystal part.

Note that the semiconductor layer may be a mixed film including two or more of the following: a region having an amorphous structure, a region having a microcrystalline structure, a region having a polycrystalline structure, a region of CAAC-OS, and a region having a single-crystal structure. The mixed film has, for example, a single-layer structure or a stacked-layer structure including two or more of the above-described regions in some cases.

### <Composition of CAC-OS>

Described below is the composition of a cloud-aligned composite oxide semiconductor (CAC-OS) applicable to a transistor disclosed in one embodiment of the present invention.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, a metal oxide used in an active layer of a transistor is called an oxide semiconductor in some cases. In other words, an OS FET is a transistor including a metal oxide or an oxide semiconductor.

In this specification, a metal oxide in which regions functioning as a conductor and regions functioning as a dielectric are mixed and which functions as a semiconductor as a whole is defined as a CAC-OS or a CAC-metal oxide.

The CAC-OS has, for example, a composition in which elements included in an oxide semiconductor are unevenly distributed. Materials including unevenly distributed elements each have a size of greater than or equal to 0.5 nm and less than or equal to 10 nm, preferably greater than or equal to 0.5 nm and less than or equal to 3 nm, or a similar size. Note that in the following description of an oxide semiconductor, a state in which one or more elements are unevenly distributed and regions including the element(s) are mixed is referred to as a mosaic pattern or a patch-like pattern. The region has a size of greater than or equal to 0.5 nm and less than or equal to 10 nm, preferably greater than or equal to 0.5 nm and less than or equal to 3 nm, or a similar size.

The physical properties of a region including an unevenly distributed element are determined by the properties of the element. For example, a region including an unevenly distributed element that relatively tends to serve as an insulator among elements included in a metal oxide serves as a dielectric region. In contrast, a region including an unevenly distributed element that relatively tends to serve as a conductor among elements included in a metal oxide serves as a conductive region. A material in which conductive regions and dielectric regions are mixed to form a mosaic pattern serves as a semiconductor.

That is, a metal oxide in one embodiment of the present invention is a kind of matrix composite or metal matrix composite, in which materials having different physical properties are mixed.

Note that an oxide semiconductor preferably contains at least indium. In particular, indium and zinc are preferably contained. In addition, an element M (M is one or more of gallium, aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be contained.

For example, of the CAC-OS, an In—Ga—Zn oxide with the CAC composition (such an In—Ga—Zn oxide may be particularly referred to as CAC-IGZO) has a composition in which materials are separated into indium oxide (InO_{X1}, where X1 is a real number greater than 0) or indium zinc oxide (In_{X2}Zn_{Y2}O_{Z2}, where X2, Y2, and Z2 are real numbers greater than 0), and gallium oxide (GaO_{X3}, where X3 is a real number greater than 0) or gallium zinc oxide (Ga_{X4}Zn_{Y4}O_{Z4}, where X4, Y4, and Z4 are real numbers greater than 0), and a mosaic pattern is formed. Then, InO_{X1} or In_{X2}Zn_{Y2}O_{Z2} forming the mosaic pattern is evenly distributed in the film. This composition is also referred to as a cloud-like composition.

That is, the CAC-OS is a composite oxide semiconductor with a composition in which a region including GaO_{X3} as a main component and a region including In_{X2}Zn_{Y2}O_{Z2} or InO_{X1} as a main component are mixed. Note that in this specification, for example, when the atomic ratio of In to an element M in a first region is greater than the atomic ratio of In to an element M in a second region, the first region has higher In concentration than the second region.

Note that a compound including In, Ga, Zn, and O is also known as IGZO. Typical examples of IGZO include a crystalline compound represented by InGaO₃(ZnO)ₘ₁ (m1 is a natural number) and a crystalline compound represented by In₍₁₊ₓ₀₎Ga₍₁₋ₓ₀₎O₃(ZnO)ₘ₀ (−1≤x0≤1; m0 is a given number).

The above crystalline compounds have a single crystal structure, a polycrystalline structure, or a CAAC structure. Note that the CAAC structure is a crystal structure in which a plurality of IGZO nanocrystals have c-axis aligmnent and are connected in the a-b plane direction without alignment.

On the other hand, the CAC-OS relates to the material composition of an oxide semiconductor. In a material composition of a CAC-OS including In, Ga, Zn, and O, nanoparticle regions including Ga as a main component are observed in part of the CAC-OS and nanoparticle regions including In as a main component are observed in part thereof. These nanoparticle regions are randomly dispersed to form a mosaic pattern. Therefore, the crystal structure is a secondary element for the CAC-OS.

Note that in the CAC-OS, a stacked-layer structure including two or more films with different atomic ratios is not included. For example, a two-layer structure of a film including In as a main component and a film including Ga as a main component is not included.

A boundary between the region including GaO_{X3} as a main component and the region including In_{X2}Zn_{Y2}O_{Z2} or InO_{X1} as a main component is not clearly observed in some cases.

In the case where one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like are contained instead of gallium in a CAC-OS, nanoparticle regions including the selected element(s) as a main component(s) are observed in part of the CAC-OS and nanoparticle regions including In as a main component are observed in part thereof, and these nanoparticle regions are randomly dispersed to form a mosaic pattern in the CAC-OS.

### <Analysis of CAC-OS>

Next, measurement results of an oxide semiconductor over a substrate by a variety of methods are described.

### <<Structure of Samples and Formation Method Thereof>>

Nine samples of one embodiment of the present invention are described below. The samples are formed at different substrate temperatures and with different ratios of an oxygen gas flow rate in formation of the oxide semiconductor. Note that each sample includes a substrate and an oxide semiconductor over the substrate.

A method for forming the samples is described.

A glass substrate is used as the substrate. Over the glass substrate, a 100-nm-thick In—Ga—Zn oxide is formed as an oxide semiconductor with a sputtering apparatus. The formation conditions are as follows: the pressure in a chamber is 0.6 Pa, and an oxide target (with an atomic ratio of In:Ga:Zn=4:2:4.1) is used as a target. The oxide target provided in the sputtering apparatus is supplied with an AC power of 2500 W.

As for the conditions in the formation of the oxide of the nine samples, the substrate temperature is set to a temperature that is not increased by intentional heating (hereinafter such a temperature is also referred to as room temperature or R.T.), to 130° C., and to 170° C. The ratio of a flow rate of an oxygen gas to a flow rate of a mixed gas of Ar and oxygen (also referred to as an oxygen gas flow rate ratio) is set to 10%, 30%, and 100%.

### <<Analysis by X-Ray Diffraction>>

In this section, results of X-ray diffraction (XRD) measurement performed on the nine samples are described. As an XRD apparatus, D8 ADVANCE manufactured by Bruker AXS is used. The conditions are as follows: scanning is performed by an out-of-plane method at θ/2θ, the scanning range is 15 deg. to 50 deg., the step width is 0.02 deg., and the scanning speed is 3.0 deg./min.

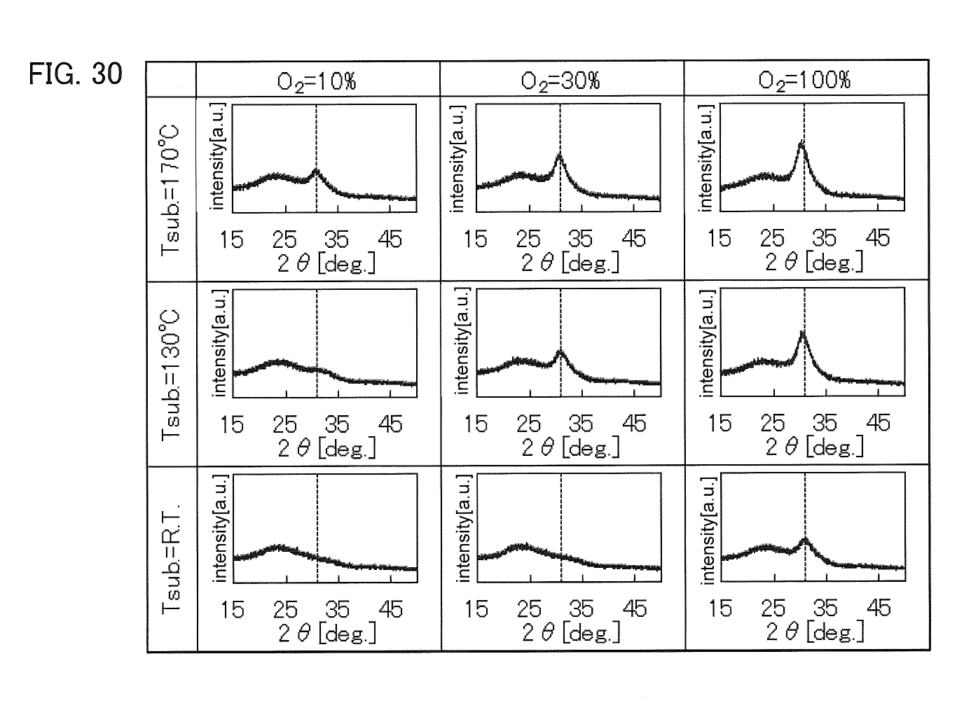

FIG. 30 shows XRD spectra measured by an out-of-plane method. In FIG. 30, the top row shows the measurement results of the samples formed at a substrate temperature of 170° C.; the middle row shows the measurement results of the samples formed at a substrate temperature of 130° C.; and the bottom row shows the measurement results of the samples formed at a substrate temperature of R.T. The left column shows the measurement results of the samples formed with an oxygen gas flow rate ratio of 10%; the middle column shows the measurement results of the samples formed with an oxygen gas flow rate ratio of 30%; and the right column shows the measurement results of the samples formed with an oxygen gas flow rate ratio of 100%.

In the XRD spectra shown in FIG. 30, the higher the substrate temperature at the time of formation is or the higher the oxygen gas flow rate ratio at the time of formation is, the higher the intensity of the peak at around 2θ=31° is. Note that it is found that the peak at around 2θ=31° is derived from a crystalline IGZO compound whose c-axes are aligned in a direction substantially perpendicular to a formation surface or a top surface of the crystalline IGZO compound (such a compound is also referred to as c-axis aligned crystalline (CAAC) IGZO).

As shown in the XRD spectra in FIG. 30, as the substrate temperature at the time of formation is lower or the oxygen gas flow rate ratio at the time of formation is lower, a peak becomes less clear. Accordingly, it is found that there are no alignment in the a-b plane direction and c-axis alignment in the measured areas of the samples that are formed at a lower substrate temperature or with a lower oxygen gas flow rate ratio.

<<Analysis with Electron Microscope>>

This section describes the observation and analysis results of the samples formed at a substrate temperature of R.T. and with an oxygen gas flow rate ratio of 10% with a high-angle annular dark-field scanning transmission electron microscope (HAADF-STEM). An image obtained with an HAADF-STEM is also referred to as a TEM image.

Described are the results of image analysis of plan-view images and cross-sectional images obtained with an HAADF-STEM (also referred to as plan-view TEM images and cross-sectional TEM images, respectively). The TEM images are observed with a spherical aberration corrector function. The HAADF-STEM images are obtained using an atomic resolution analytical electron microscope JEM-ARM200F manufactured by JEOL Ltd. under the following conditions: the acceleration voltage is 200 kV, and irradiation with an electron beam with a diameter of approximately 0.1 nm is performed.

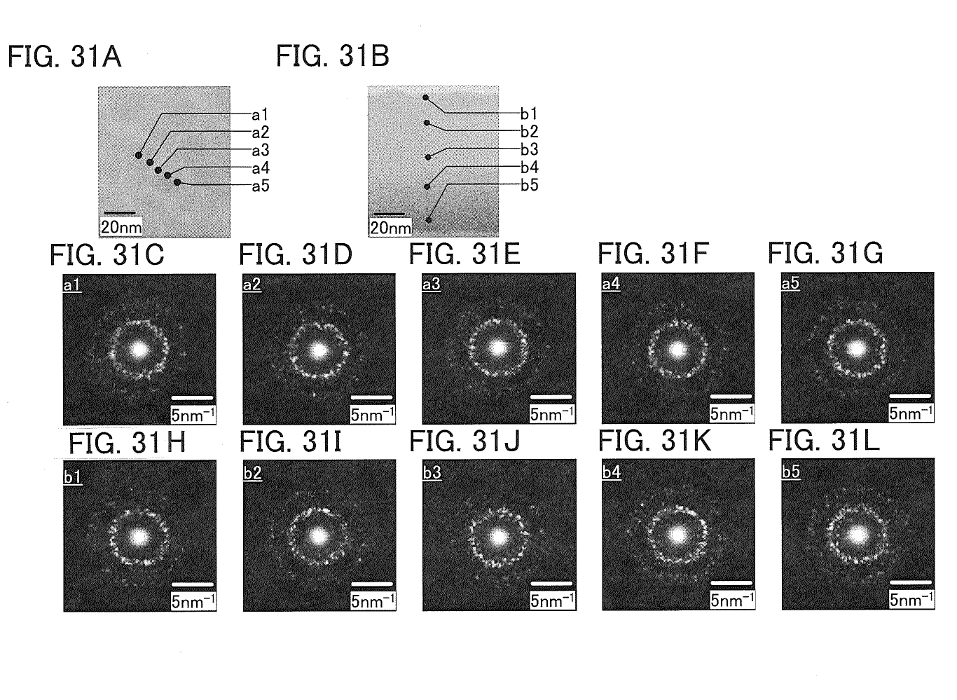

FIG. 31A is a plan-view TEM image of the sample formed at a substrate temperature of R.T. and with an oxygen gas flow rate ratio of 10%. FIG. 31B is a cross-sectional TEM image of the sample formed at a substrate temperature of R.T. and with an oxygen gas flow rate ratio of 10%.

### <<Analysis of Electron Diffraction Patterns>>

This section describes electron diffraction patterns obtained by irradiation of the sample formed at a substrate temperature of R.T. and an oxygen gas flow rate ratio of 10% with an electron beam with a probe diameter of 1 nm (also referred to as a nanobeam).

Electron diffraction patterns of points indicated by black dots a1, a2, a3, a4, and a5 in the plan-view TEM image in FIG. 31A of the sample formed at a substrate temperature of R.T. and an oxygen gas flow rate ratio of 10% are observed. Note that the electron diffraction patterns are observed while electron beam irradiation is performed at a constant rate for 35 seconds. FIGS. 31C, 31D, 31E, 31F, and 31G show the results of the points indicated by the black dots a1, a2, a3, a4, and a5, respectively.

In FIGS. 31C, 31D, 31E, 31F, and 31G, regions with high luminance in a circular (ring) pattern can be shown. Furthermore, a plurality of spots can be shown in a ring-like shape.

Electron diffraction patterns of points indicated by black dots b1, b2, b3, b4, and b5 in the cross-sectional TEM image in FIG. 31B of the sample formed at a substrate temperature of R.T. and an oxygen gas flow rate ratio of 10% are observed. FIGS. 31H, 31I, 31J, 31K, and 31L show the results of the points indicated by the black dots b1, b2, b3, b4, and b5, respectively.

In FIGS. 31H, 31I, 31J, 31K, and 31L, regions with high luminance in a ring pattern can be shown. Furthermore, a plurality of spots can be shown in a ring-like shape.

For example, when an electron beam with a probe diameter of 300 nm is incident on a CAAC-OS including an InGaZnO₄ crystal in a direction parallel to the sample surface, a diffraction pattern including a spot derived from the (009) plane of the InGaZnO₄ crystal is obtained. That is, the CAAC-OS has c-axis alignment and the c-axes are aligned in the direction substantially perpendicular to the formation surface or the top surface of the CAAC-OS. Meanwhile, a ring-like diffraction pattern is shown when an electron beam with a probe diameter of 300 nm is incident on the same sample in a direction perpendicular to the sample surface. That is, it is found that the CAAC-OS has neither a-axis alignment nor b-axis alignment.

Furthermore, a diffraction pattern like a halo pattern is observed when an oxide semiconductor including a nanocrystal (a nanocrystalline oxide semiconductor (nc-OS)) is subjected to electron diffraction using an electron beam with a large probe diameter (e.g., 50 nm or larger). Meanwhile, bright spots are shown in a nanobeam electron diffraction pattern of the nc-OS obtained using an electron beam with a small probe diameter (e.g., smaller than 50 nm). Furthermore, in a nanobeam electron diffraction pattern of the nc-OS, regions with high luminance in a circular (ring) pattern are shown in some cases. Also in a nanobeam electron diffraction pattern of the nc-OS, a plurality of bright spots are shown in a ring-like shape in some cases.

The electron diffraction pattern of the sample formed at a substrate temperature of R.T. and with an oxygen gas flow rate ratio of 10% has regions with high luminance in a ring pattern and a plurality of bright spots appear in the ring-like pattern. Accordingly, the sample formed at a substrate temperature of R.T. and with an oxygen gas flow rate ratio of 10% exhibits an electron diffraction pattern similar to that of the nc-OS and does not show alignment in the plane direction and the cross-sectional direction.

According to what is described above, an oxide semiconductor formed at a low substrate temperature or with a low oxygen gas flow rate ratio is likely to have characteristics distinctly different from those of an oxide semiconductor film having an amorphous structure and an oxide semiconductor film having a single crystal structure.

### <<Elementary Analysis>>

This section describes the analysis results of elements included in the sample formed at a substrate temperature of R.T. and with an oxygen gas flow rate ratio of 10%. For the analysis, by energy dispersive X-ray spectroscopy (EDX), EDX mapping images are obtained. An energy dispersive X-ray spectrometer AnalysisStation JED-2300T manufactured by JEOL Ltd. is used as an elementary analysis apparatus in the EDX measurement. A Si drift detector is used to detect an X-ray emitted from the sample.

In the EDX measurement, an EDX spectrum of a point is obtained in such a manner that electron beam irradiation is performed on the point in an analysis target region of a sample, and the energy of characteristic X-ray of the sample generated by the irradiation and its frequency are measured. In this embodiment, peaks of an EDX spectrum of the point are attributed to electron transition to the L shell in an In atom, electron transition to the K shell in a Ga atom, and electron transition to the K shell in a Zn atom and the K shell in an O atom, and the proportions of the atoms in the point are calculated. An EDX mapping image indicating distributions of proportions of atoms can be obtained through the process in an analysis target region of a sample.

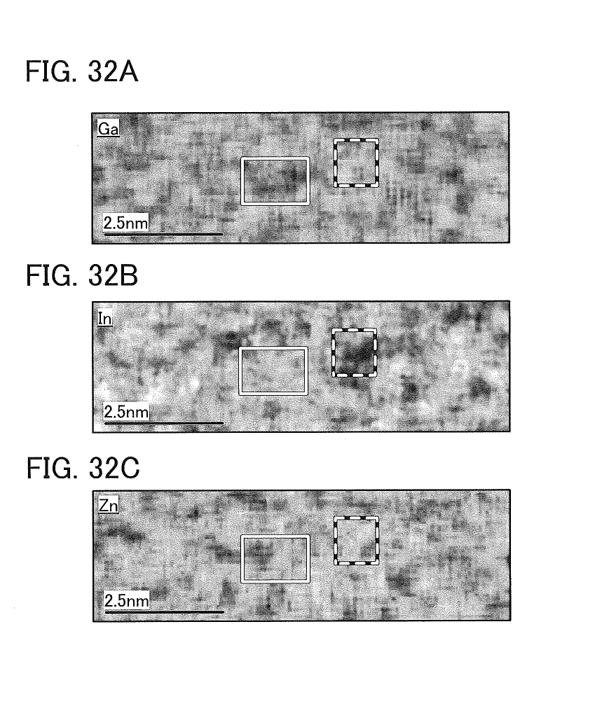

FIGS. 32A to 32C show EDX mapping images in a cross section of the sample formed at a substrate temperature of R.T. and with an oxygen gas flow rate ratio of 10%. FIG. 32A shows an EDX mapping image of Ga atoms. The proportion of the Ga atoms in all the atoms is 1.18 atomic % to 18.64 atomic %. FIG. 32B shows an EDX mapping image of In atoms. The proportion of the In atoms in all the atoms is 9.28 atomic % to 33.74 atomic %. FIG. 32C shows an EDX mapping image of Zn atoms. The proportion of the Zn atoms in all the atoms is 6.69 atomic % to 24.99 atomic %. FIGS. 32A to 32C show the same region in the cross section of the sample formed at a substrate temperature of R.T. and with an oxygen gas flow rate ratio of 10%. In the EDX mapping images, the proportion of an element is indicated by gray scale: the more measured atoms exist in a region, the brighter the region is; the less measured atoms exist in a region, the darker the region is. The magnification of the EDX mapping images in FIGS. 32A to 32C is 7200000 times.

The EDX mapping images in FIGS. 32A to 32C show relative distribution of brightness indicating that each element has a distribution in the sample formed at a substrate temperature of R.T. and with an oxygen gas flow rate ratio of 10%. Areas surrounded by solid lines and areas surrounded by dashed lines in FIGS. 32A to 32C are examined.

In FIG. 32A, a relatively dark region occupies a large area in the area surrounded by the solid line, while a relatively bright region occupies a large area in the area surrounded by the dashed line. In FIG. 32B, a relatively bright region occupies a large area in the area surrounded by the solid line, while a relatively dark region occupies a large area in the area surrounded by the dashed line.

That is, the areas surrounded by the solid lines are regions including a relatively large number of In atoms and the areas surrounded by the dashed lines are regions including a relatively small number of In atoms. In FIG. 32C, the right portion of the area surrounded by the solid line is relatively bright and the left portion thereof is relatively dark. Thus, the area surrounded by the solid line is a region including In_{X2}Zn_{Y2}O_{Z2}, InO_{X1}, or the like as a main component.

The area surrounded by the solid line is a region including a relatively small number of Ga atoms and the area surrounded by the dashed line is a region including a relatively large number of Ga atoms. In FIG. 32C, the upper left portion of the area surrounded by the dashed line is relatively bright and the lower right portion thereof is relatively dark. Thus, the area surrounded by the dashed line is a region including GaO_{X3}, Ga_{X4}Zn_{Y4}O_{Z4}, or the like as a main component.

Furthermore, as shown in FIGS. 32A to 32C, the In atoms are relatively more uniformly distributed than the Ga atoms, and regions including InO_{X1} as a main component are seemingly joined to each other through a region including In_{X2}Zn_{Y2}O_{Z2} as a main component. Thus, the regions including In_{X2}Zn_{Y2}O_{Z2} and InO_{X1} as main components extend like a cloud.

An In—Ga—Zn oxide having a composition in which the regions including GaO_{X3} or the like as a main component and the regions including In_{X2}Zn_{Y2}O_{Z2} or InO_{X1} as a main component are unevenly distributed and mixed can be referred to as a CAC-OS.

The crystal structure of the CAC-OS includes an nc structure. In an electron diffraction pattern of the CAC-OS with the nc structure, several or more bright spots appear in addition to bright spots derived from IGZO including a single crystal, a polycrystal, or a CAAC. Alternatively, the crystal structure is defined as having high luminance regions appearing in a ring pattern in addition to the several or more bright spots.

As shown in FIGS. 32A to 32C, each of the regions including GaO_{X3} or the like as a main component and the regions including In_{X2}Zn_{Y2}O_{Z2} or InO_{X1} as a main component has a size of greater than or equal to 0.5 nm and less than or equal to 10 nm, or greater than or equal to 1 nm and less than or equal to 3 nm. Note that it is preferable that a diameter of a region including each metal element as a main component be greater than or equal to 1 nm and less than or equal to 2 nm in the EDX mapping images.

As described above, the CAC-OS has a structure different from that of an IGZO compound in which metal elements are evenly distributed, and has characteristics different from those of the IGZO compound. That is, in the CAC-OS, regions including GaO_{X3} or the like as a main component and regions including In_{X2}Zn_{Y2}O_{Z2} or InO_{X1} as a main component are separated to form a mosaic pattern.

The conductivity of a region including In_{X2}Zn₂O_{Z2} or InO_{X1} as a main component is higher than that of a region including GaO_{X3} or the like as a main component. In other words, when carriers flow through regions including In_{X2}Zn_{Y2}O_{Z2} or InO_{X1} as a main component, the conductivity of an oxide semiconductor is exhibited. Accordingly, when regions including In_{X2}Zn_{Y2}O_{Z2} or InO_{X1} as a main component are distributed in an oxide semiconductor like a cloud, a high field-effect mobility (μ) can be achieved.

In contrast, the insulating property of a region including GaO_{X3} or the like as a main component is higher than that of a region including In_{X2}Zn_{Y2}O_{Z2} or InO_{X1} as a main component. In other words, when regions including GaO_{X3} or the like as a main component are distributed in an oxide semiconductor, leakage current can be suppressed and favorable switching operation can be achieved.

Accordingly, when a CAC-OS is used for a semiconductor element, the insulating property derived from GaO_{X3} or the like and the conductivity derived from In_{X2}Zn_{Y2}O_{Z2} or InO_{X1} complement each other, whereby a high on-state current (Iₒₙ) and a high field-effect mobility (μ) can be achieved.

A semiconductor element including a CAC-OS has high reliability. Thus, the CAC-OS is suitably used in a variety of semiconductor devices typified by a display.

Since a transistor including a CAC-OS in a semiconductor layer has high field-effect mobility and high driving capability, the use of the transistor in a driver circuit, a typical example of which is a gate line driver circuit that generates a gate signal, allows a display device to have a narrow bezel. Furthermore, the use of the transistor in a signal line driver circuit (particularly in a demultiplexer connected to an output terminal of a shift register included in a signal line driver circuit) that is included in a display device and supplies a signal from a signal line can reduce the number of wirings connected to the display device.

Furthermore, the transistor including a CAC-OS in the semiconductor layer does not need a laser crystallization step like a transistor including low-temperature polysilicon. Thus, the manufacturing cost of a display device can be reduced, even when the display device is formed using a large substrate. In addition, when the transistor including a CAC-OS in the semiconductor layer is used for a driver circuit and a display portion in a large display device having a high resolution such as ultra high definition (“4K resolution”, “4K2K”, and “4K”) or super high definition (“8K resolution”, “8K4K”, and “8K”), writing can be performed in a short time, and display defects can be reduced, which is preferable.

Alternatively, silicon may be used as a semiconductor in which a channel of a transistor is formed. Although amorphous silicon may be used as silicon, silicon having crystallinity is particularly preferable. For example, microcrystalline silicon, polycrystalline silicon, single crystal silicon, or the like is preferably used. In particular, polycrystalline silicon can be formed at a lower temperature than single crystal silicon and has a higher field effect mobility and higher reliability than amorphous silicon.

The bottom-gate transistor described in this embodiment is preferable because the number of manufacturing steps can be reduced. When amorphous silicon, which can be formed at a lower temperature than polycrystalline silicon, is used for the semiconductor layer, materials with low heat resistance can be used for a wiring, an electrode, or a substrate below the semiconductor layer, resulting in wider choice of materials. For example, an extremely large glass substrate can be favorably used. Meanwhile, the top-gate transistor is preferable because an impurity region is easily formed in a self-aligned manner and variation in characteristics can be reduced. The top-gate transistor is particularly preferable when polycrystalline silicon, single-crystal silicon, or the like is employed.

At least part of this embodiment can be implemented in combination with any of the other embodiments described in this specification as appropriate.

### Embodiment 7

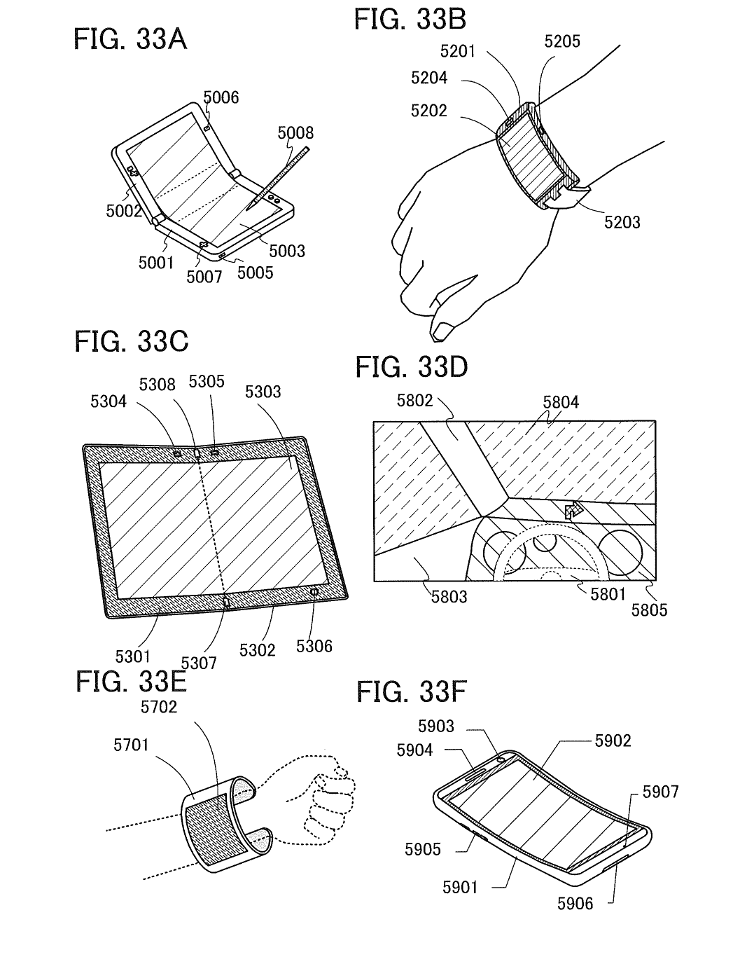

FIGS. 33A to 33F illustrate specific examples of an electronic device that can be applied to a portable terminal including the display module of one embodiment of the present invention.

FIG. 33A illustrates a portable game machine including a housing 5001, a housing 5002, a display module 5003 of one embodiment of the present invention, a microphone 5005, a speaker 5006, an operation key 5007, a stylus 5008, and the like. When the display module 5003 of one embodiment of the present invention is used in the portable game machine, the display module 5003 can display an image with high display quality without being influenced by the intensity of external light in an environment where the display module 5003 is used and can have lower power consumption.

FIG. 33B illustrates a wristwatch-type portable terminal, which includes a housing 5201, a display module 5202 of one embodiment of the present invention, a band 5203, an optical sensor 5204, a switch 5205, and the like. The display module 5202 of one embodiment of the present invention, which is used in the wristwatch-type portable terminal, can display a high-quality image regardless of the intensity of external light in an operating environment and achieve low power consumption.

FIG. 33C illustrates a tablet personal computer, which includes a housing 5301, a housing 5302, a display module 5303 of one embodiment of the present invention, an optical sensor 5304, an optical sensor 5305, a switch 5306, and the like. The display module 5303 is supported by the housing 5301 and the housing 5302. The display module 5303 is formed using a flexible substrate and therefore has a function of being flexible in shape and bendable. By changing the angle between the housing 5301 and the housing 5302 with a hinge 5307 and a hinge 5308, the display module 5303 can be folded such that the housing 5301 and the housing 5302 overlap with each other. Although not illustrated, an open/close sensor may be incorporated so that the above-described angle change can be used as information about conditions of use of the display module 5303. The display module 5303 of one embodiment of the present invention, which is used in the tablet personal computer, can display a high-quality image regardless of the intensity of external light in an operating environment and achieve low power consumption.

FIG. 33D shows the peripheral portion of the driver's seat of a moving object such as a car, which includes a handle 5801, a pillar 5802, a door 5803, a windshield 5804, a display module 5805 of one embodiment of the present invention, and the like. The display module 5805 is formed using a flexible substrate and therefore has a function of being flexible in shape and bendable. Thus, the display module 5805 can be used for an instrument panel that displays meters and the like on a dashboard of a car having a plane surface or curved surfaces with different radii of curvature. By using the display module 5805 of one embodiment of the present invention for an instrument panel of a car, the display module 5805 can display a high-quality image regardless of the intensity of external light in the operating environment and achieve low power consumption.

FIG. 33E illustrates a wristwatch-type portable terminal, which includes a housing 5701 having a curved surface, a display module 5702 of one embodiment of the present invention, and the like. When a flexible substrate is used for the display module 5702 of one embodiment of the present invention, the display module 5702 can be supported by the housing 5701 having a curved surface. Consequently, it is possible to provide a user-friendly wristwatch-type portable terminal that is flexible and lightweight. In addition, the display module 5702 of one embodiment of the present invention, which is used in the wristwatch-type portable terminal, can display a high-quality image regardless of the intensity of external light in an operating environment and achieve low power consumption.

FIG. 33F illustrates a cellular phone, which includes a display module 5902 of one embodiment of the present invention, a microphone 5907, a speaker 5904, a camera 5903, an external connection portion 5906, and an operation button 5905 in a housing 5901 having a curved surface. The display module 5902 of one embodiment of the present invention, which is used in the cellular phone, can display a high-quality image regardless of the intensity of external light in an operating environment and achieve low power consumption.

At least part of this embodiment can be implemented in combination with any of the other embodiments described in this specification as appropriate.

### REFERENCE NUMERALS

AF1: alignment film, AF2: alignment film, ANO: wiring, C1: capacitor, C2: capacitor, CF1: coloring film, CSCOM: wiring, G1: wiring, G2: wiring, G3: wiring, KB1: structure body, KB2: structure body, S1: wiring, S2: wiring, S3: wiring, SW1: switch, SW2: switch, T1: touched area, T2: touched area, T3: touched area, T4: touched area, VCOM1: wiring, VCOM2: wiring, 10: electronic device, 11: display device, 11a: display region, 11b: display region, 11c: display device, 11d: display region, 12a: display region, 12b: display region, 12c: display region, 12d: display region, 12e: display region, 12f: display region, 12g: display region, 12h: display region, 12i: display region, 12j: display region, 12k: display region, 12l: display region, 12m: display region, 12n: display region, 12o: display region, 12p: display region, 12q: display region, 13a: touch sensing region, 13b: touch sensing region, 13c: touch sensing region, 13d: touch sensing region, 14a: touch sensing region, 14b: touch sensing region, 14c: touch sensing region, 15: touch panel, 15a: touch sensing region, 15b: touch sensing region, 15c: touch sensing region, 15d: touch sensing region, 15e: touch sensing region, 15f: touch sensing region, 15g: touch sensing region, 15h: touch sensing region, 15j: touch sensing region, 15k: touch sensing region, 15l: touch sensing region, 15m: touch sensing region, 15n: touch sensing region, 15o: touch sensing region, 15p: touch sensing region, 21: touch panel, 21a: touch sensing region, 21b: touch sensing region, 21c: touch sensing region, 21d: touch sensing region, 21f: touch sensing region, 21h: touch sensing region, 21j: touch sensing region, 21l: touch sensing region, 21m: touch sensing region, 21n: touch sensing region, 21p: touch panel, 21z: touch panel, 22a: icon, 22b: icon, 22e: icon, 23: peripheral device, 23a: switch, 23b: switch, 23c: switch, 23d: joystick, 23e: carrier wave, 23g: carrier wave, 24: substrate, 24a: touch sensor module, 24b: touch sensor module, 25: substrate, 25a: display device, 25b: display device, 26a: FPC, 26b: FPC, 27a: touch sensor control IC, 27b: driver IC, 28a: gate driver, 28b: gate driver, 29a: gate driver, 29b: gate driver, 30: pixel, 30a: pixel, 30b: pixel, 31: display element, 31B: display element, 31G: display element, 31p: pixel circuit, 31R: display element, 32: display element, 32B: display element, 32G: display element, 32p: pixel circuit, 32R: display element, 32Y: display element, 35r: light, 35t: light, 35tr: light, 41: layer, 42: layer, 50: adhesive layer, 51: adhesive layer, 52: adhesive layer, 61: light, 62: reflected light, 70: display module, 70a: display module, 81: region, 82: region, 100: display panel, 101: resin layer, 102: resin layer, 110: transistor, 110a: transistor, 110b: transistor, 110c: transistor, 111: conductive layer, 112: semiconductor layer, 113a: conductive layer, 113b: conductive layer, 114: conductive layer, 115: conductive layer, 120: light-emitting element, 121: conductive layer, 122: EL layer, 123: conductive layer, 131: insulating layer, 132: insulating layer, 133: insulating layer, 134: insulating layer, 135: insulating layer, 136: insulating layer, 137: insulating layer, 141: insulating layer, 151: adhesive layer, 152: coloring layer, 153: light-blocking layer, 200: display panel, 201: resin layer, 202: resin layer, 204: insulating layer, 210: transistor, 211: conductive layer, 212: semiconductor layer, 213a: conductive layer, 213b: conductive layer, 220: liquid crystal element, 221: conductive layer, 222: liquid crystal, 223: conductive layer, 224a: alignment film, 224b: alignment film, 231: insulating layer, 232: insulating layer, 233: insulating layer, 234: insulating layer, 268: touch sensor, 300: display device, 311: electrode, 311b: electrode, 340: liquid crystal element, 351: substrate, 360: light-emitting element, 360b: light-emitting element, 360g: light-emitting element, 360r: light-emitting element, 360w: light-emitting element, 361: substrate, 362a: display portion, 362b: display portion, 364: circuit portion, 365: wiring, 366: circuit portion, 367: wiring, 368: touch sensor, 372: FPC, 373: IC, 374: FPC, 375: IC, 400: display panel, 401: transistor, 402: transistor, 403: transistor, 405: capacitor, 406: connection portion, 407: wiring, 410: pixel, 411: insulating layer, 412: insulating layer, 413: insulating layer, 414: insulating layer, 415: insulating layer, 416: spacer, 417: adhesive layer, 419: connection layer, 421: electrode, 422: EL layer, 423: electrode, 424: optical adjustment layer, 425: coloring layer, 426: light-blocking layer, 451: opening, 476: insulating layer, 478: insulating layer, 501: transistor, 503: transistor, 505: capacitor, 506: connection portion, 511: insulating layer, 512: insulating layer, 513: insulating layer, 514: insulating layer, 517: adhesive layer, 519: connection layer, 529: liquid crystal element, 543: connector, 562: electrode, 563: liquid crystal, 564a: alignment film, 564b: alignment film, 565: coloring layer, 566: light-blocking layer, 567: insulating layer, 576: insulating layer, 578: insulating layer, 591: conductive layer, 592: conductive layer, 599: polarizing plate, 611: substrate, 612: substrate, 710: CPU, 711: display controller, 712a: memory, 712b: memory, 713: camera, 714: GPS, 715: battery, 716: communication module, 717: photosensor, 718: touch controller, 719: speaker, 720: microphone, 731: reflective liquid crystal display panel, 732: light-emitting display panel, 2010: unit, 2020: unit, 2030: input unit, 2501C: insulating film, 2505: bonding layer, 2512B: conductive film, 2520: functional layer, 2521: insulating film, 2521A: insulating film, 2521B: insulating film, 2522: connection portion, 2528: insulating film, 2550: display element, 2551: electrode, 2552: electrode, 2553: layer, 2560: optical element, 2565: covering film, 2570: substrate, 2580: lens, 2591A: opening, 2700: display panel, 2700TP3: input/output panel, 2702: pixel, 2720: functional layer, 2750: display element, 2751: electrode, 2751H: region, 2752: electrode, 2753: layer, 2770: substrate, 2770D: functional film, 2770P: functional film, 2770PA: retardation film, 2770PB: polarizing layer, 2771: insulating film, 5001: housing, 5002: housing, 5003: display module, 5005: microphone, 5006: speaker, 5007: operation key, 5008: stylus, 5201: housing, 5202: display module, 5203: band, 5204: optical sensor, 5205: switch, 5301: housing, 5302: housing, 5303: display module, 5304: optical sensor, 5305: optical sensor, 5306: switch, 5307: hinge, 5701: housing, 5702: display module, 5801: handle, 5802: pillar, 5803: door, 5804: windshield, 5805: display module, 5901: housing, 5902: display module, 5903: camera, 5904: speaker, 5905: button, 5906: external connection portion, 5907: microphone, 8000: display module, 8001: upper cover, 8002: lower cover, 8005: FPC, 8006: display panel, 8009: frame, 8010: printed circuit board, 8011: battery, 8015: light-emitting portion, 8016: light-receiving portion, 8017a: light guide portion, 8017b: light guide portion, 8018: light

This application is based on Japanese Patent Application Serial No. 2016-208987 filed with Japan Patent Office on Oct. 25, 2016, the entire contents of which are hereby incorporated by reference.

1. A touch panel input system comprising:
a touch sensor module,
wherein the touch sensor module comprises a touch panel and a control portion,
wherein the touch panel comprises a first touch sensing region and a second touch sensing region,
wherein the control portion is configured to perform a step of calculating areas where a touch is sensed in the first touch sensing region and the second touch sensing region, and
wherein the control portion is configured to perform a step of determining that one of the first and second touch sensing regions that has a larger calculated area is a touched position.

2. The touch panel input system according to claim 1, further comprising a display module,
wherein the display module comprises the touch sensor module and a display device,
wherein the display device comprises a first display region,
wherein the first display region comprises a second display region and a third display region,
wherein the control portion is configured to divide the first display region into the second display region and the third display region to control the second display region and the third display region,
wherein the first touch sensing region is positioned to overlap with and be in the second display region,
wherein the second touch sensing region is positioned to overlap with and be in the third display region, and
wherein the control portion is configured to perform a step of extracting a plurality of display objects displayed in the second display region overlapping with the first touch sensing region by sensing a touch on the first touch sensing region, a step of displaying the plurality of display objects extracted from the second display region in the first display region, a step of extracting a plurality of display objects displayed in the third display region overlapping with the second touch sensing region by sensing a touch on the second touch sensing region, and a step of displaying the plurality of display objects extracted from the third display region in the first display region.

3. The touch panel input system according to claim 2,
wherein the touch sensor module further comprises a third touch sensing region,
wherein the first display region further comprises a fourth display region,
wherein the third touch sensing region is positioned to overlap with and be in the fourth display region,
wherein the control portion is configured to display a display object showing a direction in the fourth display region,
wherein the control portion is configured to perform a step of moving a selection position from the second display region to the third display region in accordance with a direction shown by the display object showing a direction by sensing a touch on the third touch sensing region, and a step of changing a gray level of the third display region to show that the third display region is selected.

4. The touch panel input system according to claim 2,
wherein the display device further comprises a transistor, and
wherein the transistor comprises metal oxide in a semiconductor layer.

5. The touch panel input system according to claim 4, wherein the transistor comprising metal oxide in the semiconductor layer in the display device comprises a back gate.

6. The touch panel input system according to claim 3, wherein the display device comprises a liquid crystal element.

7. The touch panel input system according to claim 3, wherein the display device comprises a light-emitting element.

8. An electronic device comprising:
the touch panel input system according to claim 1;
a CPU; and
a battery.

9. A touch panel input system comprising:
a touch sensor module,
wherein the touch sensor module comprises a touch panel and a control portion,
wherein the touch panel comprises a first touch sensing region and a second touch sensing region,
wherein the control portion is configured to perform a step of calculating areas where a touch is sensed in the first touch sensing region and the second touch sensing region,
wherein the control portion is configured to perform a step of determining that one of the first and second touch sensing regions that has a larger calculated area is a touched position, and
wherein the control portion is configured to perform a step of integrating the areas where a touch is sensed by time, and a step of determining that one of the first and second touch sensing regions that has a larger integrated area is a touched position.

10. The touch panel input system according to claim 9, further comprising a display module,
wherein the display module comprises the touch sensor module and a display device,
wherein the display device comprises a first display region,
wherein the first display region comprises a second display region and a third display region,
wherein the control portion is configured to divide the first display region into the second display region and the third display region to control the second display region and the third display region,
wherein the first touch sensing region is positioned to overlap with and be in the second display region,
wherein the second touch sensing region is positioned to overlap with and be in the third display region, and
wherein the control portion is configured to perform a step of extracting a plurality of display objects displayed in the second display region overlapping with the first touch sensing region by sensing a touch on the first touch sensing region, a step of displaying the plurality of display objects extracted from the second display region in the first display region, a step of extracting a plurality of display objects displayed in the third display region overlapping with the second touch sensing region by sensing a touch on the second touch sensing region, and a step of displaying the plurality of display objects extracted from the third display region in the first display region.

11. The touch panel input system according to claim 10,
wherein the touch sensor module further comprises a third touch sensing region,
wherein the first display region further comprises a fourth display region,
wherein the third touch sensing region is positioned to overlap with and be in the fourth display region,
wherein the control portion is configured to display a display object showing a direction in the fourth display region, and
wherein the control portion is configured to perform a step of moving a selection position from the second display region to the third display region in accordance with a direction shown by the display object showing a direction by sensing a touch on the third touch sensing region, and a step of changing a gray level of the third display region to show that the third display region is selected.

12. The touch panel input system according to claim 10,
wherein the display device further comprises a transistor, and
wherein the transistor comprises metal oxide in a semiconductor layer.

13. The touch panel input system according to claim 12, wherein the transistor comprising metal oxide in the semiconductor layer in the display device comprises a back gate.

14. The touch panel input system according to claim 10, wherein the display device comprises a liquid crystal element.

15. The touch panel input system according to claim 10, wherein the display device comprises a light-emitting element.

16. An electronic device comprising:
the touch panel input system according to claim 9;
a CPU; and
a battery.
